(19) United States
(12) Patent Application Publication
(10) Pub. No.: US 2022/0352482 A1
(43) Pub. Date: Nov. 3, 2022

(54) LIGHT-EMITTING ELEMENT

(71) Applicant: SHARP KABUSHIKI KAISHA, Sakai City, Osaka (JP)

(72) Inventor: KENJI KIMOTO, Sakai City, Osaka (JP)

(73) Assignee: SHARP KABUSHIKI KAISHA, Sakai City, Osaka (JP)

(21) Appl. No.: 17/634,706

(22) PCT Filed: Aug. 13, 2019
(86) PCT No.: PCT/JP2019/031804

§ 371 Date: Feb. 11, 2022

(51) Int. Cl. H01L 51/50

(52) U.S. Cl. CPC H01L 51/5064

(57) ABSTRACT

A light-emitting element is provided with a first electrode which is an anode; a second electrode which is a cathode; a light-emitting layer provided between the first electrode and the second electrode; an oxide layer provided between the first electrode or the second electrode and the light-emitting layer; and an oxide layer provided in contact with the oxide layer and between the oxide layer and the second electrode, wherein of the oxide layer and the oxide layer, the layer closer to the light-emitting layer is formed from a semiconductor; and an oxygen atom density in the oxide layer is less than an oxygen atom density in the oxide layer.

### TECHNICAL FIELD

The present disclosure relates to a light-emitting element and a light-emitting device, such as a display device, an illumination device, or the like, that includes a light-emitting element.

### BACKGROUND ART

In recent years, various display devices have been developed. Particularly, a display device including an Organic Light Emitting Diode (OLED) and a display device including an inorganic light-emitting diode or a Quantum dot Light Emitting Diode (QLED) have drawn a great deal of attention because the devices are capable of achieving lower power consumption, smaller thickness, higher picture quality, and the like.

However, in a light-emitting element, such as an OLED, QLED, and the like, for reasons described below, there is a problem in that the luminous efficiency is likely to decrease because the hole injection to the light-emitting layer and/or the electron injection to the light-emitting layer does not easily efficiently occur.

FIG. 26 is an energy band diagram for describing the reason as to why, in a conventional light-emitting element 201, such as an OLED, QLED, and like, the hole injection and the electron injection does not easily occur.

As illustrated in FIG. 26, the light-emitting element 201 includes a first electrode (hole injection layer: anode (anode electrode) 205) and a second electrode (electron injection layer: cathode (cathode electrode) 206). A hole transport layer 202, a light-emitting layer 203, and an electron transport layer 204 are layered in this order from the first electrode 205 side between the first electrode 205 and the second electrode 206.

In the light-emitting element 201, the height of a hole injection barrier Eh from the first electrode 205 to the hole transport layer 202 is the energy difference between the Fermi level of the first electrode 205 and the upper end of the valence band (HTL valence band) of the hole transport layer 202.

In the light-emitting element 201, the height of the electron injection barrier Ee from the second electrode 206 to the electron transport layer 204 is the energy difference between the lower end of the conduction band (ETL conduction band) of the electron transport layer 204 and the Fermi level of the second electrode 206.

However, the material of the hole transport layer 202 and the material of the electron transport layer 204 are selected taking into consideration the reactivity and band alignment of the light-emitting material for OLED or the light-emitting material for QLED constituting the light-emitting layer 203. However, among the light-emitting material for OLED or the light-emitting material for QLED constituting the light-emitting layer 203, the material of the hole transport layer 202, and the material of the electron transport layer 204, there are few materials that have ensured long-term reliability. Also, it is common for one from among the material of the first electrode 205 and the material of the second electrode 206 to be a light-permeable material taking into consideration light extraction from the element, and the other be a light-reflective material. Furthermore, the material of the first electrode 205 and the material of the second electrode 206 needs to be selected taking into consideration the reactivity with the hole transport layer 202 and the electron transport layer 204, the band alignment, and the like. Thus, in the case of the hole transport layer 202, the electron transport layer 204, the first electrode 205, and the second electrode 206, the choice of the material is limited.

When the material of the hole transport layer 202, the material of the light-emitting layer 203, the material of the electron transport layer 204, the material of the first electrode 205, and the material of the second electrode 206 are selected from among the small number of materials, because at least one of the height of the hole injection barrier Eh or the height of the electron injection barrier Ee increases, it becomes difficult to efficiently inject holes from the first electrode 205 to the hole transport layer 202 and/or inject electrons from the second electrode 206 to the electron transport layer 204.

As described in PTL 1, the band level of a light-emitting layer can be adjusted by forming a light-emitting layer having an organic ligand distribution in which the surface contacting the hole transport layer and the surface contacting the electron transport layer are different from each other. Specifically, it is described that by adjusting the band level of the light-emitting layer so that the energy difference between the valence band level of the light-emitting layer and the valence band level of the hole transport layer can be reduced, a light-emitting element having a low turn-on voltage and a low drive voltage and superior brightness and luminous efficiency can be achieved.

### CITATION LIST

### Patent Literature

PTL 1: JP 2010-114079 A (published on May 20, 2010)

### SUMMARY OF INVENTION

### Technical Problem

However, as described in PTL 1, the difference in ionization potential between the light-emitting layer with no band level adjustment and the light-emitting layer with an adjusted band level is small and effective band level adjustment cannot be performed. Also, the method for adjusting the band level described in PTL 1 cannot be applied to adjusting the height of the hole injection barrier Eh between the first electrode 205 and the hole transport layer 202. Similarly, the method for adjusting the band level described in PTL 1 cannot be applied to adjusting the height of the electron injection barrier Ee between the second electrode 206 and the electron transport layer 204. Thus, there is still a problem in that the luminous efficiency is poor for a light-emitting element because the hole injection amount and the electron injection amount to the light-emitting layer cannot be effectively controlled.

An aspect of the present invention has been made in view of the above-mentioned issue, and an object of the present invention is to provide a light-emitting element with a high luminous efficiency and a light-emitting device.

### Solution to Problem

In order to solve the issues described above, a light-emitting element according to an aspect of the present invention includes:

a first electrode which is an anode;

a second electrode which is a cathode;

a light-emitting layer provided between the first electrode and the second electrode;

a first oxide layer provided between the first electrode or the second electrode and the light-emitting layer: and

a second oxide layer provided in contact with the first oxide layer and between the first oxide layer and the second electrode, wherein

of the first oxide layer and the second oxide layer, the layer closer to the light-emitting layer is formed from a semiconductor; and

an oxygen atom density in the second oxide layer is different from an oxygen atom density in the first oxide layer.

In order to solve the issues described above, a light-emitting element according to an aspect of the present invention includes:

a first electrode which is an anode;

a second electrode which is a cathode;

a light-emitting layer provided between the first electrode and the second electrode;

a first oxide layer provided between the first electrode and the light-emitting layer: and

a second oxide layer provided in contact with the first oxide layer and between the first oxide layer and the light-emitting layer, wherein

the second oxide layer includes at least one of nickel oxide or copper aluminate; and

the first oxide layer includes at least one of aluminum oxide, gallium oxide, tantalum oxide, zirconium oxide, hafnium oxide, magnesium oxide, or a composite oxide including two or more types of cations of these oxides.

In order to solve the issues described above, a light-emitting element according to an aspect of the present invention includes:

a first electrode which is an anode;

a second electrode which is a cathode;

a light-emitting layer provided between the first electrode and the second electrode;

a first oxide layer provided between the first electrode and the light-emitting layer; and

a second oxide layer provided in contact with the first oxide layer and between the first oxide layer and the light-emitting layer, wherein

the second oxide layer includes copper(I) oxide; and

the first oxide layer includes at least one of aluminum oxide, gallium oxide, tantalum oxide, zirconium oxide, hafnium oxide, magnesium oxide, germanium oxide, silicon oxide, yttrium oxide, lanthanum oxide, strontium oxide, or a composite oxide including two or more types of cations of these oxides.

In order to solve the issues described above, a light-emitting element according to an aspect of the present invention includes:

a first electrode which is an anode;

a second electrode which is a cathode;

a light-emitting layer provided between the first electrode and the second electrode;

a first oxide layer provided between the second electrode and the light-emitting layer; and

a second oxide layer provided in contact with the first oxide layer and between the first oxide layer and the second electrode, wherein

an oxide including at least one of aluminum oxide, gallium oxide, tantalum oxide, zirconium oxide, hafnium oxide, magnesium oxide, germanium oxide, silicon oxide, yttrium oxide, lanthanum oxide, strontium oxide, or a composite oxide including two or more types of cations of these oxides is an oxide of a first group;

an oxide including at least one of gallium oxide (β), tantalum oxide, zirconium oxide, hafnium oxide, magnesium oxide, germanium oxide, silicon oxide, yttrium oxide, lanthanum oxide, strontium oxide, or a composite oxide including two or more types of cations of these oxides is an oxide of a second group;

an oxide including at least one of hafnium oxide, magnesium oxide, germanium oxide, silicon oxide, yttrium oxide, lanthanum oxide, strontium oxide, or a composite oxide including two or more types of cations of these oxides is an oxide of a third group;

an oxide including at least one of germanium oxide, silicon oxide, yttrium oxide, lanthanum oxide, strontium oxide, or a composite oxide including two or more types of cations of these oxides is an oxide of a fourth group;

an oxide including at least one of silicon oxide, yttrium oxide, lanthanum oxide, strontium oxide, or a composite oxide including two or more types of cations of these oxides is an oxide of a fifth group;

an oxide including at least one of yttrium oxide, lanthanum oxide, strontium oxide, or a composite oxide including two or more types of cations of these oxides is an oxide of a sixth group;

in a case where the first oxide layer includes a rutile-type titanium oxide, the second oxide layer is an oxide of the first group;

in a case where the first oxide layer includes an anatase-type of titanium oxide, the second oxide layer is an oxide of the second group;

in a case where the first oxide layer includes tin oxide, the second oxide layer is an oxide of the third group;

in a case where the first oxide layer includes strontium titanium, the second oxide layer is an oxide of the fourth group;

in a case where the first oxide layer includes indium oxide, the second oxide layer is an oxide of the fifth group; and

in a case where the first oxide layer includes zinc oxide, the second oxide layer is an oxide of the sixth group.

In order to solve the issues described above, a light-emitting element according to an aspect of the present invention includes:

a first electrode which is an anode;

a second electrode which is a cathode;

a light-emitting layer provided between the first electrode and the second electrode; and

a fifth oxide layer, a sixth oxide layer in contact with the fifth oxide layer, and a seventh oxide layer in contact with the sixth oxide layer provided in this order from a side closer to the first electrode between the first electrode and the light-emitting layer or between the light-emitting layer and the second electrode, wherein

the sixth oxide layer is formed from a semiconductor,

an oxygen atom density in the sixth oxide layer is different from an oxygen atom density in the fifth oxide layer; and

an oxygen atom density in the seventh oxide layer is different from the oxygen atom density of the sixth oxide layer.

In order to solve the issues described above, a light-emitting device according to an aspect of the present invention includes the light-emitting element.

### Advantageous Effects of Invention

According to an aspect of the present invention, a light-emitting element with high luminous efficiency and a light-emitting device can be provided.

### BRIEF DESCRIPTION OF DRAWINGS

FIG. 1 is a diagram illustrating a schematic configuration of a display device including a light-emitting element according to a first embodiment.

FIG. 2 is a cross-sectional view schematically illustrating a schematic configuration of the light-emitting element according to the first embodiment.

(a) of FIG. 3 is an energy band diagram for describing a hole injection barrier in a light-emitting element according to a comparative example. (b) of FIG. 3 is an energy band diagram for describing a hole injection barrier in the light-emitting element of the first embodiment.

(a) of FIG. 4 is a diagram for describing the mechanism by which oxygen atoms move at the interface between the oxide layers illustrated in (b) of FIG. 3. (b) of FIG. 4 is a diagram illustrating a state in which an electric dipole is formed by movement of oxygen atoms at the interface between the oxide layers illustrated in (b) of FIG. 3.

(a) of FIG. 5 is a diagram listing examples of an inorganic oxide forming a typical hole transport layer and the oxygen atom density thereof. (b) of FIG. 5 is a diagram listing examples of an exemplary inorganic oxide and the oxygen atom density thereof.

FIG. 6 is a diagram listing examples of combinations of oxides forming the hole transport layer and oxides forming the oxide layer adjacent to the oxide layer forming the hole transport layer.

(a) to (d) of FIG. 7 are diagrams illustrating schematic configurations of a light-emitting element according the first embodiment.

FIG. 8 is a cross-sectional view schematically illustrating a schematic configuration of the light-emitting element according to the second embodiment.

(a) of FIG. 9 is an energy band diagram for describing an electron injection barrier in a light-emitting element according to a comparative example. (b) of FIG. 9 is an energy band diagram for describing an electron injection barrier in the light-emitting element of the second embodiment.

(a) of FIG. 10 is a diagram for describing the mechanism by which oxygen atoms move at the interface between the oxide layers illustrated in (b) of FIG. 9. (b) of FIG. 10 is a diagram illustrating a state in which an electric dipole is formed by movement of oxygen atoms at the interface between the oxide layers illustrated in (b) of FIG. 9.

(a) of FIG. 11 is a diagram listing examples of an inorganic oxide forming a typical electron transport layer and the oxygen atom density thereof. (b) of FIG. 11 is a diagram illustrating an example of an exemplary inorganic oxide and the oxygen atom density thereof.

FIG. 12 is a diagram listing examples of combinations of oxides forming the electron transport layer and oxides forming the oxide layer adjacent to the oxide layer forming the electron transport layer.

(a) to (d) of FIG. 13 are diagrams illustrating schematic configurations of a light-emitting element according the second embodiment.

FIG. 14 is a cross-sectional view schematically illustrating a schematic configuration of a light-emitting element according to a third embodiment.

FIG. 15 is an energy band diagram for describing a hole injection barrier in the light-emitting element of the third embodiment.

(a) of FIG. 16 is a diagram for describing the mechanism by which oxygen atoms move at the interface between the oxide layers illustrated in FIG. 15. (b) of FIG. 16 is a diagram illustrating a state in which an electric dipole is formed by movement of oxygen atoms at the interface between the oxide layers illustrated in FIG. 15.

(a) of FIG. 17 is a diagram listing examples of an inorganic oxide forming a typical hole transport layer and the oxygen atom density thereof. (b) of FIG. 17 is a diagram listing examples of an exemplary inorganic oxide and the oxygen atom density thereof.

FIG. 18 is a diagram, for in the light-emitting element of the third embodiment, listing material selectable from examples of exemplary inorganic oxides forming the typical hole transport layer listed in (a) of FIG. 17, and material selectable from examples of exemplary inorganic oxides listed in (b) of FIG. 17.

FIG. 19 is a cross-sectional view schematically illustrating a schematic configuration of a light-emitting element according to a fourth embodiment.

FIG. 20 is an energy band diagram for describing an electron injection barrier in the light-emitting element of the fourth embodiment.

(a) of FIG. 21 is a diagram for describing the mechanism by which oxygen atoms move at the interface between the oxide layers illustrated in FIG. 20. (b) of FIG. 21 is a diagram illustrating a state in which an electric dipole is formed by movement of oxygen atoms at the interface between the oxide layers illustrated in FIG. 20.

(a) of FIG. 22 is a diagram listing examples of an inorganic oxide forming a typical electron transport layer and the oxygen atom density thereof. (b) of FIG. 22 is a diagram listing examples of an exemplary inorganic oxide and the oxygen atom density thereof.

FIG. 23 is a diagram, for in the light-emitting element of the fourth embodiment, listing material selectable from examples of exemplary inorganic oxides forming the typical electron transport layer listed in (a) of FIG. 22, and material selectable from examples of exemplary inorganic oxides listed in (b) of FIG. 22.

FIG. 24 is a cross-sectional view schematically illustrating a schematic configuration of a light-emitting element according to a fifth embodiment.

FIG. 25 is a cross-sectional view schematically illustrating a schematic configuration of a light-emitting element according to a sixth embodiment.

FIG. 26 is an energy band diagram for describing the reason as to why, in a conventional light-emitting element, hole injection or electron injection does not easily occur.

### DESCRIPTION OF EMBODIMENTS

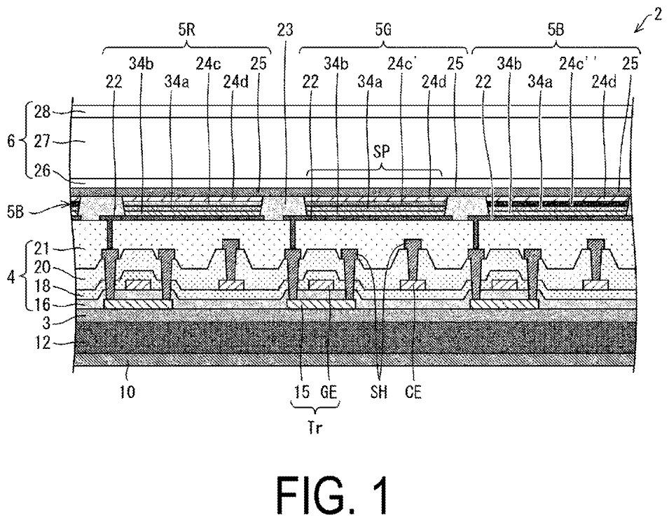

Embodiments of the present disclosure will be described with reference to FIGS. 1 to 25 as follows. Hereinafter, for convenience of explanation, components having the same functions as those described in a specific embodiment are appended with the same reference signs, and descriptions thereof may be omitted.

In the following embodiments of the present disclosure, a display device provided with a plurality of light-emitting elements on a substrate is described as an example of a light-emitting device provided with an light-emitting element on a substrate, but the present disclosure is not limited thereto and may be an illumination device provided with one or more light-emitting elements on a substrate.

### First Embodiment

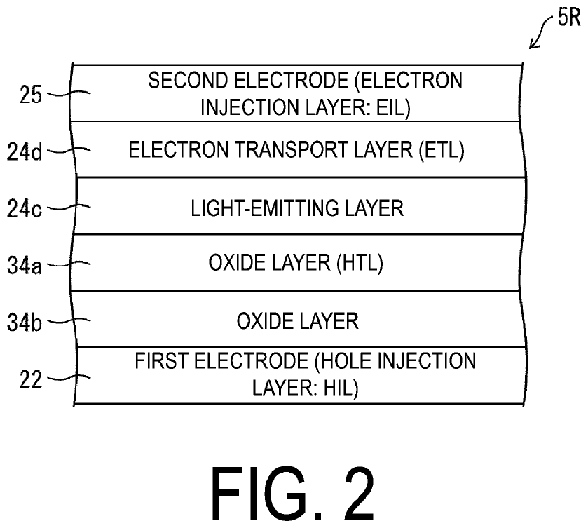

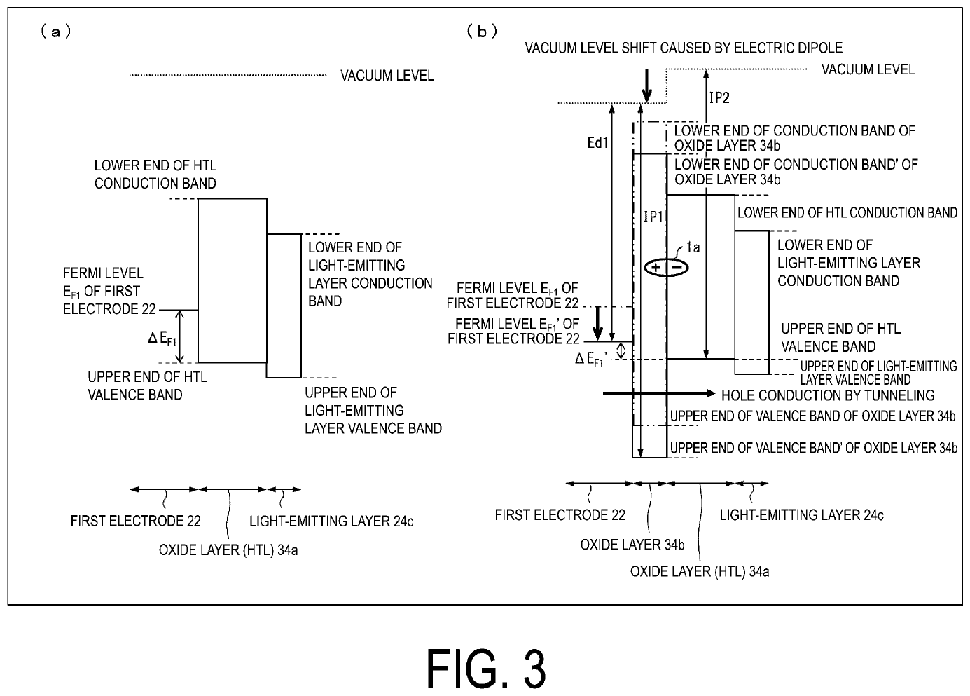

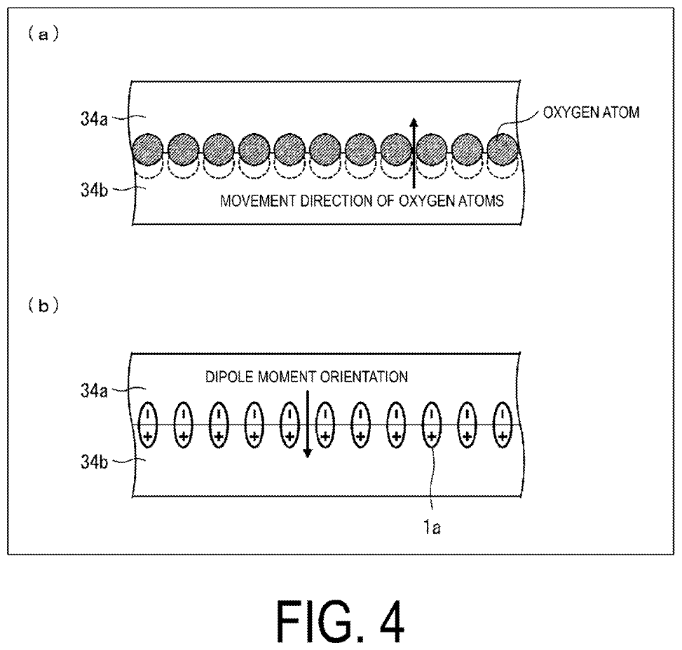

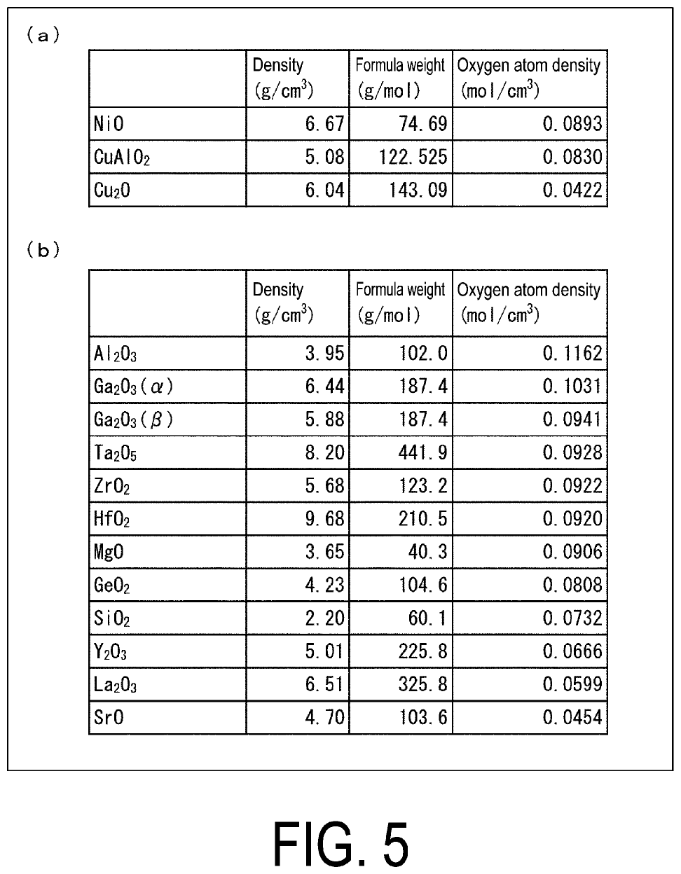

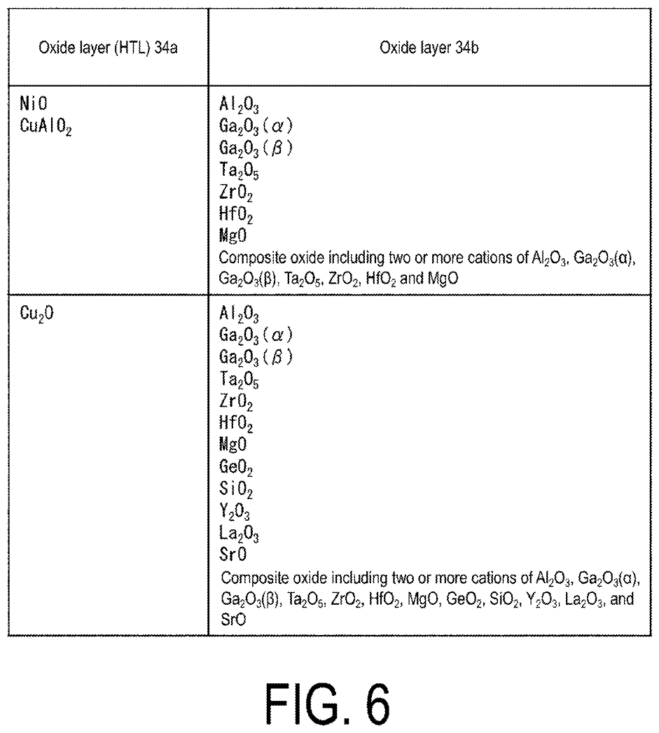

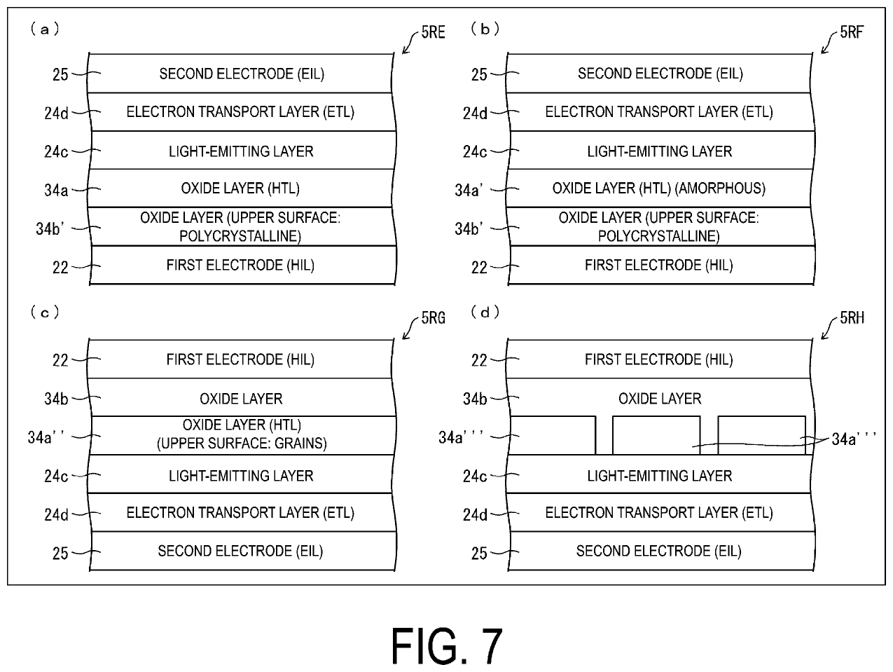

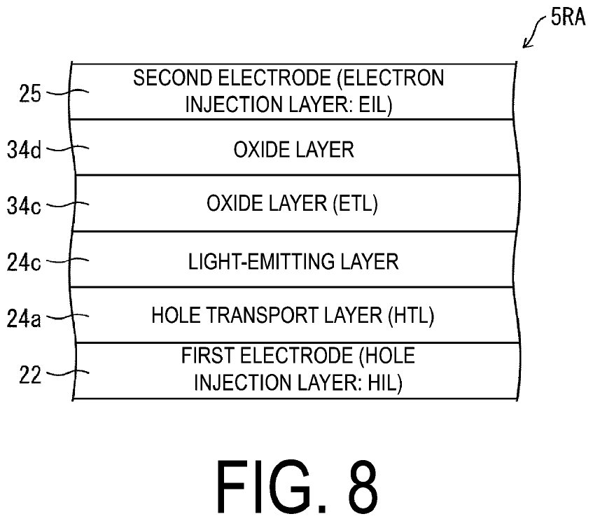

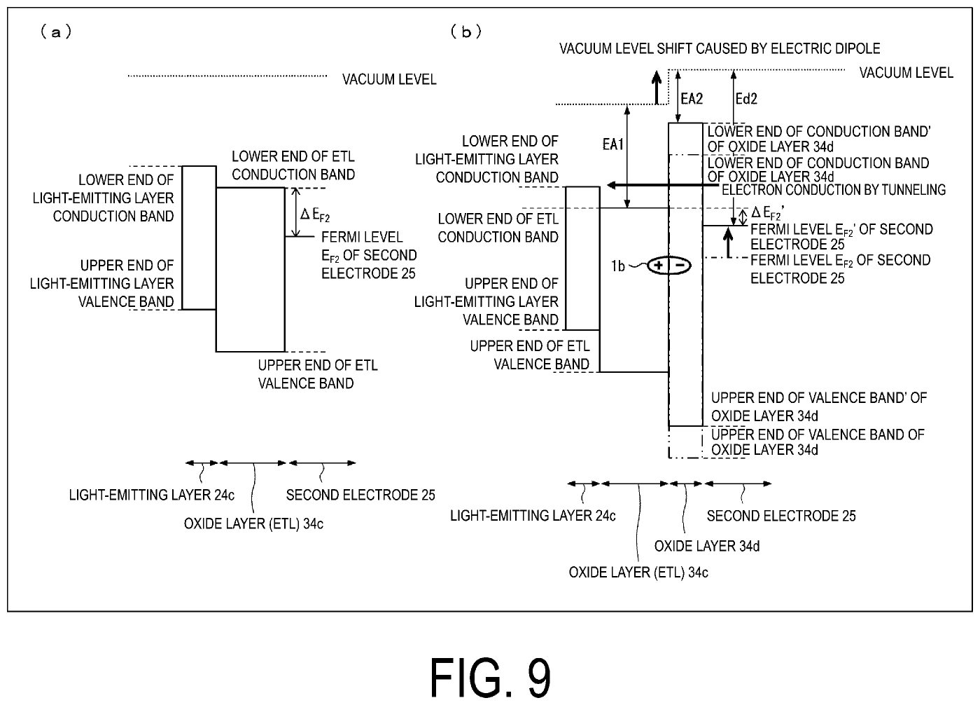

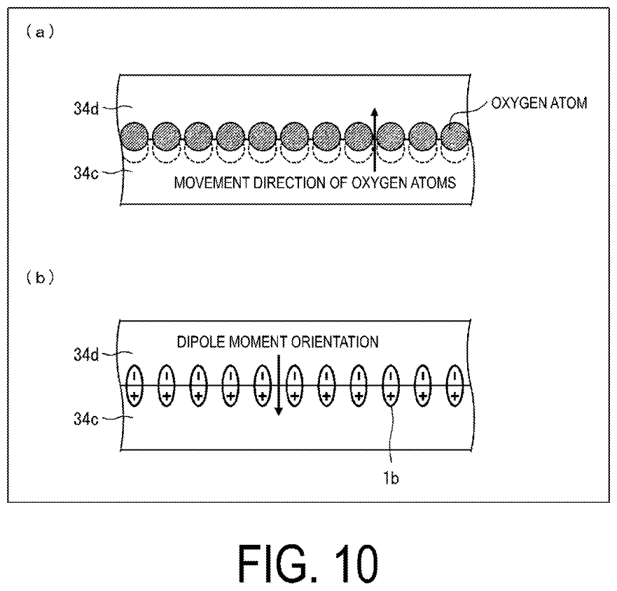

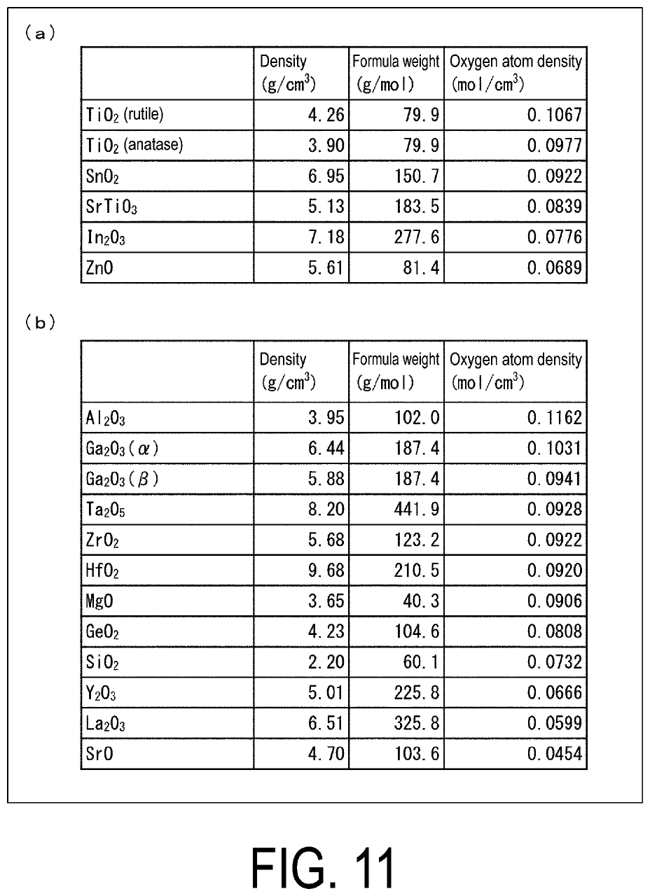

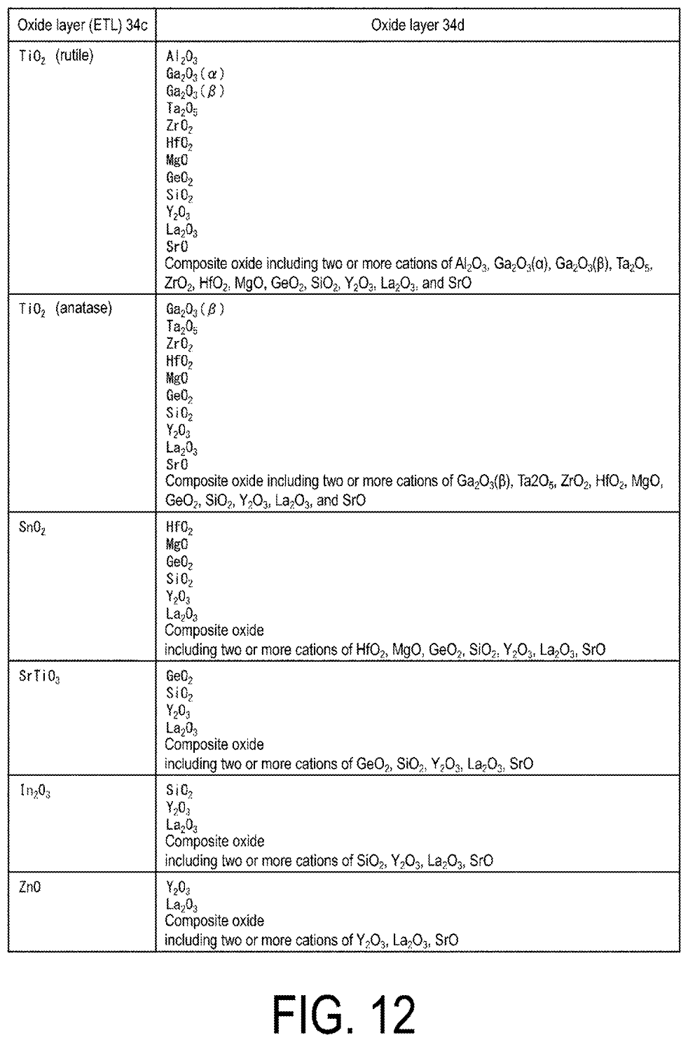

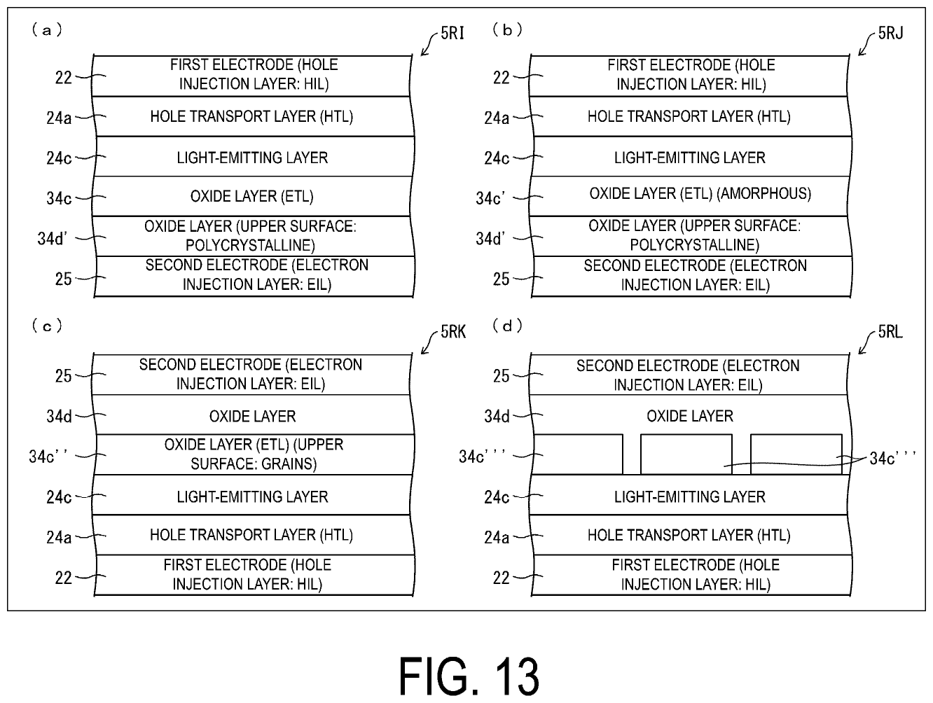

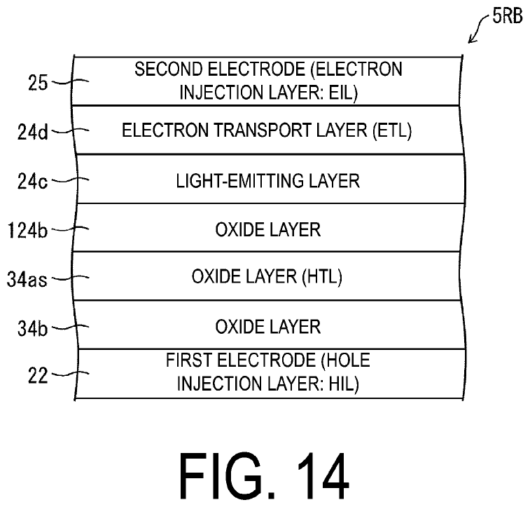

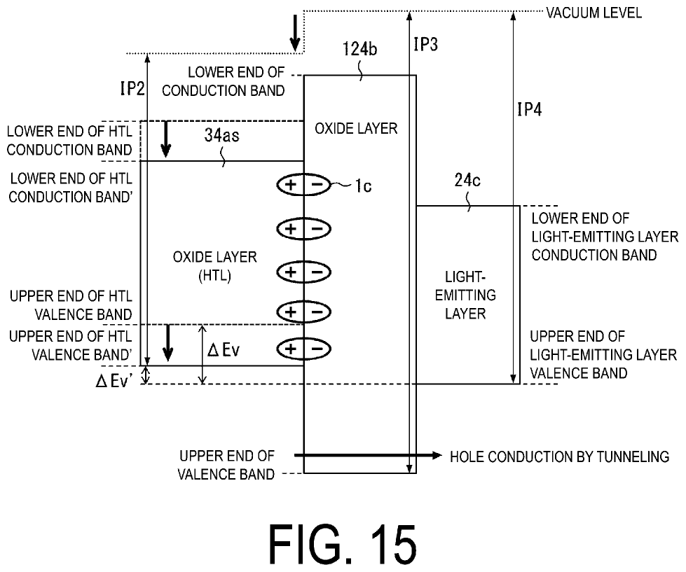

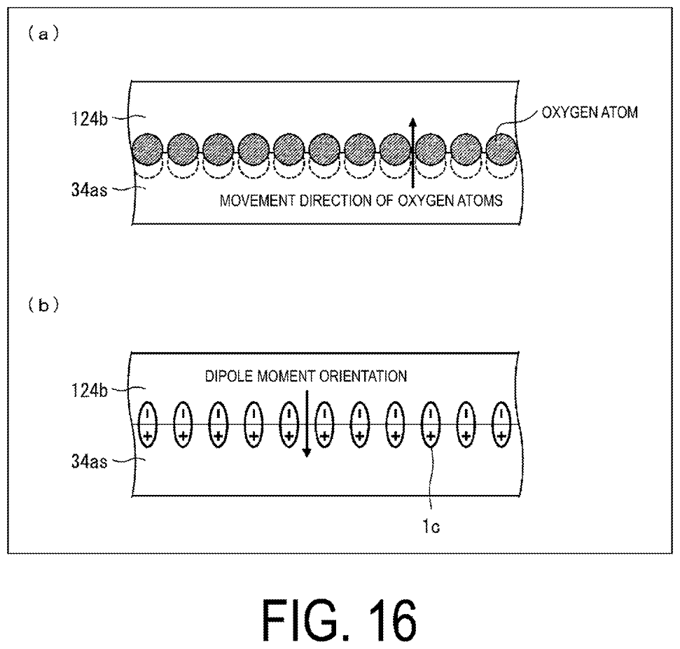

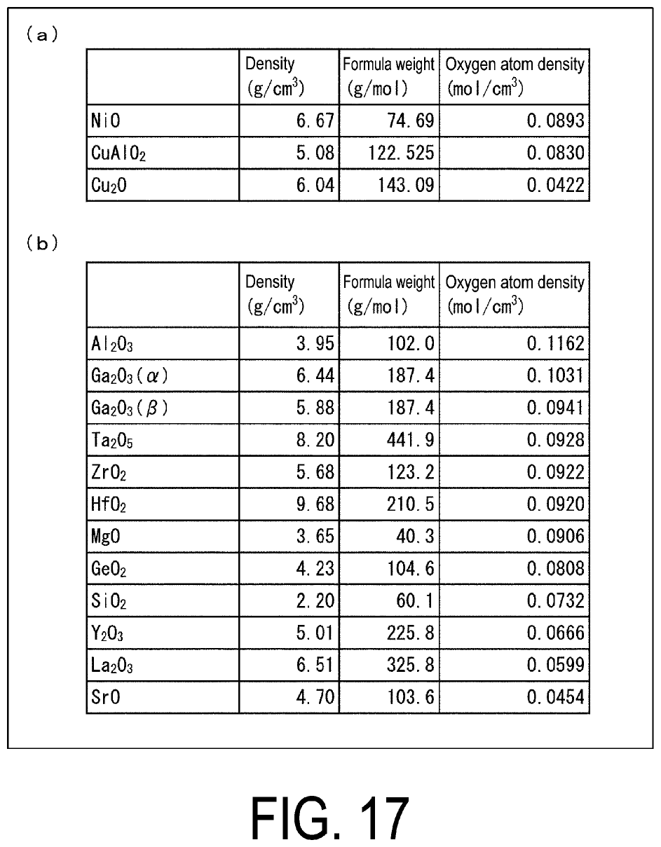

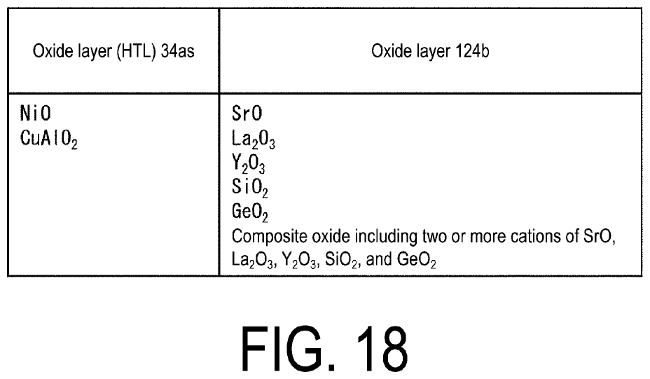

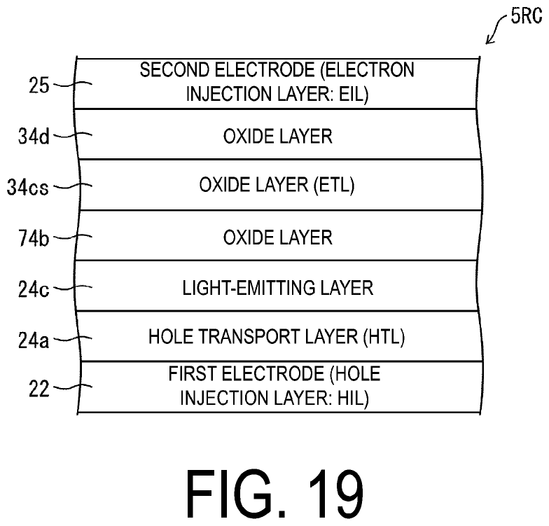

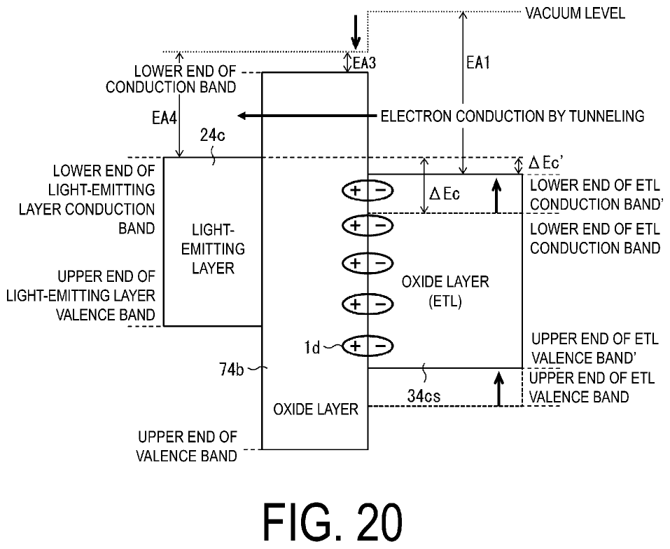

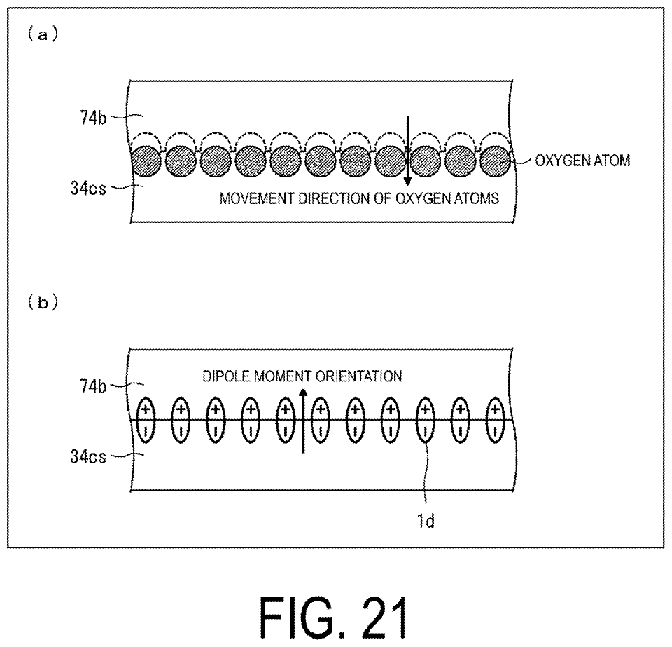

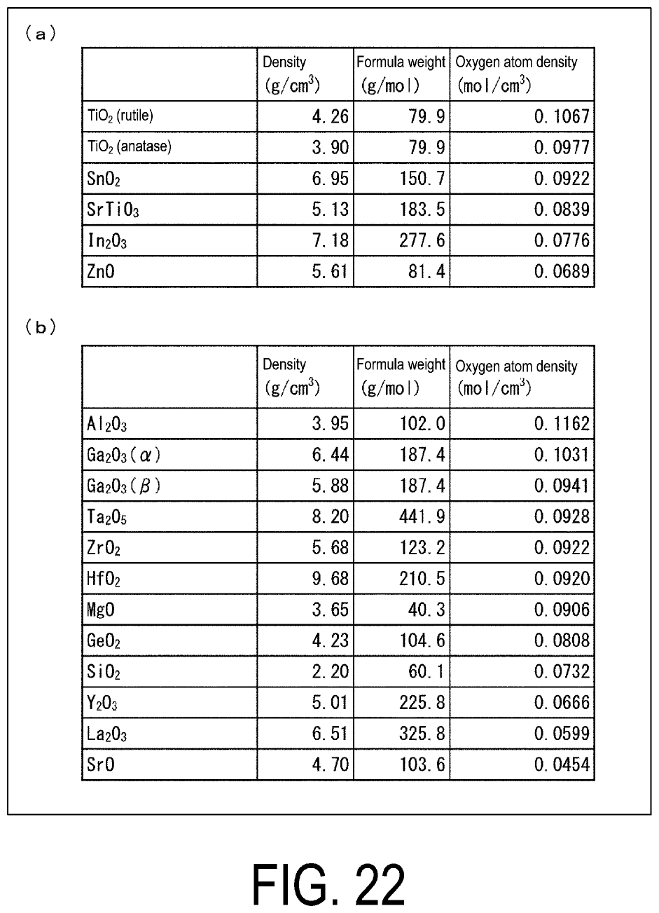

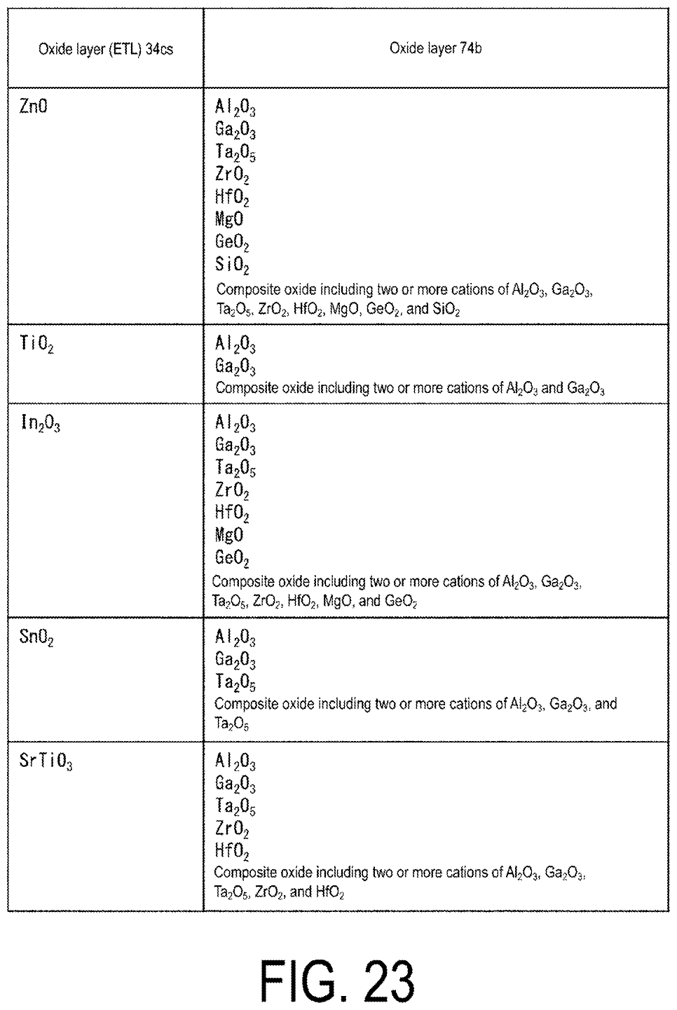

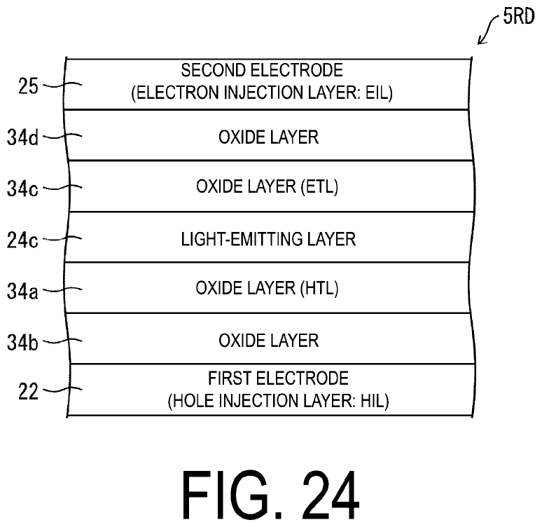

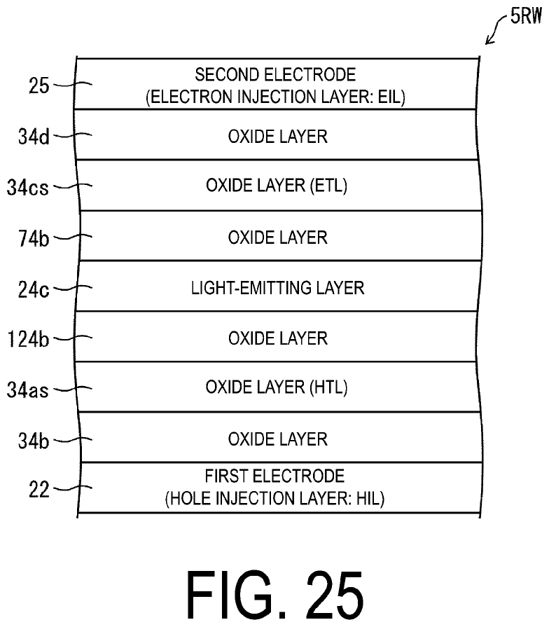

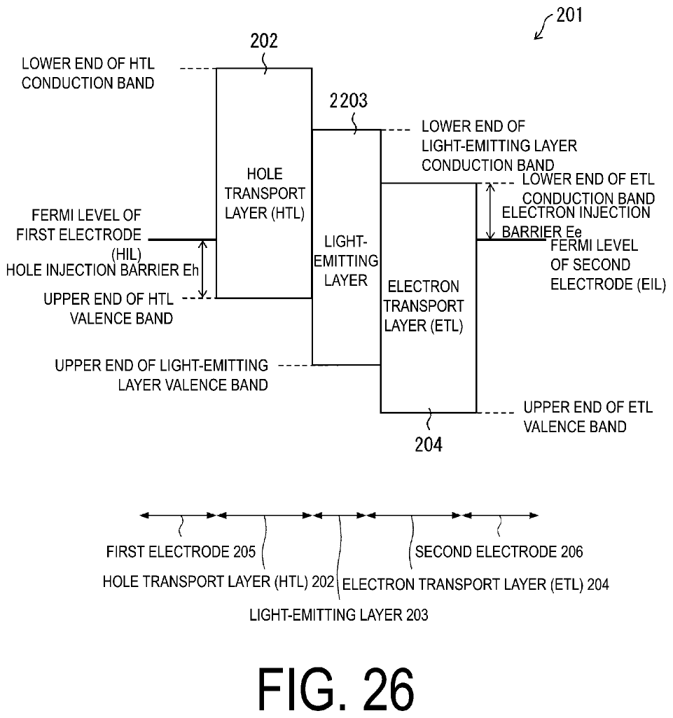

FIG. 2 is a cross-sectional view schematically illustrating a schematic configuration of a light-emitting element 5R according to the present embodiment.

As illustrated in FIG. 2, the light-emitting element 5R includes a first electrode (hole injection layer: HIL) 22, a second electrode (electron injection layer: EIL) 25, and a light-emitting layer 24c provided between the first electrode 22 and the second electrode 25. An oxide layer 34b (first oxide layer) and an oxide layer (hole transport layer: HTL) 34a (second oxide layer) are layered in this order between the first electrode 22 and the light-emitting layer 24c from the first electrode 22 side. The oxide layer 34a is a hole transport layer and is formed from a p-type semiconductor. Furthermore, the oxide layer 34a is preferably formed from an inorganic oxide. Furthermore, the oxide layer 34b is preferably formed from an inorganic oxide. Furthermore, the oxide layer 34b is preferably formed from an inorganic insulator. An electron transport layer (ETL) 24d is provided between the light-emitting layer 24c and the second electrode 25.

(a) of FIG. 4 is a diagram for describing the mechanism by which oxygen atoms move at the interface between the oxide layer (HTL) 34a and the oxide layer 34b. (b) of FIG. 4 is a diagram illustrating a state in which an electric dipole 1a is formed by movement of oxygen atoms at the interface between the oxide layer (HTL) 34a and the oxide layer 34b.

As illustrated in (a) of FIG. 4, since the oxygen atom density of the oxide layer (HTL) 34a is less than the oxygen atom density of the oxide layer 34b, when the oxide layer 34a and oxide layer 34b are formed so as to come into contact with one another, oxygen atoms easily move from the oxide layer 34b toward the oxide layer 34a. As oxygen atoms move, the oxygen holes become positively charged and the moving oxygen atoms become negatively charged.

Accordingly, as illustrated in (b) of FIG. 4, at the interface between the oxide layer 34a and the oxide layer 34b, the electric dipole 1a having a dipole moment of a component orientated in the direction from the oxide layer 34a to the oxide layer 34b is formed.

Note that the oxide layer 34a and the oxide layer 34b are preferably formed of inorganic oxides, and in this case, the long-term reliability is improved. That is, the luminous efficiency after aging is enhanced. In addition, the oxide layer 34b is preferably formed of an inorganic insulator, and in this case, long-term reliability is improved. That is, the luminous efficiency after aging is enhanced.

FIG. 1 is a diagram illustrating a schematic configuration of a display device 2 including the light-emitting element 5R.

As illustrated in FIG. 1, above the surface on one side of a substrate 10 of the display device 2, a resin layer 12, a barrier layer 3, a TFT layer 4, light-emitting elements 5R, 5G, 5B, and a sealing layer 6 are layered.

Examples of the material of the substrate 10 include polyethylene terephthalate (PET), a glass substrate, and the like, but the material is not limited thereto. In the present embodiment, in order for the display device 2 to be a flexible display device, PET is used as the material of the substrate 10, but if the display device 2 is a non-flexible display device, a glass substrate or the like may be used.

Note that in the present specification, the direction from the substrate 10 to the light-emitting elements 5R, 5G, and 5B in FIG. 1 is referred to as the “upward direction”, and the direction from the light-emitting layers 5R, 5G, and 5B to the substrate 10 is referred to as the “downward direction”. In other words, “lower layer” means a layer that is formed in a process prior to that of a comparison layer, and “upper layer” means a layer that is formed in a process after that of a comparison layer. That is, relatively, the layer closer to the substrate 10 is the lower layer, and the layer farther from the substrate 10 is the upper layer.

Examples of the material of the resin layer 12 include a polyimide resin, an epoxy resin, and a polyamide resin, but are not limited thereto. In the present embodiment, the display device 2 is made as a flexible display device by radiating the resin layer 12 through a support substrate (not illustrated) with laser light and lowering the bonding strength between the support substrate (not illustrated) and the resin layer 12, peeling (laser lift off (LLO) process) the support substrate (not illustrated) from the resin layer 12, and adhering the substrate 10 made of PET to the surface of the resin layer 12 where the support substrate (not illustrated) was peeled off from. However, in a case where the display device 2 is a non-flexible display device or when the display device 2 is a flexible display device made by a method other than the LLO process, the resin layer 12 is not necessary.

The barrier layer 3 is a layer that inhibits moisture or impurities from reaching the TFT layer 4 or the light-emitting elements 5R, 5G, and 5B when the display device 2 is being used, and can be constituted by a silicon oxide film, a silicon nitride film, or a silicon oxynitride film, or by a layered film of these, for example, formed using chemical vapor deposition (CVD).

The TFT layer 4 includes a semiconductor film 15, an inorganic insulating film 16 (a gate insulating film) above the semiconductor film 15, a gate electrode GE above the inorganic insulating film 16, an inorganic insulating film 18 above the gate electrode GE, a capacitance wiring line CE above the inorganic insulating film 18, an inorganic insulating film 20 above the capacitance wiring line CE, a source-drain wiring line SH including a source-drain electrode above the inorganic insulating film 20, and a flattening film 21 above the source-drain wiring line SH.

A thin film transistor element Tr (TFT element) as an active element is configured so as to include the semiconductor film 15, the inorganic insulating film 16 (gate insulating film), the gate electrode GE, the inorganic insulating film 18, the inorganic insulating film 20, and the source-drain wiring line SH.

The semiconductor film 15 is formed of low-temperature polysilicon (LTPS) or an oxide semiconductor, for example. Note that FIG. 1 illustrates the TFT that has a top gate structure including the semiconductor film 15 as a channel, but the TFT may have a bottom gate structure.

Each of the gate electrodes GE, the capacitance electrodes CE, the source-drain wiring line SH, the wiring lines, and the terminals is formed of, for example, a monolayer film or a layered film of metal including at least one of aluminum (Al), tungsten (W), molybdenum (Mo), tantalum (Ta), chromium (Cr), titanium (Ti), and copper (Cu).

The inorganic insulating films 16, 18, and 20 may be formed of, for example, a silicon oxide (SiOx) film, a silicon nitride (SiNx) film, or a silicon oxynitride film, or of a layered film of these, formed by CVD.

The flattening film (interlayer insulating film) 21 may be formed, for example, of a coatable photosensitive organic material, such as a polyimide resin and an acrylic resin.

In FIG. 2, only the schematic configuration of the light-emitting element 5R is illustrated as an example of the light-emitting elements 5R, 5G, and 5B included in the display device 2. However, as illustrated in FIG. 1, the display device 2 also includes the light-emitting element 5G and the light-emitting element 5B in addition to the light-emitting element 5R. The light-emitting element 5G has the same configuration as the light-emitting element 5R except that the light-emitting element 5G includes a light-emitting layer 24c′ of the second wavelength region as the light-emitting layer, and the light-emitting element 5B includes a light-emitting layer 24c″ of the third wavelength region as the light-emitting layer.

In the present embodiment, a case in which the light-emitting elements 5R, 5G, and 5B include the same oxide layer 34a, the same oxide layer 34b, and the same electron transport layer 24d is described, but the present disclosure is not limited thereto. For example, the oxide layer (HTL) 34a included in the light-emitting element 5R, the oxide layer (HTL) 34a included in the light-emitting element 5G, and the oxide layer (HTL) 34a included in the light-emitting element 5B may be three different types of oxide layers (HTL), or may be two different types of oxide layers (HTL). Also, the oxide layer 34b included in the light-emitting element 5R, the oxide layer 34b included in the light-emitting element 5G, and the oxide layer 34b included in the light-emitting element 5B may be three different types of oxide layers, or may be two different types of oxide layers. Also, the electron transport layer (ETL) 24d included in the light-emitting element 5R, the electron transport layer (ETL) 24d included in the light-emitting element 5G, and the electron transport layer (ETL) 24d included in the light-emitting element 5B may be three different types of electron transport layers (ETL), or may be two different types of electron transport layers (ETL).

The light-emitting layer 24c of the first wavelength region, the light-emitting layer 24c′ of the second wavelength region, and the light-emitting layer 24c″ of the third wavelength region are different in terms of the central wavelength of the light emitted, and in the present embodiment, a case is described where the light-emitting layer 24c of the first wavelength region emits a red color, the light-emitting layer 24c′ of the second wavelength region emits a green color, and the light-emitting layer 24c″ of the third wavelength region emits a blue color, but no such limitation is intended.

Also, in the present embodiment, a case is described where the display device 2 includes the three types of light-emitting elements 5R, 5G, 5B that emit red, green, and blue light. However, no such limitation is intended, and two types of light-emitting elements may be provided that emit light of different color. Alternatively, the display device 2 may be provided with one type of light-emitting element.

The light-emitting layer 24c of the first wavelength region, the light-emitting layer 24c′ of the second wavelength region, and the light-emitting layer 24c″ of the third wavelength region are light-emitting layers that include a quantum dot (nanoparticle) phosphor. Hereinafter, “phosphor” is omitted for the sake of simplicity and is simply referred to as quantum dots (nanoparticles). As the specific material of the quantum dot (nanoparticles), for example, any of CdSe/CdS, CdSe/ZnS, InP/ZnS, and CIGS/ZnS may be used, and the particle diameter of the quantum dots (nanoparticles) is around 3 to 10 nm. Note that, the light-emitting layer 24c of the first wavelength region, the light-emitting layer 24c′ of the second wavelength region, and the light-emitting layer 24c″ of the third wavelength region may use the quantum dots (nanoparticles) having different particle diameters or use quantum dots (nanoparticles) of different types from one another so that the light-emitting layers have center wavelengths of emitted light, which are different from one another.

In the present embodiment, a case has been described in which a light-emitting layer including quantum dots (nanoparticles) is used as the light-emitting layer 24c of the first wavelength region, the light-emitting layer 24c′ of the second wavelength region, and the light-emitting layer 24c″ of the third wavelength region. However, no such limitation is intended, and a light-emitting layer for OLED may be used as the light-emitting layer 24c of the first wavelength region, the light-emitting layer 24c′ of the second wavelength region, and the light-emitting layer 24c″ of the third wavelength region.

As illustrated in FIG. 1, each of the light-emitting elements 5R, 5G, and 5B has a configuration in which the first electrode 22; the oxide layer 34b; the oxide layer (HTL) 34a; any one of the light-emitting layer 24c of the first wavelength region, the light-emitting layer 24c′ of the second wavelength region, or the light-emitting layer 24c′ of the third wavelength region; the electron transport layer 24d; and the second electrode 25 are layered in this order. Note that the layering order of the light-emitting elements 5R, 5G, and 5B from the first electrode 22 to the second electrode 25 may be reversed. In this case, in FIG. 1, the second electrode 25 is disposed at the position of the first electrode 22, and the first electrode 22 is disposed at the position of the second electrode 25. Also, although the materials of the oxide layer 34b, the oxide layer (HTL) 34a, and the electron transport layer 24d of the light-emitting elements 5R, 5G, and 5B are as described later, the oxide layer 34b, the oxide layer (HTL) 34a, and the electron transport layer 24d of the light-emitting elements 5R, 5G, and 5B are not necessarily formed of common materials and may be formed of different materials. Note that each of the light-emitting elements 5R, 5G, and 5B is a subpixel SP of the display device 2.

The bank 23 that covers the edge of the first electrode 22 may be formed of, for example, a coatable photosensitive organic material such as a polyimide resin or an acrylic resin.

In the present embodiment, a case is described where the first electrode 22, the oxide layer 34b, the oxide layer 34a, the light-emitting layer 24c of the first wavelength region, the light-emitting layer 24c′ of the second wavelength region, the light-emitting layer 24c″ of the third wavelength region, and the electron transport layer 24d are formed into island shapes for each subpixel SP, with the second electrode 25 formed as a solid-like common layer, but no such limitation is intended. For example, the oxide layer 34b, the oxide layer 34a, the electron transport layer 24d, and the second electrode 25, excluding the first electrode 22, the light-emitting layer 24c of the first wavelength region, the light-emitting layer 24c′ of the second wavelength region, and the light-emitting layer 24c″ of the third wavelength region, may be formed as a solid-like common layer. Note that in this case, the bank 23 need not be provided.

In each of the light-emitting elements 5R, 5G, and 5B, the electron transport layer 24d may not be formed.

The first electrode 22 is formed of a conductive material, and has a function as a hole injection layer (HIL) for injecting a positive hole in the oxide layer 34a, which is a hole transport layer. The second electrode 25 is formed of a conductive material and has a function as an electron injection layer (EIL) for injecting an electron in the electron transport layer 24d.

At least one of the first electrode 22 or the second electrode 25 is made of a light-permeable material. Note that one of the first electrode 22 or the second electrode 25 may be formed from a light-reflective material. In a case where the display device 2 is a top-emitting display device, the second electrode 25 being an upper layer is formed of a light-permeable material, and the first electrode 22 being a lower layer is formed of a light-reflective material. In a case where the display device 2 is a bottom-emitting display device, the second electrode 25 being an upper layer is formed of a light-reflective material, and the first electrode 22 being a lower layer is formed of a light-permeable material. Note that in a case where the layering order from the first electrode 22 to the second electrode 25 is reversed, the display device 2 can be formed as a top-emitting display device by the first electrode 22, being an upper layer, being formed of a light-permeable material and the second electrode 25, being a lower layer, being formed of a light-reflective material, or can be formed as a bottom-emitting display device by the first electrode 22, being an upper layer, being formed of a light-reflective material and the second electrode 25, being a lower layer, being formed of a light-permeable material.

As the light-permeable material, a transparent conductive film material can be used, for example. Specifically, Indium Tin Oxide (ITO), Indium Zinc Oxide (IZO), ZnO, aluminum-doped zinc oxide (AZO), boron-doped zinc oxide (BZO), or the like may be used. These materials have a high transmittance of visible light, and thus luminous efficiency is improved.

As the light-reflective material, a material with high visible light reflectivity such as a metal material is preferably used. Specifically, for example, Al, Cu, Au, Ag, or the like may be used. These materials have a high reflectivity of visible light, and thus luminous efficiency is improved.

In addition, an electrode with light reflectivity obtained by making either one of the first electrode 22 or the second electrode 25 a layered body including a light-permeable material and a light-reflective material may be used.

Note that in the present embodiment, because the display device 2 is a top-emitting type, the second electrode 25 being an upper layer is formed of a light-permeable material, and the first electrode 22 being a lower layer is formed of a light-reflective material.

In particular, although described below, the oxygen atom density in the oxide layer 34a illustrated in FIGS. 1 and 2 is less than the oxygen atom density in the oxide layer 34b. In this case, oxygen atoms at the interface between oxide layer 34a and oxide layer 34b move in the direction of the oxide layer 34a from the oxide layer 34b, and an electric dipole is easily formed.

(a) of FIG. 5 is a diagram listing examples of an inorganic oxide forming a typical hole transport layer and the oxygen atom density thereof. (b) of FIG. 5 is a diagram listing examples of an exemplary inorganic oxide and the oxygen atom density thereof. Note that the inorganic oxides listed in (a) of FIG. 5 are p-type semiconductors, and the inorganic oxides listed in (b) of FIG. 5 are insulators.

FIG. 6 is a diagram listing material, for the oxide layer (HTL) 34a, selectable from examples of exemplary inorganic oxides forming the typical hole transport layer listed in (a) of FIG. 5, and material, for the oxide layer 34b, selectable from examples of exemplary inorganic oxides listed in (b) of FIG. 5.

FIG. 6 is a diagram listing examples of combinations of oxides forming the oxide layer (HTL) 34a and oxides forming the oxide layer 34b.

In the combinations listed in FIG. 6, the oxygen atom density in the oxide layer (HTL) 34a is less than the oxygen atom density in the oxide layer 34b. Thus, an electric dipole having a dipole moment including a component orientated in the direction from the oxide layer (HTL) 34a to the oxide layer 34b is formed at the interface between the oxide layer (HTL) 34a and the oxide layer 34b. As a result, efficient hole injection from the first electrode 22 to the oxide layer (HTL) 34a is possible, thus improving the luminous efficiency.

As listed in FIG. 6, in the present embodiment, the oxygen atom density in the oxide layer 34a is less than the oxygen atom density in the oxide layer 34b, and thus, for example, as the oxide layer 34a, an inorganic oxide including at least one of nickel oxide (for example, NiO) or copper aluminate (for example, CuAlO₂) can be used, and, as the oxide layer 34b, an inorganic oxide including at least one of aluminum oxide (for example, Al₂O₃), gallium oxide (for example, Ga₂O₃), tantalum oxide (for example, Ta₂O₅), zirconium oxide (for example, ZrO₂), hafnium oxide (for example, HfO₂), magnesium oxide (for example, MgO) or a composite oxide including two or more types of cations of these oxides can be used. The oxide layer 34b may be formed of any one of aluminum oxide, gallium oxide, tantalum oxide, zirconium oxide, hafnium oxide, magnesium oxide, or a composite oxide including two or more types of cations of these oxides. In addition, the oxide layer 34b may be formed of an oxide in which the most abundant element other than oxygen is any one of Al, Ga, Ta, Zr, Hf, or Mg.

Also, in similar manner, as the oxide layer (HTL) 34a, copper oxide, (copper(I) oxide) (for example, Cu₂O) can be used, and as the oxide layer 34b, an inorganic oxide including at least one of aluminum oxide (for example, Al₂O₃), gallium oxide (for example, Ga₂O₃), tantalum oxide (for example, Ta₂O₅), zirconium oxide (for example, ZrO₂), hafnium oxide (for example, HfO₂), magnesium oxide (for example, MgO), germanium oxide (for example, GeO₂), silicon oxide (for example, SiO₂), yttrium oxide (for example, Y₂O₃), lanthanum oxide (for example, La₂O₃), strontium oxide (for example, SrO), or a composite oxide including two or more types of cations of these oxides may be used. The oxide layer 34b may include any one of one of aluminum oxide, gallium oxide, tantalum oxide, zirconium oxide, hafnium oxide, magnesium oxide, germanium oxide, silicon oxide, yttrium oxide, lanthanum oxide, strontium oxide, or a composite oxide including two or more types of cations of these oxides. In addition, the oxide layer 34b may be formed of an oxide in which the most abundant element other than oxygen is any one of Al, Ga, Ta, Zr, Hf, Mg, Ge, Si, Y, La, or Sr.

Note that the combinations of oxides forming the oxide layer 34b and the oxide layer (HTL) 34a listed in FIG. 6 are merely examples. In the present embodiment, as long as the oxygen atom density in the oxide layer (HTL) 34a is less than the oxygen atom density in the oxide layer 34b, the present disclosure is not limited to these combinations.

By the oxygen atom density in the oxide layer (HTL) 34a being less than the oxygen atom density in the oxide layer 34b, the electric dipole 1a having a dipole moment of a component oriented in the direction of the oxide layer 34b from the oxide layer (HTL) 34a is more easily formed, and hole injection efficiency can be improved.

From the perspective of easily forming the electric dipole 1a (illustrated in (b) of FIG. 4) having a dipole moment of a component orientated from the oxide layer 34a toward the oxide layer 34b direction and improving the hole injection efficiency, the oxygen atom density in the oxide layer 34a is preferably 90% or less of the oxygen atom density in the oxide layer 34b, and the oxygen atom density in the oxide layer 34a is more preferably 80% or less of the oxygen atom density in the oxide layer 34b. Furthermore, the oxygen atom density in the oxide layer 34a is more preferably 75% or less, and even more preferably 70% or less of the oxygen atom density in the oxide layer 34b.

Also, the oxygen atom density in the oxide layer 34a is preferably 50% or greater of the oxygen atom density in the oxide layer 34b. In this case, it is possible to suppress the formation of recombination centers due to dangling bonds and the like at the interface between the oxide layer 34a and the oxide layer 34b.

Note that the oxygen atom density of the oxide layer in the present application is a unique value for the oxide layer 34a and for the oxide layer 34b and applies to the oxygen atom bulk density of the material forming the oxide layer 34a or oxide layer 34b. For example, for the materials listed in FIG. 5, the oxygen atom densities listed in FIG. 5 are applied.

The electron transport layer 24d illustrated in FIGS. 1 and 2 is a layer that transports electrons and inhibits the movement of holes. The material of the electron transport layer 24d is not particularly limited as long as it is an electron transport material, and a known electron transport material can be used. The electron transport material may be an oxide or a material other than an oxide. As the electron transport material, ZnO, TiO₂, SrTiO₃, and the like can be used, or nanoparticles can be used. An n-type semiconductor, for example, is preferably used as the electron transport material.

Also, as the electron transporting material, an organic material, such as TPBi(1,3,5-Tris(1-phenyl-1Hbenzimidazol-2-yl)benzene), Alq3(Tris(8-hydroxy-quinolinato) aluminum), BCP (2,9-Dimethyl-4,7-diphenyl-1,10-phenanthroline), and the like, may be used.

As illustrated in FIG. 1, the sealing layer 6 is a light transmissive layer, and includes a first inorganic sealing film 26 that covers the second electrode 25, an organic sealing film 27 that is formed on a side above the first inorganic sealing film 26, and a second inorganic sealing film 28 that covers the organic sealing film 27. The sealing layer 6 covering the light-emitting elements 5R, 5G, 5B inhibits foreign matters such as water and oxygen from penetrating into the light-emitting elements 5R, 5G, 5B.

Each of the first inorganic sealing film 26 and the second inorganic sealing film 28 may be constituted by, for example, a silicon oxide film, a silicon nitride film, or a silicon oxynitride film, or a layered film of these films formed by CVD. The organic sealing film 27 is a light transmissive organic film which is thicker than the first inorganic sealing film 26 and the second inorganic sealing film 28, and can be formed of a coatable photosensitive organic material such as a polyimide resin or an acrylic resin.

(a) of FIG. 3 is an energy band diagram for describing a hole injection barrier between the first electrode 22 and the oxide layer (HTL) 34a in the light-emitting element according to a comparative example. (b) of FIG. 3 is an energy band diagram for describing a hole injection barrier between the first electrode 22 and the oxide layer (HTL) 34a in the light-emitting element 5.

As illustrated in (a) of FIG. 3, in the light-emitting element in which the first electrode 22 and the oxide layer (HTL) 34a come into direct contact, the energy difference ΔE_{F1} between the Fermi level E_{F1} of the first electrode 22 and the upper end of the valence band (HTL valence band) of the oxide layer (HTL) 34a is large. Because the energy difference ΔE_{F1} is the height of the hole injection barrier, efficient hole injection from the first electrode 22 to the oxide layer (HTL) 34a cannot be achieved in the light-emitting element illustrated in (a) of FIG. 3. Thus, efficient hole injection to the light-emitting layer 24c cannot be achieved.

On the other hand, as illustrated in (b) of FIG. 3, the light-emitting element 5R according to the present embodiment includes, between the first electrode 22 and the light-emitting layer 24c, the oxide layer 34b and the oxide layer (HTL) 34a layered adjacent to one another in this order from the first electrode 22 side, and as described above, the oxygen atom density of the oxide layer (HTL) 34a is less than the oxygen atom density of the oxide layer 34b. Thus, the oxygen atoms can easily move from the oxide layer 34b toward the oxide layer (HTL) 34a at the interface between the oxide layer 34b and the oxide layer (HTL) 34a, and, at the interface, the electric dipole 1a having a dipole moment of a component orientated in the direction from the oxide layer (HTL) 34a to the oxide layer 34b is formed.

When the electric dipole 1a is formed in this manner, as illustrated in (b) of FIG. 3, a vacuum level shift caused by the electric dipole 1a occurs at the interface between the oxide layer 34b and the oxide layer (HTL) 34a, which is the interface where the electric dipole 1a is formed. As a result, as illustrated in (b) of FIG. 3, at the interface between the oxide layer 34b and the oxide layer (HTL) 34a, the position of the band on the first electrode 22 side moves downward with respect to the position of the band on the second electrode 25 side (oxide layer (HTL) 34a side). In other words, the position of the band of the first electrode 22 and the position of the band of the oxide layer 34b move further downward (band shift) with respect to the position of the band of the oxide layer (HTL) 34a and the position of the band of the light-emitting layer 24c. Note that in (b) of FIG. 3, the position of the Fermi level E_{F1} of the first electrode 22 before the vacuum level shift due to the electric dipole 1a is indicated by a dot-dash line, and the position of the Fermi level E_{F1}′ of the first electrode 22 after the vacuum level shift due to the electric dipole 1a is indicated by a solid line. Also, the position of the band of the oxide layer 34b before the vacuum level shift due to the electric dipole 1a is indicated by a dot-dash line, and the position of the band of the oxide layer 34b after the vacuum level shift due to the electric dipole 1a is indicated by a solid line. In addition, the vacuum level after band shift is indicated by a broken line at the top of (b) of FIG. 3.

Specifically, when the electric dipole 1a is formed, the Fermi level E_{F1} of the first electrode 22 moves to E_{F1}′. By this movement, the energy difference ΔE_{F1} between the Fermi level E_{F1} of the first electrode 22 and the upper end of the valence band of the oxide layer (HTL) 34a (upper end of the HTL valence band) (see (a) of FIG. 3) becomes the energy difference ΔE_{F1}′ between the Fermi level E_{F1}′ of the first electrode 22 and the upper end of the valence band of the oxide layer (HTL) 34a (upper end of the HTL valence band). As a result, the energy difference ΔE_{F1}′ after formation of the electric dipole 1a (the hole injection barrier height from the first electrode 22 to the oxide layer (HTL) 34a after formation of the electric dipole 1a) is less than the energy difference ΔE_{F1} (the hole injection barrier height from the first electrode 22 to the oxide layer (HTL) 34a in a case where the oxide layer 34b is not formed).

In a case where the film thickness of the oxide layer 34b is sufficiently thin in the light-emitting element 5R, because the holes have conductivity via tunneling of the oxide layer 34b, the hole barrier height between the first electrode 22 and the oxide layer (HTL) 34a is effectively the energy difference ΔE_{F1}′ between the Fermi level E_{F1}′ of the first electrode 22 and the upper end of the valence band of the oxide layer (HTL) 34a (upper end of the HTL valence band). According to the present embodiment, by forming the oxide layer 34b and the oxide layer (HTL) 34a in this manner, efficient hole injection from the first electrode 22 to the oxide layer (HTL) 34a can be achieved. As a result, efficient hole injection from the first electrode 22 to the light-emitting layer 24c of the first wavelength region is possible, thus improving the luminous efficiency.

The film thickness of the oxide layer 34b is preferably is from 0.2 nm to 5 nm. By setting the film thickness to be 5 nm or less, hole tunneling can be efficient. Additionally, by setting the film thickness to be 0.2 nm or greater, a sufficiently large dipole moment can be obtained. Furthermore, the film thickness is preferably from 0.8 nm to 3 nm or less. In this case, more efficient hole injection is possible.

The oxide layer (HTL) 34a is a hole transport layer and is formed from a semiconductor. The oxide layer (HTL) 34a is preferably formed from a p-type semiconductor. In this case, the oxide layer (HTL) 34a includes a band gap indicated by the semiconductor, and the carrier is a hole. Additionally, the hole density of the oxide layer (HTL) 34a, which is the hole transport layer, is greater than the hole density in the oxide layer 34b. Note that the oxide layer (HTL) 34a is preferably formed from a p-type semiconductor. Also, the carrier density (electron density) of the oxide layer (HTL) 34a is preferably 1×10¹⁵ cm³ or greater. Also, the carrier density (electron density) of the oxide layer (HTL) 34a is preferably 3×10¹⁷ cm³ or less.

Note that in the example illustrated in (b) of FIG. 3, an example is given of a case in which the Fermi level E_{F1}′ of the first electrode 22 after a band shift has been caused by formation of the electric dipole 1a is positioned above the upper end of the valence band of the oxide layer (HTL) 34a (upper end of HTL valence band). However, the Fermi level E_{F1}′ of the first electrode 22 after a band shift may be positioned below the upper end of the valence band of the oxide layer (HTL) 34a (upper end of HTL valence band). Also, the oxygen atom density in the oxide layer (HTL) 34a is preferably 90% or less of the oxygen atom density in the oxide layer 34b. In this case, efficient hole injection is possible. Furthermore, the oxygen atom density in the oxide layer (HTL) 34a is preferably 80% or less of the oxygen atom density in the oxide layer 34b, and in this case, ΔE_{F1}′ becomes even smaller, and more efficient hole injection is possible. Furthermore, the oxygen atom density in the oxide layer (HTL) 34a is more preferably 75% or less, and even more preferably 70% or less of the oxygen atom density in the oxide layer 34b. In this case, ΔE_{F1}′ becomes even smaller, and more efficient hole injection is possible.

In the example of (b) of FIG. 3, the energy difference Ed1 between the vacuum level and the Fermi level E_{F1}′ of the first electrode 22 is less than the ionization potential IP2 of the oxide layer (HTL) 34a, and the ionization potential IP2 of the oxide layer (HTL) 34a is less than the ionization potential IP1 of the oxide layer 34b. Note that the energy difference Ed1 between the vacuum level after band shift and Fermi level E_{F1}′ of the first electrode 22 is the same as the energy difference between the vacuum level before band shift and the Fermi level E_{F1} of the first electrode 22, and is a work function of the first electrode 22. Thus, the energy difference Ed1 between the vacuum level after band shift and the Fermi level E_{F1}′ of the first electrode 22 is a material specific value for the first electrode 22 with or without band shift.

As illustrated in (b) of FIG. 3, the energy difference between the lower end of the conduction band′ of the oxide layer 34b and the upper end of the valence band′ of the oxide layer 34b (=the energy difference between the lower end of the conduction band of the oxide layer 34b and the upper end of the valence band of the oxide layer 34b) is greater than the energy difference between the lower end of the HTL conduction band and the upper end of the HTL valence band in the oxide layer (HTL) 34a. Thus, the oxide layer 34b has a smaller carrier density and better insulating properties than the oxide layer (HTL) 34a. Accordingly, hole conduction by tunneling occurs in the oxide layer 34b. As described above, the hole density in the oxide layer (HTL) 34a, which is the hole transport layer, is greater than the hole density in the oxide layer 34b, and holes are efficiently injected from the first electrode 22 to the oxide layer (HTL) 34a via tunneling of the oxide layer 34b and, thereafter, are conducted through the oxide layer (HTL) 34a and injected into the light-emitting layer 24c of the first wavelength region.

Note that in the example of (b) of FIG. 3, only the light-emitting element 5R including the light-emitting layer 24c of the first wavelength region has been described, but with the light-emitting element 5G including the light-emitting layer 24c′ of the second wavelength region and the light-emitting element 5B including the light-emitting layer 24c″ of the third wavelength region also, efficient hole injection is possible in a similar manner to the light-emitting element 5R including the light-emitting layer 24c of the first wavelength region due to the forming the oxide layer 34b and the oxide layer (HTL) 34a.

### First Modification Example

(a) of FIG. 7 is a diagram illustrating a schematic configuration of a light-emitting element 5RE, and (b) of FIG. 7 is a diagram illustrating a schematic configuration of a light-emitting element 5RF.

In the light-emitting element 5RE illustrated in (a) of FIG. 7, the upper surface of the oxide layer 34b′ (first oxide layer) in contact with the oxide layer (HTL) 34a (second oxide layer) includes grains. Also, in the light-emitting element 5RF illustrated in (b) of FIG. 7, the oxide layer (HTL) 34a′ is amorphous, and the upper surface of the oxide layer 34b′ in contact with the oxide layer (HTL) 34a′ includes grains. Materials similar to that used for the oxide layer (HTL) 34a and the oxide layer 34b described above can be used for the oxide layer (HTL) 34a′ and the oxide layer 34b′.

In the light-emitting element 5RE illustrated in (a) of FIG. 7, the first electrode 22 is below the light-emitting layer 24c of the first wavelength region, and the second electrode 25 is above the light-emitting layer 24c of the first wavelength region, and at least a portion of the upper surface of the oxide layer 34b′ in contact with the oxide layer (HTL) 34a is polycrystallized. That is, the upper surface of the oxide layer 34b′ includes grains (grains). In this manner, by the upper surface of the oxide layer 34b′ including grains, the area of the interface between the upper surface of the oxide layer 34b′ and the oxide layer (HTL) 34a is increased, allowing the electric dipole to be more efficiently formed, and with the light-emitting element 5RE, effective hole injection from the first electrode 22 to the oxide layer (HTL) 34a is possible. As a result, with the light-emitting element 5RE, efficient hole injection from the first electrode 22 to the light-emitting layer 24c of the first wavelength region is possible, thus improving the luminous efficiency.

In the light-emitting element 5RF illustrated in (b) of FIG. 7, the first electrode 22 is below the light-emitting layer 24c of the first wavelength region, and the second electrode 25 is above the light-emitting layer 24c of the first wavelength region. At least a portion of the upper surface of the oxide layer 34b′ (first oxide layer) in contact with the oxide layer (HTL) 34a′ (second oxide layer) is polycrystallized. That is, the upper surface of the oxide layer 34b′ includes grains (grains). The oxide layer (HTL) 34a′ is formed of an amorphous oxide.

By making the oxide layer (HTL) 34a′ an amorphous oxide, the film thickness uniformity of the oxide layer (HTL) 34a′ can be improved, and thus good coverage with respect to the oxide layer 34b′ having grains is obtained. In addition, since the film thickness uniformity of the oxide layer (HTL) 34a′ can be improved, the uniformity of hole conduction in the oxide layer (HTL) 34a′ can be improved. By the upper surface of the oxide layer 34b′ including grains, the area of the interface between the upper surface of the oxide layer 34b′ and the oxide layer (HTL) 34a′ is increased, allowing the electric dipole to be more efficiently formed. Thus, efficient hole injection from the first electrode 22 to the oxide layer (HTL) 34a′ is possible with the light-emitting element 5RF. As a result, with the light-emitting element 5RF, efficient hole injection from the first electrode 22 to the light-emitting layer 24c of the first wavelength region is possible, thus improving the luminous efficiency.

Note that in the present embodiment, a portion including the upper surface of the oxide layer 34b′ is heat treated using laser light, and the upper surface of the oxide layer 34b′ is polycrystallized, but the present disclosure is not limited thereto. Also, as long as the oxygen atom density of the oxide layer (HTL) 34a, 34a′ is less than the oxygen atom density of the oxide layer 34b′, the method of polycrystallizing the oxide layer 34b′ and the type of polycrystalline oxide forming the oxide layer 34b′ are not particularly limited.

Furthermore, in the present embodiment, a case has been described in which grains are formed by polycrystallizing the upper surface of the oxide layer 34b′, but the present disclosure is not limited thereto, and grains may be formed on at least a portion of the upper surface of the oxide layer 34b′ using spontaneous nucleation, for example, via sputtering, CVD, or the like.

Furthermore, in the present embodiment, a case in which the upper surface of the oxide layer 34b′ is polycrystallized has been described as an example, but the present disclosure is not limited thereto, and the entire oxide layer 34b′ may be formed of a polycrystalline oxide.

Furthermore, in the present embodiment, a case in which the upper surface of the oxide layer 34b′ includes grains has been described as an example, but the present disclosure is not limited thereto, and the entire oxide layer 34b′ may include grains.

Note that, at the upper surface of the oxide layer 34b′, grains may be distributed discretely. Grains may also be crystal grains including crystals or may include an amorphous phase.

(c) of FIG. 7 is a diagram illustrating a schematic configuration of the light-emitting element 5RG.

In the light-emitting element 5RG illustrated in (c) of FIG. 7, the second electrode 25, the electron transport layer 24d, the light-emitting layer 24c of the first wavelength region, the oxide layer (HTL) 34a″ (second oxide layer), oxide layer 34b (first oxide layer), and the first electrode 22 are layered in this order from the lower layer side to the upper layer side, and at least the upper surface of the oxide layer (HTL) 34a″ includes grains. Materials similar to that used for the oxide layer (HTL) 34a and the oxide layer (HTL) 34a′ described above can be used for the oxide layer (HTL) 34a″.

In the light-emitting element 5RG illustrated in (c) of FIG. 7, the second electrode 25 formed of a light-permeable material is below the first electrode 22 formed of a light-reflective material, allowing the light-emitting element 5RG to be used in a bottom-emitting display device. Of course, the present disclosure is not limited thereto, and, in a similar manner to the light-emitting element 5R, in the light-emitting element 5RG, the first electrode 22 and/or the second electrode 25 may be formed of a light-permeable material, and the first electrode 22 or the second electrode 25 may be formed of a light-reflective material. Note that in the display device including the light-emitting element 5RG, the first electrode 22 is formed as a solid-like common layer, and the second electrode 25 electrically connected to the thin film transistor element Tr (TFT element) is formed into island shapes for each subpixel.

In the light-emitting element 5RG, the first electrode 22 is above the light-emitting layer 24c of the first wavelength region, and the second electrode 25 is below the light-emitting layer 24c of the first wavelength region. At least the upper surface of the oxide layer 34a″ in contact with the oxide layer 34b includes grains. In the oxide layer 34a″, grains may be distributed discretely. Grains may also be crystal grains containing crystals or may include an amorphous phase.

A case in which, in the light-emitting element 5RG, the upper surface of the oxide layer 34a″ in contact with oxide layer 34b includes grains has been described as an example, but the present disclosure is not limited thereto, and the entire oxide layer 34a″ may include grains.

Note that in the present embodiment, in the light-emitting element 5RG, a portion including the upper surface of the oxide layer 34a″ is heat treated using laser light, and at least a portion of the upper surface of the oxide layer 34a″ is polycrystallized and the upper surface of the oxide layer 34a″ includes grains, but the present disclosure is not limited thereto. Grains can also be formed using spontaneous nucleation, for example, via sputtering, CVD, and the like. Also, as long as the oxygen atom density of the oxide layer (HTL) 34a″ is less than the oxygen atom density of the oxide layer 34b, the method of forming the oxide layer 34a″ including grains and the type of the oxide layer 34a″ are not particularly limited. The entire oxide layer 34a″ may be polycrystalline.

As described above, by the upper surface of the oxide layer (HTL) 34a″ in contact with the oxide layer 34b including grains, the area of the interface between the oxide layer 34b and the upper surface of the oxide layer 34a″ is increased, allowing the electric dipole to be more efficiently formed. Accordingly, efficient hole injection from the first electrode 22 to the oxide layer (HTL) 34a″ is possible with the light-emitting element 5RG. As a result, with the light-emitting element 5RG, efficient hole injection from the first electrode 22 to the light-emitting layer 24c of the first wavelength region is possible, thus improving the luminous efficiency.

The oxide layer 34b may be an amorphous oxide. By the oxide layer 34b being an amorphous oxide, the film thickness uniformity of the oxide layer 34b can be improved. This allows the uniformity of hole conductivity due to tunneling of the oxide layer 34b to be improved. Also, even in a case where the oxide layer 34b is an amorphous oxide, the upper surface of the oxide layer 34a″ includes grains. Thus, the area of the interface with the amorphous oxide is increased, allowing the electric dipole to be more efficiently formed. Accordingly, efficient hole injection from the first electrode 22 to the oxide layer (HTL) 34a″ is possible with the light-emitting element 5RG. As a result, with the light-emitting element 5RG, efficient hole injection from the first electrode 22 to the light-emitting layer 24c of the first wavelength region is possible, thus improving the luminous efficiency.

(d) of FIG. 7 is a diagram illustrating a schematic configuration of the light-emitting element 5RH.

In the light-emitting element 5RH illustrated in (d) of FIG. 7, the oxide layer (HTL) 34a′″ (second oxide layer) in contact with the oxide layer 34b (first oxide layer) is formed into island shapes. Materials similar to that used for the oxide layer (HTL) 34a, the oxide layer (HTL) 34a′, and the oxide layer (HTL) 34a″ described above can be used for the oxide layer (HTL) 34a′″.

In a similar manner to the light-emitting element 5R illustrated in FIG. 2, in the light-emitting element 5RH illustrated in (d) of FIG. 7, the first electrode 22 and/or the second electrode 25 may be formed of a light-permeable material, and the first electrode 22 or the second electrode 25 may be formed of a light-reflective material. Note that in the display device including the light-emitting element 5RH, the first electrode 22 is formed as a solid-like common layer, and the second electrode 25 electrically connected to the thin film transistor element Tr (TFT element) is formed into island shapes for each subpixel.

In the light-emitting element 5RH, the first electrode 22 is above the light-emitting layer 24c of the first wavelength region, and the second electrode 25 is below the light-emitting layer 24c of the first wavelength region. Furthermore, the oxide layer (HTL) 34a′″ in contact with the oxide layer 34b is formed into island shapes. The oxide layer (HTL) 34a′″ can be formed into island shapes using spontaneous nucleation using a sputtering method, a CVD method, or the like. Furthermore, after forming the thin film, the thin film may be processed into island shapes by etching or the like. The patterning process may also be performed such that the surface roughness of the oxide layer (HTL) 34a′″ increases when the oxide layer (HTL) 34a′″ is patterned to form island shapes.

The oxygen atom density of the oxide layer (HTL) 34a′″ is less than the oxygen atom density of the oxide layer 34b. By the oxide layer (HTL) 34a′″ being formed into island shapes, the area of the interface between the oxide layer (HTL) 34a′″ and the oxide layer 34b is increased, allowing the electric dipole to be more efficiently formed. Accordingly, efficient hole injection from the first electrode 22 to the oxide layer (HTL) 34a″ is possible with the light-emitting element 5RH. As a result, with the light-emitting element 5RH, efficient hole injection from the first electrode 22 to the light-emitting layer 24c of the first wavelength region is possible, thus improving the luminous efficiency.

The oxide layer 34b may be an amorphous oxide. By the oxide layer 34b being an amorphous oxide, the film thickness uniformity of the oxide layer 34b can be improved. This allows the uniformity of hole conductivity due to tunneling of the oxide layer 34b to be improved. Also, even in a case where the oxide layer 34b is an amorphous oxide, the oxide layer (HTL) 34a′″ is formed into island shapes. Thus, the area of the interface with the amorphous oxide is increased, allowing the electric dipole to be more efficiently formed. Accordingly, efficient hole injection from the first electrode 22 to the oxide layer (HTL) 34a″ is possible with the light-emitting element 5RH. As a result, with the light-emitting element 5RH, efficient hole injection from the first electrode 22 to the light-emitting layer 24c of the first wavelength region is possible, thus improving the luminous efficiency.

Note that, as illustrated in FIG. 2, (a) of FIGS. 7, and (b) of FIG. 7, in a case where the first electrode 22 is below the light-emitting layer 24c of the first wavelength region and the second electrode 25 is above the light-emitting layer 24c of the first wavelength region, of the oxide layers (HTL) 34a, 34a′ and the oxide layers 34b, 34b′, at least the oxide layers (HTL) 34a, 34a′ is preferably a continuous film. Also, as illustrated in (c) of FIGS. 7 and (d) of FIG. 7, in a case where the first electrode 22 is above the light-emitting layer 24c of the first wavelength region and the second electrode 25 is below the light-emitting layer 24c of the first wavelength region, of the oxide layers (HTL) 34a″, 34a′″ and the oxide layer 34b, at least the oxide layer 34b is preferably a continuous film. In other words, of the oxide layers (HTL) 34a, 34a′, 34a″, 34a′″ and oxide layers 34b, 34b′, at least the film formed from after is preferably a continuous film. Also, in this example, the continuous film is a dense film having a porosity of less than 1%. In other words, the continuous film is a film with substantially no voids. Note that the continuous film can be formed via, for example, sputtering, vapor deposition, CVD (chemical vapor deposition), PVD (physical vapor deposition), or the like. Note that a film made by applying microparticles such as nanoparticles cannot be a continuous film because of the porous nature due to a large number of voids being formed between the microparticles.

In the light-emitting element 5RE illustrated in (a) of FIG. 7, by forming the oxide layer (HTL) 34a, which is the film (upper layer side film) that is formed after, as a continuous film, the contact area between the oxide layer (first oxide layer) 34b′ and the oxide layer (HTL) (second oxide layer) 34a becomes large, so it is possible to efficiently form an electric dipole. As a result, the luminous efficiency is improved. Also, in the light-emitting element 5RF illustrated in (b) of FIG. 7, by forming the oxide layer (HTL) 34a′, which is the film (upper layer side film) that is formed after, as a continuous film, the contact area between the oxide layer (first oxide layer) 34b′ and the oxide layer (HTL) (second oxide layer) 34a′ becomes large, so it is possible to efficiently form an electric dipole. As a result, the luminous efficiency is improved. Also, in the light-emitting element 5RG illustrated in (c) of FIG. 7, by forming the oxide layer 34b, which is the film (upper layer side film) that is formed after, as a continuous film, the contact area between the oxide layer (HTL) (second oxide layer) 34a″ and the oxide layer (first oxide layer) 34b becomes large, so it is possible to efficiently form an electric dipole. As a result, the luminous efficiency is improved. Also, in the light-emitting element 5RH illustrated in (d) of FIG. 7, by forming the oxide layer 34b, which is the film (upper layer side film) that is formed after, as a continuous film, the contact area between the oxide layer (second oxide layer) 34a′″ and the oxide layer (first oxide layer) 34b becomes large, so it is possible to efficiently form an electric dipole. As a result, the luminous efficiency is improved.

Note that the oxide layers (HTL) 34a, 34a′, 34a″, 34a′″ and oxide layers 34b, 34b′ may be formed via, for example, sputtering, vapor deposition, CVD (chemical vapor deposition), PVD (physical vapor deposition), or the like. The oxide layers (HTL) 34a, 34a′, 34a″, 34a′″ and the oxide layers 34b and 34b′ formed via such a method have a large contact area due to both layers in contact with one another being continuous films, allowing the electric dipole 1a to be densely formed.

### Second Embodiment

Next, the second embodiment of the present invention will be described with reference to FIGS. 8 to 13. In the light-emitting elements 5RA, 5RI, 5RJ, 5RK, 5RL in the present embodiment, an oxide layer (ETL) 34c, 34c′, 34c″, 34c′″(first oxide layer) formed from an n-type semiconductor and the oxide layer 34d, 34d′ (second oxide layer) are layered in this order from the light-emitting layer 24c side between the second electrode 25 and the light-emitting layer 24c of the first wavelength region. This is different from the first embodiment. For convenience of explanation, components having the same functions as those described in diagrams of the first embodiment are appended with the same reference signs, and descriptions thereof may be omitted.

In the display device 2 according to the first embodiment illustrated in FIG. 1, the display device of the present embodiment is provided with any one of the light-emitting elements 5RA, 5RI, 5RJ, 5RK, and 5RL illustrated in FIGS. 8 and 13 instead of the light-emitting element 5R illustrated in FIG. 2. The display device according to the present embodiment may include, instead of 5G and 5B in the display device 2 of the first embodiment illustrated in FIG. 1, light-emitting elements with light emission wavelengths appropriately changed by changing the material of the light-emitting layer 24c of the light-emitting element 5RA, 5RI, 5RJ, 5RK, 5RL.

FIG. 8 is a cross-sectional view schematically illustrating a schematic configuration of a light-emitting element 5RA according to the present embodiment.

As illustrated in FIG. 8, the light-emitting element 5RA includes a first electrode (hole injection layer: HIL) 22, a second electrode (electron injection layer: EIL) 25, and a light-emitting layer 24c provided between the first electrode 22 and the second electrode 25. An oxide layer (ETL) 34c (first oxide layer) and an oxide layer 34d (second oxide layer) are layered in this order between the second electrode 25 and the light-emitting layer 24c from the first electrode 22 side. In other words, the oxide layer 34d is provided in contact with the oxide layer (ETL) 34c. The oxide layer 34c is an electron transport layer and is formed from a semiconductor. The oxide layer 32c is preferably formed from an n-type semiconductor. In this case, the oxide layer (ETL) 34c includes a band gap of a region indicated by the semiconductor, and the carrier is an electron. Furthermore, the oxide layer (ETL) 34c is preferably formed from an inorganic oxide. Furthermore, the oxide layer 34d is preferably formed from an inorganic oxide. Furthermore, the oxide layer 34d is preferably formed from an inorganic insulator. Note that the hole transport layer (HTL) 24a is provided between the light-emitting layer 24c and the first electrode 22.

Note that the hole transport layer (HTL) 24a illustrated in FIG. 8 is a layer that transports holes and inhibits the movement of electrons. The material of the hole transport layer (HTL) 24a is not particularly limited as long as it is a hole transport material, and a known hole transport material can be used. The hole transport material may be an oxide or a material other than an oxide. Examples of the hole transport material include NiO, CuAlO₂, PEDOT: PSS, PVK, and the like. Nanoparticles may also be used. An n-type semiconductor, for example, is preferably used as the hole transport material.

(a) of FIG. 10 is a diagram for describing the mechanism by which oxygen atoms move at the interface between the oxide layer (ETL) 34c and the oxide layer 34d. (b) of FIG. 10 is a diagram illustrating a state in which an electric dipole 1b is formed by movement of oxygen atoms at the interface between the oxide layer (ETL) 34c and the oxide layer 34d.

As illustrated in (a) of FIG. 10, since the oxygen atom density of the oxide layer 34d is less than the oxygen atom density of the oxide layer (ETL) 34c, when the oxide layer 34c and oxide layer 34d are formed so as to come into contact with one another, oxygen atoms easily move from the oxide layer 34c toward the oxide layer 34d. As oxygen atoms move, the oxygen holes become positively charged and the moving oxygen atoms become negatively charged.

Accordingly, as illustrated in (b) of FIG. 10, at the interface between the oxide layer 34c and the oxide layer 34d, the electric dipole 1b having a dipole moment of a component orientated in the direction from the oxide layer 34c to the oxide layer 34d is formed.

Note that the oxide layer 34c and the oxide layer 34d are preferably formed of inorganic oxides, and in this case, the long-term reliability is improved. That is, the luminous efficiency after aging is enhanced. In addition, the oxide layer 34d is preferably formed of an inorganic insulator, and in this case, long-term reliability is improved. That is, the luminous efficiency after aging is enhanced.

(a) of FIG. 9 is an energy band diagram for describing an electron injection barrier between the second electrode 25 and the oxide layer (ETL) 34c in the light-emitting element according to a comparative example. (b) of FIG. 9 is an energy band diagram for describing an electron injection barrier between the second electrode 25 and the oxide layer (ETL) 34c in the light-emitting element 5RA illustrated in FIG. 8.

As illustrated in (a) of FIG. 9, an energy difference ΔE_{F2} between the lower end of the conduction band (ETL conduction band) of the oxide layer (ETL) 34c and the Fermi level E_{F2} of the second electrode 25 in the light-emitting element directly in contact with the second electrode 25 and the oxide layer (ETL) 34c is large. Because the energy difference ΔE_{F2} is the height of the electron injection barrier, efficient electron injection from the second electrode 25 to the oxide layer (ETL) 34c cannot be achieved in the light-emitting element illustrated in (a) of FIG. 9. Thus, efficient electron injection to the light-emitting layer 24c cannot be achieved.

On the other hand, as illustrated in (b) of FIG. 9, the light-emitting element 5RA according to the present embodiment includes, between the second electrode 25 and the light-emitting layer 24c, the oxide layer (ETL) 34c and the oxide layer 34d layered adjacent to one another in this order from the first electrode 22 side, i.e., the light-emitting layer 24c side, and, as described above, the oxygen atom density in the oxide layer 34d is less than the oxygen atom density in the oxide layer (ETL) 34c. Thus, the oxygen atoms can easily move from the oxide layer (ETL) 34c toward the oxide layer 34d at the interface between the oxide layer (ETL) 34c and the oxide layer 34d, and, at the interface, the electric dipole 1b having a dipole moment of a component orientated in the direction from the oxide layer 34d to the oxide layer (ETL) 34c is formed.

When the electric dipole 1b is formed in this manner, as illustrated in (b) of FIG. 9, a vacuum level shift caused by the electric dipole 1b occurs at the interface between the oxide layer (ETL) 34c and the oxide layer 34d, which is the interface where the electric dipole 1b is formed. As a result, as illustrated in (b) of FIG. 9, at the interface between the oxide layer (ETL) 34c and the oxide layer 34d, the position of the band on the second electrode 25 side moves upward with respect to the position of the band on the first electrode 22 side (oxide layer (ETL) 34c side). In other words, the position of the band of the second electrode 25 and the position of the band of the oxide layer 34d move further upward (band shift) with respect to the position of the band of the oxide layer (ETL) 34c and the position of the band of the light-emitting layer 24c. Note that in (b) of FIG. 9, the position of the Fermi level E_{F2} of the second electrode 25 before the vacuum level shift due to the electric dipole 1b is indicated by a dot-dash line, and the position of the Fermi level E_{F2}′ of the second electrode 25 after the vacuum level shift due to the electric dipole 1b is indicated by a solid line. Also, the position of the band of the oxide layer 34d before the vacuum level shift due to the electric dipole 1b is indicated by a dot-dash line, and the position of the band of the oxide layer 34d after the vacuum level shift due to the electric dipole 1b is indicated by a solid line. In addition, the vacuum level after band shift is indicated by a broken line at the top of (b) of FIG. 9.

Specifically, when the electric dipole 1b is formed, the Fermi level E_{F2} of the second electrode 25 moves to E_{F2}′. By this movement, the energy difference ΔE_{F2} (illustrated in (a) of FIG. 9) between the lower end of the conduction band (lower end of the ETL conduction band) of the oxide layer (ETL) 34c and the Fermi level E_{F2} of the second electrode 25 becomes the energy difference ΔE_{F2}′ between the lower end of the conduction band (lower end of the ETL conduction band) of the oxide layer (ETL) 34c and the Fermi level E_{F2}′ of the second electrode 25. As a result, the energy difference ΔE_{F2}′ after formation of the electric dipole 1b (the electron injection barrier height from the second electrode 25 to the oxide layer (ETL) 34c after formation of the electric dipole 1b) is less than the energy difference ΔE_{F2} (the electron injection barrier height from the second electrode 25 to the oxide layer (ETL) 34c in a case where the oxide layer 34d is not formed).

In a case where the film thickness of the oxide layer 34d is sufficiently thin in the light-emitting element 5RA, because the electrons have conductivity via tunneling of the oxide layer 34d, the electron injection barrier height between the second electrode 25 and the oxide layer (ETL) 34c is effectively the energy difference ΔE_{F2}′ between the lower end of the conduction band (lower end of the ETL conduction band) of the oxide layer (ETL) 34c and the Fermi level E_{F2}′ of the second electrode 25. According to the present embodiment, by forming the oxide layer 34d and the oxide layer (ETL) 34c in this manner, efficient electron injection can be achieved.

The film thickness of the oxide layer 34d is preferably is from 0.2 nm to 5 nm. By setting the film thickness to be 5 nm or less, electron tunneling can be efficient. Additionally, by setting the film thickness to be 0.2 nm or greater, a sufficiently large dipole moment can be obtained. Furthermore, the film thickness is preferably from 0.8 nm to 3 nm or less. In this case, more efficient electron injection is possible.

The oxide layer (ETL) 34c, which is the electron transport layer, is preferably formed from an n-type semiconductor. Also, the carrier density of the oxide layer (ETL) 34c is preferably 1×10¹⁵ cm⁻³ or greater. Also, the carrier density of the oxide layer (ETL) 34c is preferably 3×10″ cm⁻³ or less. Note that the electron density in the oxide layer (ETL) 34c is greater than the electron density in the oxide layer 34d.

Note that in the example illustrated in (b) of FIG. 9, an example is given of a case in which the Fermi level E_{F2}′ of the second electrode 25 after a band shift has been caused by formation of the electric dipole 1b is positioned below the lower end (ETL conduction band lower end) of the conduction band of the oxide layer (ETL) 34c. However, the Fermi level E_{F2}′ of the second electrode 25 after a band shift may be positioned above the lower end (ETL conduction band lower end) of the conduction band of the oxide layer (ETL) 34c. Also, the oxygen atom density in the oxide layer 34d is preferably 90% or less of the oxygen atom density in the oxide layer (ETL) 34c. In this case, efficient electron injection is possible. Also, the oxygen atom density in the oxide layer 34d is preferably 80% or less of the oxygen atom density in the oxide layer (ETL) 34c. In this case, ΔE_{F2}′ becomes even smaller, and more efficient electron injection is possible. Furthermore, the oxygen atom density in the oxide layer 34d is more preferably 75% or less, and even more preferably 70% or less of the oxygen atom density in the oxide layer (ETL) 34c. In this case, ΔE_{F2}′ becomes even smaller, and more efficient electron injection is possible. Also, the oxygen atom density in the oxide layer 34d is preferably 50% or greater of the oxygen atom density in the oxide layer (ETL) 34c. In this case, it is possible to suppress the formation of recombination centers due to dangling bonds and the like at the interface between the oxide layer (ETL) 34c and the oxide layer 34d.

Note that as illustrated in (b) of FIG. 9, the energy difference between the lower end of the conduction band and the upper end of the valence band in the oxide layer 34d (the energy difference between the lower end of the conduction band′ and the upper of the valence band′ in the oxide layer 34d) is greater than the energy difference between the lower end of the conduction band (ETL conduction band lower end) and the upper end of the valence band (ETL valence band upper end) in the oxide layer (ETL) 34c.

As illustrated in (b) of FIG. 9, the energy difference Ed2 between the vacuum level after the band shift and the Fermi level E_{F2}′ of the second electrode 25 is greater than the electron affinity EA1 of the oxide layer (ETL) 34c, and the electron affinity EA2 of the oxide layer 34d is less than the electron affinity EA1 of the oxide layer (ETL) 34c. Note that the energy difference Ed2 between the vacuum level after band shift and Fermi level E_{F2}′ of the second electrode 25 is the same as the energy difference between the vacuum level before band shift and the Fermi level E_{F2} of the second electrode 25, and is a work function of the second electrode 25. Thus, the energy difference Ed2 between the vacuum level after band shift and the Fermi level E_{F2}′ of the second electrode 25 is a material specific value for the second electrode 25 with or without band shift.

(a) of FIG. 11 is a diagram listing examples of an inorganic oxide forming a typical electron transport layer and the oxygen atom density thereof. (b) of FIG. 11 is a diagram listing examples of an exemplary inorganic oxide and the oxygen atom density thereof. Note that the inorganic oxides listed in (a) of FIG. 11 are n-type semiconductors, and the inorganic oxides listed in (b) of FIG. 11 are insulators.

FIG. 12 is a diagram listing material, for the oxide layer (ETL) 34c, selectable from examples of exemplary inorganic oxides forming the typical electron transport layer listed in (a) of FIG. 11, and material, for the oxide layer 34d, selectable from examples of exemplary inorganic oxides listed in (b) of FIG. 11.

In the present embodiment, the oxide for forming the oxide layer (ETL) 34c and the oxide for forming the oxide layer 34d can be selected such that the oxygen atom density of the oxide for forming the oxide layer 34d is less than the oxygen atom density of the oxide for forming the oxide layer (ETL) 34c.

In the combinations listed in FIG. 12, the oxygen atom density in the oxide layer 34d is less than the oxygen atom density in the oxide layer (ETL) 34c. Thus, an electric dipole having a dipole moment including a component orientated in the direction from the oxide layer 34d to the oxide layer (ETL) 34c is formed at the interface between the oxide layer (ETL) 34c and the oxide layer 34d. As a result, efficient electron injection from the second electrode 25 to the oxide layer (ETL) 34c is possible, thus improving the luminous efficiency.

In a case where titanium oxide (for example, TiO₂) with a rutile structure is used as the oxide layer (ETL) 34c because the oxygen atom density in the oxide layer 34d is less than the oxygen atom density in the oxide layer (ETL) 34c, as the oxide layer (HTL) 34d, an inorganic oxide (oxide of a first group) including at least one of aluminum oxide (for example, Al₂O₃), gallium oxide (for example, Ga₂O₃(α), Ga₂O₃(β)), tantalum oxide (for example, Ta₂O₅), zirconium oxide (for example, ZrO₂), hafnium oxide (for example, HfO₂), magnesium oxide (for example, MgO), germanium oxide (for example, GeO₂), silicon oxide (for example, SiO₂), yttrium oxide (for example, Y₂O₃), lanthanum oxide (for example, La₂O₃), strontium oxide (for example, SrO), or a composite oxide including two or more types of cations of these oxides may be used. The oxide layer 34d may include any one of one of aluminum oxide, gallium oxide, tantalum oxide, zirconium oxide, hafnium oxide, magnesium oxide, germanium oxide, silicon oxide, yttrium oxide, lanthanum oxide, strontium oxide, or a composite oxide including two or more types of cations of these oxides. In addition, the oxide layer 34d may be formed of an oxide in which the most abundant element other than oxygen is any one of Al, Ga, Ta, Zr, Hf, Mg, Ge, Si, Y, La, or Sr.

In a similar manner, in a case where titanium oxide (for example, TiO₂) with an anatase structure is used as the oxide layer (ETL) 34c, as the oxide layer (HTL) 34d, an inorganic oxide (oxide of a second group) including at least one of gallium oxide (P) (for example, Ga₂O₃(β)), tantalum oxide (for example, Ta₂O₅), zirconium oxide (for example, ZrO₂), hafnium oxide (for example, HfO₂), magnesium oxide (for example, MgO), germanium oxide (for example, GeO₂), silicon oxide (for example, SiO₂), yttrium oxide (for example, Y₂O₃), lanthanum oxide (for example, La₂O₃), strontium oxide (for example, SrO), or a composite oxide including two or more types of cations of these oxides may be used. The oxide layer 34d may include any one of one of gallium oxide (P), tantalum oxide, zirconium oxide, hafnium oxide, magnesium oxide, germanium oxide, silicon oxide, yttrium oxide, lanthanum oxide, strontium oxide, or a composite oxide including two or more types of cations of these oxides. In addition, the oxide layer 34d may be formed of an oxide in which the most abundant element other than oxygen is any one of Ga, Ta, Zr, Hf, Mg, Ge, Si, Y, La, or Sr.

In a similar manner, in a case where tin oxide (for example, SnO₂) is used as the oxide layer (ETL) 34c, as the oxide layer (HTL) 34d, an inorganic oxide (oxide of a third group) including at least one of hafnium oxide (for example, HfO₂), magnesium oxide (for example, MgO), germanium oxide (for example, GeO₂), silicon oxide (for example, SiO₂), yttrium oxide (for example, Y₂O₃), lanthanum oxide (for example, La₂O₃), strontium oxide (for example, SrO), or a composite oxide including two or more types of cations of these oxides may be used. The oxide layer 34d may include any one of one of hafnium oxide, magnesium oxide, germanium oxide, silicon oxide, yttrium oxide, lanthanum oxide, strontium oxide, or a composite oxide including two or more types of cations of these oxides. In addition, the oxide layer 34d may be formed of an oxide in which the most abundant element other than oxygen is any one of Hf, Mg, Ge, Si, Y, La, or Sr.

In a similar manner, in a case where strontium titanium oxide (for example, strontium titanate (SrTiO₃)) is used as the oxide layer (ETL) 34c, as the oxide layer (HTL) 34d, an inorganic oxide (oxide of a fourth group) including at least one of germanium oxide (for example, GeO₂), silicon oxide (for example, SiO₂), yttrium oxide (for example, Y₂O₃), lanthanum oxide (for example, La₂O₃), strontium oxide (for example, SrO), or a composite oxide including two or more types of cations of these oxides may be used. The oxide layer 34d may include any one of one of germanium oxide, silicon oxide, yttrium oxide, lanthanum oxide, strontium oxide, or a composite oxide including two or more types of cations of these oxides. In addition, the oxide layer 34d may be formed of an oxide in which the most abundant element other than oxygen is any one of Ge, Si, Y, La, or Sr.

In a similar manner, in a case where indium oxide (for example, In₂O₃)) is used as the oxide layer (ETL) 34c, as the oxide layer (HTL) 34d, an inorganic oxide (oxide of a fifth group) including at least one of silicon oxide (for example, SiO₂), yttrium oxide (for example, Y₂O₃), lanthanum oxide (for example, La₂O₃), strontium oxide (for example, SrO), or a composite oxide including two or more types of cations of these oxides may be used. The oxide layer 34d may include any one of one of silicon oxide, yttrium oxide, lanthanum oxide, strontium oxide, or a composite oxide including two or more types of cations of these oxides. In addition, the oxide layer 34d may be formed of an oxide in which the most abundant element other than oxygen is any one of Si, Y, La, or Sr.

In a similar manner, in a case where zinc oxide (for example, ZnO)) is used as the oxide layer (ETL) 34c, as the oxide layer (HTL) 34d, an inorganic oxide (oxide of a sixth group) including at least one of yttrium oxide (for example, Y₂O₃), lanthanum oxide (for example, La₂O₃), strontium oxide (for example, SrO), or a composite oxide including two or more types of cations of these oxides may be used. The oxide layer 34d may include any one of one of yttrium oxide, lanthanum oxide, strontium oxide, or a composite oxide including two or more types of cations of these oxides. In addition, the oxide layer 34d may be formed of an oxide in which the most abundant element other than oxygen is any one of Y, La, or Sr.

Note that the combinations of oxides forming the oxide layer (ETL) 34c and oxides forming the oxide layer 34d listed in FIG. 12 are merely examples. In the present embodiment, as long as the oxygen atom density in the oxide layer 34d is less than the oxygen atom density in the oxide layer (ETL) 34c, the present disclosure is not limited to these combinations.

By the oxygen atom density in the oxide layer 34d being less than the oxygen atom density in the oxide layer (ETL) 34c, the electric dipole 1b having a dipole moment of a component oriented in the direction of the oxide layer (ETL) 34c from the oxide layer 34d is more easily formed, and electron injection efficiency can be improved.

From the perspective of easily forming the electric dipole 1b (illustrated in (b) of FIG. 10) having a dipole moment of a component orientated from the oxide layer 34d toward the oxide layer (ETL) 34c direction and improving the electron injection efficiency, the oxygen atom density in the oxide layer 34d is preferably 90% or less of the oxygen atom density in the oxide layer (ETL) 34c, and the oxygen atom density in the oxide layer 34d is more preferably 80% or less of the oxygen atom density in the oxide layer (ETL) 34c. Furthermore, the oxygen atom density in the oxide layer 34d is more preferably 75% or less, and even more preferably 70% or less of the oxygen atom density in the oxide layer (ETL) 34c.

Also, the oxygen atom density in the oxide layer 34d is preferably 50% or greater of the oxygen atom density in the oxide layer (ETL) 34c. In this case, it is possible to suppress the formation of recombination centers due to dangling bonds and the like at the interface between the oxide layer (ETL) 34c and the oxide layer 34d.

Note that the oxygen atom density of the oxide layer in the present application is a unique value for the oxide layer (ETL) 34c and for the oxide layer 34d and applies to the oxygen atom bulk density of the material forming the oxide layer (ETL) 34c or oxide layer 34d. For example, for the materials listed in FIG. 11, the oxygen atom densities listed in FIG. 11 are applied.

### Second Modification Example

(a) of FIG. 13 is a diagram illustrating a schematic configuration of a light-emitting element 5RI, and (b) of FIG. 13 is a diagram illustrating a schematic configuration of a light-emitting element 5RJ.

In the light-emitting element 5RI illustrated in (a) of FIG. 13, the upper surface of the oxide layer 34d′ in contact with the oxide layer (ETL) 34c includes grains. Also, in the light-emitting element 5RJ illustrated in (b) of FIG. 13, the oxide layer (ETL) 34c′ is amorphous, and the upper surface of the oxide layer 34d′ in contact with the oxide layer (ETL) 34c′ includes grains. Materials similar to that used for the oxide layer (ETL) 34c and the oxide layer 34d described above can be used for the oxide layer (ETL) 34c′ and the oxide layer 34d′. Note that in the display device including the light-emitting element 5RI, the first electrode 22 is formed as a solid-like common layer, and the second electrode 25 electrically connected to the thin film transistor element Tr (TFT element) is formed into island shapes for each subpixel.

In the light-emitting element 5RI illustrated in (a) of FIG. 13, the first electrode 22 is above the light-emitting layer 24c of the first wavelength region, and the second electrode 25 is below the light-emitting layer 24c of the first wavelength region, and at least a portion of the upper surface of the oxide layer 34d′ (second oxide layer) in contact with the oxide layer (ETL) 34c (first oxide layer) is polycrystallized. That is, the upper surface of the oxide layer 34d′ includes grains (grains). In this manner, by the upper surface of the oxide layer 34d′ including grains, the area of the interface between the upper surface of the oxide layer 34d′ and the oxide layer (ETL) 34c is increased, allowing the electric dipole to be more efficiently formed, and with the light-emitting element 5RI, effective electron injection from the second electrode 25 to the oxide layer (ETL) 34c is possible. As a result, with the light-emitting element 5RI, efficient electron injection from the second electrode 25 to the light-emitting layer 24c of the first wavelength region is possible, thus improving the luminous efficiency.

In the light-emitting element 5RJ illustrated in (b) of FIG. 13, the first electrode 22 is above the light-emitting layer 24c of the first wavelength region, and the second electrode 25 is below the light-emitting layer 24c of the first wavelength region. At least a portion of the upper surface of the oxide layer 34d′ (second oxide layer) in contact with the oxide layer (ETL) 34c′ (first oxide layer) is polycrystallized. That is, the upper surface of the oxide layer 34d′ includes grains (grains). The oxide layer (ETL) 34c′ is formed of an amorphous oxide. Note that in the display device including the light-emitting element 5RJ, the first electrode 22 is formed as a solid-like common layer, and the second electrode 25 electrically connected to the thin film transistor element Tr (TFT element) is formed into island shapes for each subpixel.

By making the oxide layer (ETL) 34c′ an amorphous oxide, good coverage with respect to the oxide layer 34d′ including grains in the surface is obtained, allowing the electric dipole 1b is be easily formed. In addition, since the film thickness uniformity of the oxide layer (ETL) 34c′ can be improved, the uniformity of electron conduction in the oxide layer (ETL) 34c′ can be improved. By the upper surface of the oxide layer 34d′ including grains, the area of the interface between the upper surface of the oxide layer 34d′ and the oxide layer (ETL) 34c′ is increased, allowing the electric dipole to be more efficiently formed. Thus, efficient electron injection from the second electrode 25 to the oxide layer (ETL) 34c′ is possible with the light-emitting element 5RJ. As a result, with the light-emitting element 5RJ, efficient electron injection from the second electrode 25 to the light-emitting layer 24c of the first wavelength region is possible, thus improving the luminous efficiency.

Note that in the present embodiment, a portion including the upper surface of the oxide layer 34d′ is heat treated using laser light, and the upper surface of the oxide layer 34d′ is polycrystallized, but the present disclosure is not limited thereto. Also, as long as the oxygen atom density of the oxide layer 34d′ is less than the oxygen atom density of the oxide layer (ETL) 34c, 34c′, the method of polycrystallizing the oxide layer 34d′ and the type of polycrystalline oxide forming the oxide layer 34d′ are not particularly limited.

Furthermore, in the present embodiment, a case has been described in which grains are formed by polycrystallizing the upper surface of the oxide layer 34d′, but the present disclosure is not limited thereto, and grains may be formed on at least a portion of the upper surface of the oxide layer 34d′ using spontaneous nucleation, for example, via sputtering, CVD, or the like.

Furthermore, in the present embodiment, a case in which the upper surface of the oxide layer 34d′ is polycrystallized has been described as an example, but the present disclosure is not limited thereto, and the entire oxide layer 34d′ may be formed of a polycrystalline oxide.

Furthermore, in the present embodiment, a case in which the upper surface of the oxide layer 34d′ includes grains has been described as an example, but the present disclosure is not limited thereto, and the entire oxide layer 34d′ may include grains.

Note that, at the upper surface of the oxide layer 34d′, grains may be distributed discretely. Grains may also be crystal grains including crystals or may include an amorphous phase.

(c) of FIG. 13 is a diagram illustrating a schematic configuration of the light-emitting element 5RK.

In the light-emitting element 5RK illustrated in (c) of FIG. 13, the first electrode 22, the hole transport layer (HTL) 24a, the light-emitting layer 24c of the first wavelength region, the oxide layer (ETL) 34c″ (first oxide layer), oxide layer 34d (second oxide layer), and the second electrode 25 are layered in this order from the lower layer side to the upper layer side, and at least the upper surface of the oxide layer (ETL) 34c″ includes grains. Materials similar to that used for the oxide layer (ETL) 34c and the oxide layer (ETL) 34c′ described above can be used for the oxide layer (ETL) 34c″.

In the light-emitting element 5RK illustrated in (c) of FIG. 13, the first electrode 22 formed of a light-permeable material is below the second electrode 25 formed of a light-reflective material, allowing the light-emitting element 5RK to be used in a bottom-emitting display device. Of course, the present disclosure is not limited thereto, and, in a similar manner to the light-emitting element 5R, in the light-emitting element 5RK, the first electrode 22 and/or the second electrode 25 may be formed of a light-permeable material, and the first electrode 22 or the second electrode 25 may be formed of a light-reflective material.

In the light-emitting element 5RK, the second electrode 25 is above the light-emitting layer 24c of the first wavelength region, and the first electrode 22 is below the light-emitting layer 24c of the first wavelength region. At least the upper surface of the oxide layer (ETL) 34c″ in contact with the oxide layer 34d includes grains. In the oxide layer (ETL) 34c″, grains may be distributed discretely. Grains may also be crystal grains containing crystals or may include an amorphous phase.

A case in which, in the light-emitting element 5RK, the upper surface of the oxide layer (ETL) 34c″ in contact with oxide layer 34d includes grains has been described as an example, but the present disclosure is not limited thereto, and the entire oxide layer (ETL) 34c″ may include grains.

Note that in the present embodiment, in the light-emitting element 5RK, a portion including the upper surface of the oxide layer (ETL) 34c″ is heat treated using laser light, and at least a portion of the upper surface of the oxide layer (ETL) 34c″ is polycrystallized and the upper surface of the oxide layer (ETL) 34c″ includes grains, but the present disclosure is not limited thereto. Grains can also be formed using spontaneous nucleation, for example, via sputtering, CVD, and the like. Also, as long as the oxygen atom density of the oxide layer 34d is less than the oxygen atom density of the oxide layer (ETL) 34c″, the method of forming the oxide layer (ETL) 34c″ including grains and the type of the oxide layer (ETL) 34c″ are not particularly limited. The entire oxide layer (ETL) 34c″ may be polycrystalline.

In this manner, by the upper surface of the oxide layer (ETL) 34c″ in contact with the oxide layer 34d including grains, the area of the interface between the oxide layer 34d and the upper surface of the oxide layer (ETL) 34c″ is increased, allowing the electric dipole to be more efficiently formed, and with the light-emitting element 5RK, effective electron injection from the second electrode 25 to the oxide layer (ETL) 34c″ is possible. As a result, with the light-emitting element 5RK, efficient electron injection from the second electrode 25 to the light-emitting layer 24c of the first wavelength region is possible, thus improving the luminous efficiency.

The oxide layer 34d may be an amorphous oxide. By making the oxide layer 34d an amorphous oxide, good coverage with respect to the oxide layer (ETL) 34c″ including grains is obtained, allowing the electric dipole 1b is be easily formed. In addition, since the film thickness uniformity of the oxide layer 34d can be improved, the uniformity of electron conduction via tunneling in the oxide layer 34d can be improved. Also, even in a case where the oxide layer 34d is an amorphous oxide, the upper surface of the oxide layer (ETL) 34c″ includes grains. Thus, the area of the interface with the amorphous oxide is increased, allowing the electric dipole to be more efficiently formed and efficient electron injection from the second electrode 25 to the oxide layer (ETL) 34c″ to be possible in the light-emitting element 5RK. As a result, with the light-emitting element 5RK, efficient electron injection from the second electrode 25 to the light-emitting layer 24c of the first wavelength region is possible, thus improving the luminous efficiency.

(d) of FIG. 13 is a diagram illustrating a schematic configuration of the light-emitting element 5RL.

In the light-emitting element 5RL illustrated in (d) of FIG. 13, the oxide layer (ETL) 34c′″(first oxide layer) in contact with the oxide layer 34d (second oxide layer) is formed into island shapes. Materials similar to that used for the oxide layer (ETL) 34c, the oxide layer (ETL) 34c′, and the oxide layer (ETL) 34c″ described above can be used for the oxide layer (ETL) 34c′″.

In a similar manner to the light-emitting element 5R illustrated in FIG. 2, in the light-emitting element 5RL illustrated in (d) of FIG. 13, the first electrode 22 and/or the second electrode 25 may be formed of a light-permeable material, and the first electrode 22 or the second electrode 25 may be formed of a light-reflective material.

In the light-emitting element 5RL, the second electrode 25 is above the light-emitting layer 24c of the first wavelength region, and the first electrode 22 is below the light-emitting layer 24c of the first wavelength region. Furthermore, the oxide layer (ETL) 34c′″ in contact with the oxide layer 34d is formed into island shapes. The oxide layer (ETL) 34c′″ can be formed into island shapes using spontaneous nucleation using a sputtering method, a CVD method, or the like. Furthermore, after forming the thin film, the thin film may be processed into island shapes by etching or the like. The patterning process may also be performed such that the surface roughness of the oxide layer (ETL) 34c′″ increases when the oxide layer (ETL) 34c′″ is patterned to form island shapes.

The oxygen atom density of the oxide layer 34d is less than the oxygen atom density of the oxide layer (ETL) 34c′″. By the oxide layer (ETL) 34c′″ being formed into island shapes, the area of the interface with the oxide layer 34d is increased, allowing the electric dipole to be more efficiently formed, and with the light-emitting element 5RL, effective electron injection from the second electrode 25 to the oxide layer (ETL) 34c′″ is possible. As a result, with the light-emitting element 5RL, efficient electron injection from the second electrode 25 to the light-emitting layer 24c of the first wavelength region is possible, thus improving the luminous efficiency.

The oxide layer 34d may be an amorphous oxide. By making the oxide layer 34d an amorphous oxide, good coverage with respect to the oxide layer (ETL) 34c′″ including grains in the surface is obtained, allowing the electric dipole 1b is be easily formed. In addition, since the film thickness uniformity of the oxide layer 34d can be improved, the uniformity of electron conduction via tunneling in the oxide layer 34d can be improved. Also, even in a case where the oxide layer 34d is an amorphous oxide, the oxide layer (ETL) 34c′″ is formed into island shapes. Thus, the area of the interface with the amorphous oxide is increased, allowing the electric dipole to be more efficiently formed and efficient electron injection from the second electrode 25 to the oxide layer (ETL) 34c′″ to be possible in the light-emitting element 5RL. As a result, with the light-emitting element 5RL, efficient electron injection from the second electrode 25 to the light-emitting layer 24c of the first wavelength region is possible, thus improving the luminous efficiency.

Note that, as illustrated in FIG. 8, (c) of FIGS. 13, and (d) of FIG. 13, in a case where the first electrode 22 is below the light-emitting layer 24c of the first wavelength region and the second electrode 25 is above the light-emitting layer 24c of the first wavelength region, in other words, in a case where the oxide layer 34d is above the oxide layer (ETL) 34c, 34c″, 34c′″, of the oxide layers (ETL) 34c, 34c″, 34c′″, and the oxide layer 34d, at least the oxide layer 34d is preferably a continuous film.

Also, as illustrated in (a) of FIGS. 13 and (b) of FIG. 13, in a case where the first electrode 22 is above the light-emitting layer 24c of the first wavelength region and the second electrode 25 is below the light-emitting layer 24c of the first wavelength region, in other words, in a case where the oxide layer (ETL) 34c, 34c is above the oxide layer 34d, of the oxide layers (ETL) 34c, 34c′, and the oxide layer 34b, at least the oxide layer (ETL) 34c, 34c is preferably a continuous film. In other words, of the oxide layers (ETL) 34c, 34c′, 34c″, 34c′″ and oxide layers 34d, 34d′, at least the film formed from after is preferably a continuous film. Also, in this example, the continuous film is a dense film having a porosity of less than 1%. In other words, the continuous film is a film with substantially no voids.

The oxide layers (ETL) 34c, 34c′, 34c″, 34c′″ and oxide layers 34d, 34d′ should be formed via, for example, sputtering, vapor deposition, CVD (chemical vapor deposition), PVD (physical vapor deposition), or the like. The oxide layers (ETL) 34c, 34c′, 34c″, 34c′″ and the oxide layers 34d and 34d′ formed via such a method are continuous films, allowing the electric dipole 1b to be densely formed. Note that a film made by applying microparticles such as nanoparticles cannot be a continuous film because of the porous nature due to a large number of voids being formed between the microparticles.

### Third Embodiment

Next, the third embodiment of the present invention will be described with reference to FIGS. 14 to 18. In the light-emitting element 5RB of the present embodiment, the oxide layer 34b (fifth oxide layer), the oxide layer (HTL) 34as (sixth oxide layer) in contact with the oxide layer 34b (fifth oxide layer), and an oxide layer 124b (seventh oxide layer) in contact with the oxide layer (HTL) 34as (sixth oxide layer) are provided in this order between the first electrode 22 and the light-emitting layer 24c from the side near the first electrode 22. This is different from the first embodiment. Note that materials similar to that used for the oxide layer (HTL) 34a described above can be used for the oxide layer (HTL) 34as.

Also, in the present embodiment described below, the oxygen atom density in the oxide layer (HTL) 34as is less than the oxygen atom density in the oxide layer 34b, and the oxygen atom density in the oxide layer 124b is less than the oxygen atom density in the oxide layer (HTL) 34as. Also, in the present embodiment described below, the material of the oxide layer 34b, the material of the oxide layer 124b, and the material of the oxide layer (HTL) 34as as selected from those listed in (b) of FIG. 5, (b) of FIGS. 17, and (a) of FIG. 17 such that the oxygen atom density in the oxide layer (HTL) 34as is less than the oxygen atom density in the oxide layer 34b, and the oxygen atom density in the oxide layer 124b is less than the oxygen atom density in the oxide layer (HTL) 34as. For convenience of explanation, components having the same functions as those described in diagrams of the first embodiment are appended with the same reference signs, and descriptions thereof may be omitted.

FIG. 14 is an image illustrating a schematic configuration of a light-emitting element 5RB according a third embodiment.

As illustrated in FIG. 14, the light-emitting element 5RB includes the first electrode 22, the second electrode 25, and the light-emitting layer 24c provided between the first electrode 22 and the second electrode 25. Also, the oxide layer 34b (fifth oxide layer), the oxide layer (HTL) 34as (sixth oxide layer) in contact with the oxide layer 34b (fifth oxide layer), and an oxide layer 124b (seventh oxide layer) in contact with the oxide layer (HTL) 34as (sixth oxide layer) are provided in this order between the first electrode 22 and the light-emitting layer 24c from the side near the first electrode 22. Also, the electron transport layer (ETL) 24d is provided between the light-emitting layer 24c and the second electrode 25.

Of the oxide layer 34b and the oxide layer (HTL) 34as, the oxide layer (HTL) 34as, which is the layer near the light-emitting layer 24c, is formed from a semiconductor. The oxide layer (HTL) 34as is preferably formed from a p-type semiconductor. The oxygen atom density in the oxide layer (HTL) 34as is less than the oxygen atom density in the oxide layer 34b, and the oxygen atom density in the oxide layer 124b is less than the oxygen atom density in the oxide layer (HTL) 34as.

The relationship between the oxide layer 34b already described in the first embodiment and the oxide layer (HTL) 34as selected from among the materials of the oxide layer (HTL) 34a already described in the first embodiment is the same as in the first embodiment described above, and thus descriptions thereof will be omitted, and only the relationship between the oxide layer (HTL) 34as and the oxide layer 124b will be described.

(a) of FIG. 16 is a diagram for describing the mechanism by which oxygen atoms move at the interface between the oxide layer (HTL) 34as and the oxide layer 124b. (b) of FIG. 16 is a diagram illustrating a state in which an electric dipole 1c is formed by movement of oxygen atoms at the interface between the oxide layer (HTL) 34as and the oxide layer 124b.

As illustrated in (a) of FIG. 16, since the oxygen atom density of the oxide layer 124b is less than the oxygen atom density of the oxide layer (HTL) 34as, when the oxide layer (HTL) 34as and oxide layer 124b are formed so as to come into contact with one another, oxygen atoms easily move from the oxide layer (HTL) 34as toward the oxide layer 124b. As oxygen atoms move, the oxygen holes become positively charged and the moving oxygen atoms become negatively charged.

Accordingly, as illustrated in (b) of FIG. 16, at the interface between the oxide layer (HTL) 34as and the oxide layer 124b, the electric dipole 1c having a dipole moment of a component orientated in the direction from the oxide layer 124b to the oxide layer (HTL) 34as is formed.

FIG. 15 is an energy band diagram for describing a hole injection barrier in the light-emitting element 5RB.

As illustrated in FIG. 15, in the light-emitting element 5RB having a configuration in which the oxide layer 124b is formed between the oxide layer (HTL) 34as and the light-emitting layer 24c of the first wavelength region, the oxygen atom density in the oxide layer 124b is less than the oxygen atom density in the oxide layer (HTL) 34as. Thus, the electric dipole 1c (having a dipole moment of a component orientated in the direction from the oxide layer 124b to the oxide layer (HTL) 34as) is formed at the interface between the oxide layer (HTL) 34as and the oxide layer 124b. When the electric dipole 1c is formed in this manner, as illustrated in FIG. 15, a vacuum level shift caused by the electric dipole 1c occurs at the interface between the oxide layer (HTL) 34as and the oxide layer 124b, which is the interface where the electric dipole 1c is formed. As a result, as illustrated in FIG. 15, the band position of the oxide layer (HTL) 34as is moved downward with respect to the band position of the light-emitting layer 24c of the first wavelength region. Specifically, the lower end of the conduction band (HTL conduction band) of the oxide layer (HTL) 34as illustrated by a dashed line in FIG. 15 moves to the lower end of the HTL conduction band′ illustrated by a solid line in FIG. 15, and the upper end of the valence band (HTL valence band) of the oxide layer (HTL) 34as illustrated by a dashed line in FIG. 15 moves to the upper end of the HTL valence band′ illustrated by a solid line in the FIG. 15. By this movement, the energy difference ΔEv′ between the upper end of the HTL valence band′ of the oxide layer (HTL) 34as and the upper end of the valence band of the light-emitting layer 24c of the first wavelength region is less than the energy difference ΔEv between the upper end (upper end of the HTL valence band in FIG. 15) of the HTL valence band of the oxide layer (HTL) 34as in a case where the oxide layer 124b is not provided and there is no vacuum level shift and the upper end of the valence band of the light-emitting layer 24c of the first wavelength region. In addition, the vacuum level after band shift is indicated by a broken line at the top of FIG. 15.

In a case where the film thickness of the oxide layer 124b is sufficiently thin in the light-emitting element 5RB, because the holes have conductivity via tunneling of the oxide layer 124b, the hole barrier height between the oxide layer (HTL) 34as and the light-emitting layer 24c of the first wavelength region is effectively the energy difference ΔEv′ between the upper end of the HTL valence band′ of the oxide layer (HTL) 34as and the upper end of the valence band of the light-emitting layer 24c of the first wavelength region. Thus, in the light-emitting element 5RB, by also forming the oxide layer 124b in addition to that formed in the light-emitting element 5R of the first embodiment, hole injection from the oxide layer (HTL) 34as to the light-emitting layer 24c of the first wavelength region can be more efficient, and luminous efficiency can be improved.

The film thickness of the oxide layer 124b is preferably is from 0.2 nm to 5 nm. By setting the film thickness to be 5 nm or less, hole tunneling can be efficient. Additionally, by setting the film thickness to be 0.2 nm or greater, a sufficiently large dipole moment can be obtained. Furthermore, the film thickness is preferably from 0.8 nm to 3 nm or less. In this case, more efficient hole injection is possible.

The oxide layer (HTL) 34as, which is the hole transport layer, is preferably formed from a p-type semiconductor. Also, the carrier density (electron density) of the oxide layer (HTL) 34as is preferably 1×10¹⁵ cm⁻³ or less. Also, the carrier density (electron density) of the oxide layer (HTL) 34as is preferably 3×10¹⁷ cm³ or less.

As illustrated in FIG. 15, the ionization potential IP2 of the oxide layer (HTL) 34as is less than the ionization potential IP4 of the light-emitting layer 24c of the first wavelength region, and the ionization potential IP3 of the oxide layer 124b is greater than the ionization potential IP4 of the light-emitting layer 24c of the first wavelength region.

Also, as illustrated in FIG. 15, the energy difference between the conduction band lower end in the oxide layer 124b and the valence band upper end is greater than the energy difference between the lower end of the HTL conduction band′ in the oxide layer (HTL) 34as and the upper end of the HTL valence band′. Thus, the oxide layer 124b has a smaller carrier density and better insulating properties than the oxide layer (HTL) 34as. Accordingly, hole conduction by tunneling occurs in the oxide layer 124b. As described above, the hole density in the oxide layer (HTL) 34as, which is the hole transport layer, is greater than the hole density in the oxide layer 124b, and holes are injected to the light-emitting layer 24c of the first wavelength region via tunneling of the oxide layer 124b.

Note that in the example of FIG. 15, only the light-emitting element 5RB including the light-emitting layer 24c of the first wavelength region has been described, but with the light-emitting element including the light-emitting layer 24c′ of the second wavelength region and the light-emitting element including the light-emitting layer 24c″ of the third wavelength region also, efficient hole injection is possible in a similar manner to the light-emitting element 5RB including the light-emitting layer 24c of the first wavelength region due to the forming the oxide layer 124b.

(a) of FIG. 17 is a diagram listing examples of an inorganic oxide forming a typical hole transport layer and the oxygen atom density thereof. (b) of FIG. 17 is a diagram listing examples of an exemplary inorganic oxide and the oxygen atom density thereof. Note that the inorganic oxides listed in (b) of FIG. 17 are insulators.

FIG. 18 is a diagram listing material, for the oxide layer (HTL) 34as, selectable from examples of exemplary inorganic oxides forming the typical hole transport layer listed in (a) of FIG. 17, and material, for the oxide layer 124b, selectable from examples of exemplary inorganic oxides listed in (b) of FIG. 17.

In the present embodiment, the oxygen atom density in the oxide layer 124b is less than the oxygen atom density in the oxide layer (HTL) 34as, and thus, for example, as the oxide layer (HTL) 34as, an inorganic oxide including at least one of nickel oxide or copper aluminate can be used, and, as the oxide layer 124b, for example, an inorganic oxide including at least one of strontium oxide, lanthanum oxide, yttrium oxide, silicon oxide, germanium oxide, or a composite oxide including two or more types of cations of these oxides can be used.

The oxide layer 124b may be formed from one of strontium oxide (for example, SrO), lanthanum oxide (for example, La₂O₃), yttrium oxide (for example, Y₂O₃), silicon oxide (for example, SiO₂), germanium oxide (for example, GeO₂), or a composite oxide including two or more types of cations of these oxides.

The oxide layer 124b may be formed from an oxide including one or more elements from among Sr, La, Y, Si, and Ge as a main component.

In addition, the oxide layer 124b may be formed of an oxide in which the most abundant element other than oxygen is any one of Sr, La, Y, Si, and Ge.

Note that the combinations of the oxide layer (HTL) 34as and the oxide layer 124b described above are examples and are not limited thereto. It is only required that the oxygen atom density in the oxide layer (HTL) 34as is less than the oxygen atom density in the oxide layer 34b and the oxygen atom density in the oxide layer 124b is less than the oxygen atom density in the oxide layer (HTL) 34as.

By the oxygen atom density being less, the electric dipole 1c having a dipole moment of a component oriented in the direction of the oxide layer (HTL) 34as from the oxide layer 124b is more easily formed, and hole injection efficiency can be improved.

From the perspective of easily forming the electric dipole 1c (illustrated in (b) of FIG. 16) having a dipole moment of a component orientated from the oxide layer 124b toward the oxide layer (HTL) 34as direction and improving the hole injection efficiency, the oxygen atom density in the oxide layer 124b is preferably 90% or less of the oxygen atom density in the oxide layer (HTL) 34as, and the oxygen atom density in the oxide layer 124b is more preferably 80% or less of the oxygen atom density in the oxide layer (HTL) 34as. Furthermore, the oxygen atom density in the oxide layer 124b is more preferably 75% or less, and even more preferably 70% or less of the oxygen atom density in the oxide layer (HTL) 34as.

Also, the oxygen atom density in the oxide layer 124b is preferably 50% or greater of the oxygen atom density in the oxide layer (HTL) 34as. In this case, it is possible to suppress the formation of recombination centers due to dangling bonds and the like at the interface between the oxide layer (HTL) 34as and the oxide layer 124b.

Note that the oxygen atom density of the oxide layer in the present application is a unique value for the oxide layer (HTL) 34as and for the oxide layer 124b and applies to the oxygen atom bulk density of the material forming the oxide layer (HTL) 34as or oxide layer 124b. For example, for the materials listed in FIG. 17, the oxygen atom densities listed in FIG. 15 are applied.

### Fourth Embodiment

Next, the fourth embodiment of the present invention will be described with reference to FIGS. 19 to 23. In the light-emitting element 5RC of the present embodiment, the oxide layer 74b (fifth oxide layer), the oxide layer (ETL) 34cs (sixth oxide layer) in contact with the oxide layer 74b (fifth oxide layer), and an oxide layer 34d (seventh oxide layer) in contact with the oxide layer (ETL) 34cs (sixth oxide layer) are provided in this order between the light-emitting layer 24c and the second electrode 25 from the side near the first electrode 22. This is different from the second embodiment. Note that materials similar to that used for the oxide layer (ETL) 34c described above can be used for the oxide layer (ETL) 34cs. In the present embodiment described below, the oxygen atom density in the oxide layer 34d is less than the oxygen atom density in the oxide layer (ETL) 34cs, and the oxygen atom density in the oxide layer (ETL) 34cs is less than the oxygen atom density in the oxide layer 74b. In the present embodiment described below, the material of the oxide layer 34d, the material of the oxide layer (ETL) 34cs, and the material of the oxide layer 74b as selected from those listed in (b) of FIG. 11, (a) of FIGS. 22, and (b) of FIG. 22 such that the oxygen atom density in the oxide layer 34d is less than the oxygen atom density in the oxide layer (ETL) 34cs, and the oxygen atom density in the oxide layer (ETL) 34cs is less than the oxygen atom density in the oxide layer 74b. For convenience of explanation, components having the same functions as those described in diagrams of the second embodiment are appended with the same reference signs, and descriptions thereof may be omitted.

FIG. 19 is an image illustrating a schematic configuration of a light-emitting element 5RC according a fourth embodiment.

As illustrated in FIG. 19, the light-emitting element 5RC includes the first electrode 22, the second electrode 25, and the light-emitting layer 24c provided between the first electrode 22 and the second electrode 25. Also, the oxide layer 74b (fifth oxide layer), the oxide layer (ETL) 34cs (sixth oxide layer) in contact with the oxide layer 74b (fifth oxide layer), and an oxide layer 34d (seventh oxide layer) in contact with the oxide layer (ETL) 34cs (sixth oxide layer) are provided in this order between the light-emitting layer 24c and the second electrode 25 from the side near the first electrode 22. Also, the electron transport layer (HTL) 24a is provided between the light-emitting layer 24c and the first electrode 22.

Of the oxide layer 34d and the oxide layer 34cs, the oxide layer (ETL) 34cs, which is the layer near the light-emitting layer 24c, is formed from a semiconductor. The oxide layer (ETL) 34cs is preferably formed from an n-type semiconductor. In the present embodiment described below, the oxygen atom density in the oxide layer 34d is less than the oxygen atom density in the oxide layer (ETL) 34cs, and the oxygen atom density in the oxide layer (ETL) 34cs is less than the oxygen atom density in the oxide layer 74b.

The relationship between the oxide layer 34d already described in the second embodiment and the oxide layer (ETL) 34cs for which the same material as the oxide layer (ETL) 34c already described in the second embodiment can be used is the same as in the second embodiment described above, and thus descriptions thereof will be omitted, and only the relationship between the oxide layer (ETL) 34cs and the oxide layer 74b will be described.

The oxide layer (ETL) 34cs is preferably a layer that transports electrons and formed from an n-type semiconductor. Furthermore, the oxide layer (ETL) 34cs is preferably formed from an inorganic oxide.

The oxide layer 74b is formed from an oxide. The oxide layer 74b is preferably formed from an inorganic oxide. Furthermore, the oxide layer 74b is preferably formed from an insulator.

The oxygen atom density in the oxide layer (ETL) 34cs is less than the oxygen atom density in the oxide layer 74b. In this case, oxygen atoms at the interface between oxide layer (ETL) 34cs and oxide layer 74b move in the direction of the oxide layer (ETL) 34cs from the oxide layer 74b, and an electric dipole 1d (having a dipole moment of a component orientated in the direction from the oxide layer (ETL) 34cs to the oxide layer 74b) is easily formed.

(a) of FIG. 21 is a diagram for describing the mechanism by which oxygen atoms move at the interface between the oxide layer (ETL) 34cs and the oxide layer 74b. (b) of FIG. 21 is a diagram illustrating a state in which an electric dipole 1d is formed by movement of oxygen atoms at the interface between the oxide layer (ETL) 34cs and the oxide layer 74b.

As illustrated in (a) of FIG. 21, since the oxygen atom density in the oxide layer (ETL) 34cs is less than the oxygen atom density in the oxide layer 74b, when the oxide layer (ETL) 34cs and oxide layer 74b are formed so as to come into contact with one another, oxygen atoms easily move from the oxide layer 74b toward the oxide layer (ETL) 34cs. As oxygen atoms move, the oxygen holes become positively charged and the moving oxygen atoms become negatively charged.

Accordingly, as illustrated in (b) of FIG. 21, at the interface between the oxide layer (ETL) 34cs and the oxide layer 74b, the electric dipole 1d having a dipole moment of a component orientated in the direction from the oxide layer (ETL) 34cs to the oxide layer 74b is formed.

From the perspective of easily forming the electric dipole 1d (illustrated in (b) of FIG. 21) having a dipole moment of a component orientated from the oxide layer (ETL) 34cs toward the oxide layer 74b direction and improving the electron injection efficiency, the oxygen atom density in the oxide layer (ETL) 34cs is preferably 95% or less of the oxygen atom density in the oxide layer 74b, and the oxygen atom density in the oxide layer 34cs is more preferably 84% or less of the oxygen atom density in the oxide layer 74b.

Also, the oxygen atom density in the oxide layer (ETL) 34cs is preferably 50% or greater of the oxygen atom density in the oxide layer 74b. In this case, it is possible to suppress the formation of recombination centers due to dangling bonds and the like at the interface between the oxide layer (ETL) 34cs and the oxide layer 74b.

FIG. 20 is an energy band diagram for describing an electron injection barrier in the light-emitting element 5RC of the fourth embodiment.

As illustrated in FIG. 20, in the light-emitting element 5RC having a configuration in which the oxide layer 74b is formed between the oxide layer (ETL) 34cs and the light-emitting layer 24c of the first wavelength region, the oxygen atom density in the oxide layer (ETL) 34cs is less than the oxygen atom density in the oxide layer 74b. Thus, the electric dipole 1d (having a dipole moment including a component orientated in the direction from the oxide layer (ETL) 34cs to the oxide layer 74b) is formed at the interface between the oxide layer (ETL) 34cs and the oxide layer 74b. When the electric dipole 1d is formed in this manner, a vacuum level shift caused by the electric dipole 1d occurs at the interface between the oxide layer (ETL) 34cs and the oxide layer 74b, which is the interface where the electric dipole 1d is formed. As a result, as illustrated in FIG. 20, the band position of the oxide layer (ETL) 34cs is moved upward with respect to the band position of the light-emitting layer 24c of the first wavelength region. Specifically, the lower end of the ETL conduction band of the oxide layer (ETL) 34cs illustrated by a dashed line in FIG. 20 moves to the lower end of the ETL conduction band′ illustrated by a solid line in FIG. 20, and the upper end of the ETL valence band of the oxide layer (ETL) 34cs illustrated by a dashed line in FIG. 20 moves to the upper end of the ETL valence band′ illustrated by a solid line in the FIG. 20. By this movement, the energy difference ΔEc′ between the lower end of the conduction band (light-emitting layer conduction band) of the light-emitting layer 24c of the first wavelength region and the lower end of the ETL conduction band′ of the oxide layer 34cs is less than the energy difference ΔEc between the lower end of the conduction band (light-emitting layer conduction band) of the light-emitting layer 24c of the first wavelength region and the lower end (lower end of the ETL conduction band in FIG. 20) of the ETL conduction band of the oxide layer (ETL) 34cs in a case where the oxide layer 74b is not provided and there is no vacuum level shift. In addition, the vacuum level after band shift is indicated by a broken line at the top of FIG. 20.

In a case where the film thickness of the oxide layer 74b is sufficiently thin in the light-emitting element 5RC, because the electrons have conductivity via tunneling of the oxide layer 74b, the electron injection barrier height between the oxide layer (ETL) 34cs and the light-emitting layer 24c of the first wavelength region is effectively the energy difference ΔEc′ between the lower end of the conduction band (light-emitting layer conduction band) of the light-emitting layer 24c of the first wavelength region and the lower end of the ETL conduction band′ of the oxide layer (ETL) 34cs. Thus, in the light-emitting element 5RC, by also forming the oxide layer 74b in addition to that formed in the light-emitting element 5RA of the second embodiment, electron injection from the oxide layer (ETL) 34cs to the light-emitting layer 24c of the first wavelength region can be more efficient, and luminous efficiency can be improved.

FIG. 20 illustrates a case in which the lower end of the ETL conduction band′ of the oxide layer (ETL) 34cs is located below the lower end of the conduction band (light-emitting layer conduction band) of the light-emitting layer 24c of the first wavelength region. However, no such limitation is intended, and the lower end of the ETL conduction band′ of the oxide layer (ETL) 34cs may be located above the lower end of the conduction band (light-emitting layer conduction band) of the light-emitting layer 24c of the first wavelength region.

As illustrated in FIG. 20, the electron affinity EA1 of the oxide layer (ETL) 34cs is greater than the electron affinity EA4 of the light-emitting layer 24c of the first wavelength region, and the electron affinity EA3 of the oxide layer 74b is less than the electron affinity EA4 of the light-emitting layer 24c of the first wavelength region.

Also, as illustrated in FIG. 20, the energy difference between the conduction band lower end in the oxide layer 74b and the valence band upper end is greater than the energy difference between the lower end of the ETL conduction band′ in the oxide layer (ETL) 34cs and the upper end of the ETL valence band′. Thus, the oxide layer 74b has a smaller carrier density (electron density) and better insulating properties than the oxide layer (ETL) 34cs. Accordingly, electron conduction by tunneling occurs in the oxide layer 74b. As described above, the electron density in the oxide layer (ETL) 34cs, which is the electron transport layer, is greater than the electron density in the oxide layer 74b, and electrons are injected from the oxide layer (ETL) 34cs to the light-emitting layer 24c of the first wavelength region via tunneling of the oxide layer 74b.

In a case where the film thickness of the oxide layer 74b is sufficiently thin in the light-emitting element 5RC, because the electrons have conductivity via tunneling of the oxide layer 74b, the electron injection barrier height between the oxide layer (ETL) 34cs and the light-emitting layer 24c of the first wavelength region is effectively the energy difference ΔEc′ between the lower end of the conduction band (light-emitting layer conduction band) of the light-emitting layer 24c of the first wavelength region and the lower end of the ETL conduction band′ of the oxide layer (ETL) 34cs. Thus, in the light-emitting element 5RC, by also forming the oxide layer 74b in addition to that formed in the light-emitting element 5RB of the second embodiment, electron injection from the oxide layer (ETL) 34cs to the light-emitting layer 24c of the first wavelength region can be more efficient, and luminous efficiency can be improved.

The film thickness of the oxide layer 74b is preferably is from 0.2 nm to 5 nm. By setting the film thickness to be 5 nm or less, electron tunneling can be efficient. Additionally, by setting the film thickness to be 0.2 nm or greater, a sufficiently large dipole moment can be obtained. Furthermore, the film thickness is preferably from 0.8 nm to 3 nm or less. In this case, more efficient electron injection is possible.

Note that the carrier density (electron density) of the oxide layer (ETL) 34cs, which is the electron transport layer, is preferably 1×10¹⁵ cm³ or greater. Also, the carrier density (electron density) of the oxide layer (ETL) 34cs, which is the electron transport layer, is preferably 3×10¹⁷ cm³ or less.

(a) of FIG. 22 is a diagram listing an example of an inorganic oxide forming a typical electron transport layer and the oxygen atom density thereof. (b) of FIG. 22 is a diagram listing an example of an exemplary inorganic oxide and the oxygen atom density thereof. Note that the inorganic oxides listed in (a) of FIG. 22 are n-type semiconductors, and the inorganic oxides listed in (b) of FIG. 22 are insulators.

FIG. 23 is a diagram listing material, for the oxide layer (ETL) 34cs, selectable from examples of exemplary inorganic oxides forming the typical electron transport layer listed in (a) of FIG. 22, and material, for the oxide layer 74b, selectable from examples of exemplary inorganic oxides listed in (b) of FIG. 22.

Since the oxygen atom density in the oxide layer (ETL) 34cs needs to be less than the oxygen atom density in the oxide layer 74b, in a case where an inorganic oxide including zinc oxide is used as the oxide layer (ETL) 34cs, as the oxide layer 74b, an inorganic oxide (oxide of the fifth group) including at least one of aluminum oxide, gallium oxide, tantalum oxide, zirconium oxide, hafnium oxide, magnesium oxide, germanium oxide, silicon oxide, and a composite oxide including two or more cations of these oxides can be used.

In a case where an inorganic oxide including titanium oxide is used as the oxide layer (ETL) 34cs, as the oxide layer 74b, an inorganic oxide (oxide of the first group) including at least one of aluminum oxide, gallium oxide, and a composite oxide including two or more cations of these oxides can be used.

In a case where an inorganic oxide including indium oxide is used as the oxide layer (ETL) 34cs, as the oxide layer 74b, an inorganic oxide (oxide of the fourth group) including at least one of aluminum oxide, gallium oxide, tantalum oxide, zirconium oxide, hafnium oxide, magnesium oxide, germanium oxide, and a composite oxide including two or more cations of these oxides can be used.

In a case where an inorganic oxide including tin oxide is used as the oxide layer (ETL) 34cs, as the oxide layer 74b, an inorganic oxide (oxide of the second group) including at least one of aluminum oxide, gallium oxide, tantalum oxide, and a composite oxide including two or more cations of these oxides can be used.

In a case where an inorganic oxide including strontium titanate is used as the oxide layer (ETL) 34cs, as the oxide layer 74b, an inorganic oxide (oxide of the third group) including at least one of aluminum oxide, gallium oxide, tantalum oxide, zirconium oxide, hafnium oxide, and a composite oxide including two or more cations of these oxides can be used.

Also, in a case where the oxide layer (ETL) 34cs is formed from zinc oxide, the oxide layer 74b is preferably formed from at least one of aluminum oxide, gallium oxide, tantalum oxide, zirconium oxide, hafnium oxide, magnesium oxide, germanium oxide, silicon oxide, and a composite oxide including two or more cations of these oxides.

In a case where the oxide layer (ETL) 34cs is formed from titanium oxide, the oxide layer 74b is preferably formed from at least one of aluminum oxide, gallium oxide, and a composite oxide including two or more cations of these oxides.

In a case where the oxide layer (ETL) 34cs is formed from indium oxide, the oxide layer 74b is preferably formed from at least one of aluminum oxide, gallium oxide, tantalum oxide, zirconium oxide, hafnium oxide, magnesium oxide, germanium oxide, and a composite oxide including two or more cations of these oxides.

In a case where the oxide layer (ETL) 34cs is formed from tin oxide, the oxide layer 74b is preferably formed from at least one of aluminum oxide, gallium oxide, tantalum oxide, and a composite oxide including two or more cations of these oxides.

In a case where the oxide layer (ETL) 34cs is formed from strontium titanate, the oxide layer 74b is preferably formed from at least one of aluminum oxide, gallium oxide, tantalum oxide, zirconium oxide, hafnium oxide, and a composite oxide including two or more cations of these oxides.

Note that In₂O₃ in indium oxide and SnO₂ in tin oxide are normally not used as the electron transport layer (ETL) because the lower end of the conduction band is in a deep position, but, in a case where the electric dipole 1d is formed via the oxide layer 74b, they can be used.

The oxide layer (ETL) 34cs may be an oxide including one or more elements from among Zn, In, Sn, Ti, and Sr as a main component.

Also, the oxide layer (ETL) 34cs may be an oxide including one or more elements from among Zn, In, Sn, Ti, and Sr as the most abundant element other than oxygen.

The oxide layer 74b may be an oxide including one or more elements from among Al, Ga, Ta, Zr, Hf, Mg, Ge, and Si as a main component.

Also, the oxide layer 74b may be an oxide including one or more elements from among Al, Ga, Ta, Zr, Hf, Mg, Ge, and Si as the most abundant element other than oxygen.

Note that as described above, a composite oxide including a plurality of oxide cations may be used.

Also, the oxide layer 74b may also include cations included in the oxide layer (ETL) 34cs. In this case, lattice mismatch between the oxide layer (ETL) 34cs and the oxide layer 74b is alleviated, and the effect of the electric dipole 1d can be effectively obtained.

Note that the combination of the oxide layer (ETL) 34cs and the oxide layer 74b is not limited to this configuration, and it is only required that the oxygen atom density in the oxide layer 74a is less than the oxygen atom density in the oxide layer 74b.

Note that from the perspective of increasing the contact area between the oxide layer (ETL) 34cs and the oxide layer 74b, for the inorganic oxide forming the oxide layer (ETL) 34cs and the oxide layer 74b, particle-like components are preferably not used. In a case where particle-like components are used, an oxide layer formed of particles is preferably used as the lower layer, and an oxide layer not formed from particles is preferably formed as the upper layer. In other words, it is preferable to form an oxide layer formed from particles first, and an oxide layer not formed from particles thereafter. In other words, from among the oxide layer (ETL) 34cs and the oxide layer 74b, the layer formed at a position farthest from the substrate 10 (see FIG. 1) is preferably a continuous film. In this example, the continuous film is a dense film having a porosity of less than 1%.

Accordingly, in the light-emitting element 5RC, the oxygen atom density in the oxide layer (ETL) 34cs is less than the oxygen atom density in the oxide layer 74b. This allows for efficient electron injection and high luminous efficiency to be achieved.

Note that the oxygen atom density of the oxide layer in the present application is a unique value for the oxide layer (ETL) 34cs and for the oxide layer 74b and applies to the oxygen atom bulk density of the material forming the oxide layer (ETL) 34cs or oxide layer 74b. For example, for the materials listed in FIG. 22, the oxygen atom densities listed in FIG. 22 are applied.

### Fifth Embodiment

Next, the fifth embodiment of the present invention will be described with reference to FIG. 24. In the light-emitting element 5RD of the present embodiment, the oxide layer 34b (first oxide layer) and the oxide layer (HTL) 34a (second oxide layer), which is the hole transport layer, are layered in this order between the first electrode 22 and the light-emitting layer 24c of the first wavelength region from the first electrode 22 side, and the oxide layer (ETL) 34c (third oxide layer), which is the electron transport layer, and the oxide layer 34d (fourth oxide layer) are layered in this order between the light-emitting layer 24c of the first wavelength region and the second electrode 25 from the first electrode 22 side. This is different from the first to fourth embodiments. For convenience of explanation, components having the same functions as those described in diagrams of the first to fourth embodiments are appended with the same reference signs, and descriptions thereof may be omitted.

FIG. 24 is an image illustrating a schematic configuration of a light-emitting element 5RD according a fifth embodiment.

As illustrated in FIG. 24, in the light-emitting element 5RD of the present embodiment, the oxide layer 34b and the oxide layer (HTL) 34a, which is the hole transport layer, are layered in this order between the first electrode 22 and the light-emitting layer 24c of the first wavelength region from the first electrode 22 side, and the oxide layer (ETL) 34c (third oxide layer), which is the electron transport layer, and the oxide layer 34d (fourth oxide layer) are layered in this order between the light-emitting layer 24c of the first wavelength region and the second electrode 25 from the first electrode 22.

The oxide layer (HTL) 34a and the oxide layer 34b in the present embodiment can be the oxide layer (HTL) 34a and the oxide layer 34b, respectively, in the first embodiment described above.

Also, the oxide layer (ETL) 34c and the oxide layer 34d in the present embodiment can be the oxide layer (ETL) 34c and the oxide layer 34d, respectively, in the second embodiment described above.

The oxygen atom density in the oxide layer (HTL) 34a is less than the oxygen atom density in the oxide layer 34b, and the oxygen atom density in the oxide layer 34d is less than the oxygen atom density in the oxide layer (ETL) 34c. Thus, in the light-emitting element 5RD, efficient hole injection and electron injection to the light-emitting layer 24c of the first wavelength region is possible and high luminous efficiency can be achieved.

### Sixth Embodiment

Next, the sixth embodiment of the present invention will be described with reference to FIG. 25. In the light-emitting element 5RW of the present embodiment, the oxide layer 34b (fifth oxide layer), the oxide layer (HTL) 34as (sixth oxide layer), which is the hole transport layer, and the oxide layer 124b (seventh oxide layer) are layered in this order between the first electrode 22 and the light-emitting layer 24c of the first wavelength region from the first electrode 22 side, and the oxide layer 74b (eighth oxide layer), the oxide layer (ETL) 34cs (ninth oxide layer), and the oxide layer 34d (tenth oxide layer) are layered in this order between the light-emitting layer 24c of the first wavelength region and the second electrode 25 from the first electrode 22 side. This is different from the first to fifth embodiments. For convenience of explanation, components having the same functions as those described in diagrams of the first to fifth embodiments are appended with the same reference signs, and descriptions thereof may be omitted.

FIG. 25 is an image illustrating a schematic configuration of a light-emitting element 5RW according a sixth embodiment.

As illustrated in FIG. 25, in the light-emitting element 5RW of the present embodiment, the oxide layer 34b (fifth oxide layer), and the oxide layer (HTL) 34as (sixth oxide layer), which is the hole transport layer, and the oxide layer 124b (seventh oxide layer) are layered in this order between the first electrode 22 and the light-emitting layer 24c from the first electrode 22 side. Also, the oxide layer 74b (eighth oxide layer), the oxide layer (ETL) 34cs (ninth oxide layer), and the oxide layer 34d (tenth oxide layer) are layered in this order between the light-emitting layer 24c of the first wavelength region and the second electrode 25 from the first electrode 22 side.

The oxide layer 34b, the oxide layer (HTL) 34as, which is the hole transport layer, and the oxide layer 124b in the present embodiment can be the oxide layer 34b, the oxide layer (HTL) 34as, which is the hole transport layer, and the oxide layer 124b, respectively, in the third embodiment described above.

Also, the oxide layer 74b, the oxide layer (ETL) 34cs and the oxide layer 34d in the present embodiment can be the oxide layer 74b, the oxide layer (ETL) 34cs, and the oxide layer 34d, respectively, in the fourth embodiment described above.

Thus, the oxygen atom density in the oxide layer 124b is less than the oxygen atom density in the oxide layer (HTL) 34as, which is the hole transport layer, and the oxygen atom density in the oxide layer (HTL) 34as, which is the hole transport layer, is less than the oxygen atom density in the oxide layer 34b. Also, the oxygen atom density in the oxide layer 34d is less than the oxygen atom density in the oxide layer (ETL) 34cs, and the oxygen atom density in the oxide layer (ETL) 34cs is less than the oxygen atom density in the oxide layer 74b. Thus, in the light-emitting element 5RW, more efficient hole injection and electron injection to the light-emitting layer 24c of the first wavelength region is possible, and high luminous efficiency can be achieved.

In the embodiments described above, the layering order from the first electrode 22 to the second electrode 25 may be reversed. In other words, the light-emitting element 5R illustrated in FIG. 2, the light-emitting elements 5RE, 5RF, 5RG, 5RH illustrated in FIG. 7, the light-emitting element 5RA illustrated in FIG. 8, the light-emitting element 5RI, 5RJ, 5RK, 5RL illustrated in FIG. 13, the light-emitting element 5RB illustrated in FIG. 14, the light-emitting element 5RC illustrated in FIG. 19, the light-emitting element 5RD illustrated in FIG. 24, and the light-emitting element 5RW illustrated in FIG. 25 may have their configurations vertically reversed. In this case, at least one of the first electrode 22 and the second electrode 25 may be formed using a light-permeable material taking into consideration the light extraction direction of the display device 2. Also, one of the first electrode 22 or the second electrode 25 may be formed from a light-reflective material. Also, the oxygen atom density of the oxide layers in the present disclosure is a unique value for the oxide layers and applies to the oxygen atom bulk density of the material forming the oxide layers. For example, for the materials listed in FIGS. 5, 11, 17, and 22, the oxygen atom densities listed in FIGS. 5, 11, 17, and 22 are applied.

Note that, in each of the embodiments described above, the description focused on how, in order to form an electric dipole having a dipole moment in a direction which reduces the hole injection barrier height or the electron injection barrier height, the oxygen atom density of each layer (the first to tenth oxide layers) is determined, resulting in an improvement of the hole injection efficiency or the electron injection efficiency and enhancement of the luminous efficiency. However, the embodiments described above are not limited thereto, and the oxygen atom density in each layer (the first to tenth oxide layers) may be set such that at least one of the electric dipole 1a, 1b, 1c, and 1d is formed having a dipole moment with the reversed orientation of that in the embodiments described above.

That is, a light-emitting element according to the present disclosure may include:

a first electrode which is an anode;

a second electrode which is a cathode;

a light-emitting layer provided between the first electrode and the second electrode;

a first oxide layer provided between the first electrode or the second electrode and the light-emitting layer; and

a second oxide layer provided in contact with the first oxide layer and between the first oxide layer and the second electrode, wherein

of the first oxide layer and the second oxide layer, the layer closer to the light-emitting layer is formed from a semiconductor; and

an oxygen atom density in the second oxide layer is different from an oxygen atom density in the first oxide layer.

In this case, it is possible to effectively control the amount of electron injection or the amount of hole injection to the light-emitting layer, and the luminous efficiency can be improved.

Also, a light-emitting element according to the present disclosure may include:

a first electrode which is an anode;

a second electrode which is a cathode;

a light-emitting layer provided between the first electrode and the second electrode;

a first oxide layer provided between the first electrode or the second electrode and the light-emitting layer; and

a second oxide layer provided in contact with the first oxide layer and between the first oxide layer and the second electrode, wherein

of the first oxide layer and the second oxide layer, the layer closer to the light-emitting layer is formed from a semiconductor; and

an oxygen atom density in the first oxide layer is less than an oxygen atom density in the second oxide layer.

In this case, excessive electron injection or hole injection to the light-emitting layer can be effectively suppressed, and the luminous efficiency can be improved by suppressing unbalance between the amount of electron injection and the amount of hole injection.

In a light-emitting element, for example, in a case where the relationship between ΔEv illustrated in FIG. 15 and the ΔEc illustrated in FIG. 20 is ΔEv<ΔEc, or the relationship between ΔE_{F1} illustrated in (a) of FIG. 3 and ΔE_{F2} illustrated in (a) of FIG. 9 is ΔE_{F1}<ΔE_{F2}, the amount of hole injection to the light-emitting layer tends to be excessive with respect to the amount of electron injection. For example, in a case of excessive hole injection, regarding the layering order of the oxide layers for the light-emitting element 5R of the first embodiment illustrated in FIG. 2, for example, by reversing the size relationship between the oxygen atom density in the first oxide layer and the oxygen atom density in the second oxide layer, the orientation of the dipole moment of the electric dipole 1a may be reversed. That is, the oxygen atom density in the first oxide layer may be less than the oxygen atom density in the second oxide layer. In this case, the relationship between ΔE_{F1} illustrated in (a) of FIG. 3 and ΔE_{F1}′ illustrated in (b) of FIG. 3 is ΔE_{F1}′<ΔE_{F1} as illustrated in FIG. 3, which corresponds to the opposite of ΔE_{F1}′>ΔE_{F1}, allowing for excessive hole injection from the first electrode to the second oxide layer to be suppressed, and thus, excessive hole injection to the light-emitting layer to be suppressed. As a result, unbalance between hole injection and electron injection to the light-emitting layer is suppressed, and long-term reliability is improved. That is, the luminous efficiency after aging is enhanced.

Note that in this manner, regarding the layering order of the oxide layers in the light-emitting element 5R of the first embodiment illustrated in FIG. 2 for example, in a case where the oxygen atom density in the first oxide layer (oxide layer 34b) is less than the oxygen atom density in the second oxide layer (oxide layer 34a), the same material as used for the oxide layer 124b listed in FIG. 18 can be used for the first oxide layer, for example. In addition, as the second oxide layer, which is the layer closer to the light-emitting layer and formed from a semiconductor, the same material as used for the oxide layer (HTL) 34as listed in FIG. 18 can be used.

In addition, in a light-emitting element, in a case where ΔEv>ΔEc or ΔE_{F1}>ΔE_{F2}, for example, the amount of electron injection to the light-emitting layer tends to be excessive with respect to the amount of hole injection. For example, in a case of excessive electron injection, regarding the layering order of the oxide layers for the light-emitting element 5RA of the second embodiment illustrated in FIG. 8, for example, by reversing the size relationship between the oxygen atom density in the first oxide layer (oxide layer 34c) and the oxygen atom density in the second oxide layer (oxide layer 34d), the orientation of the dipole moment of the electric dipole 1b may be reversed. That is, the oxygen atom density in the first oxide layer may be less than the oxygen atom density in the second oxide layer. In this case, since ΔE_{F2}′>ΔE_{F2} holds true, excessive electron injection from the second electrode to the first oxide layer is suppressed, and as a result, excessive electron injection to the light-emitting layer is suppressed. As a result, unbalance between hole injection and electron injection to the light-emitting layer is suppressed, and long-term reliability is improved. That is, the luminous efficiency after aging is enhanced.

Note that in this manner, regarding the layering order of the oxide layers in the light-emitting element 5RA of the second embodiment illustrated in FIG. 8 for example, in a case where the oxygen atom density in the first oxide layer is less than the oxygen atom density in the second oxide layer, the same material as used for the oxide layer (ETL) 34cs illustrated in FIG. 23 can be used to the first oxide layer which is the layer closer to the light-emitting layer and formed from a semiconductor, for example. In addition, as the second oxide layer, the same material as used for the oxide layer 74b illustrated in FIG. 23 can be used.

Also, a light-emitting element according to the present disclosure may include.

a first electrode which is an anode;

a second electrode which is a cathode;

a light-emitting layer provided between the first electrode and the second electrode; and

a fifth oxide layer, a sixth oxide layer in contact with the fifth oxide layer, and a seventh oxide layer in contact with the sixth oxide layer provided in this order from a side closer to the first electrode between the first electrode and the light-emitting layer, wherein

the sixth oxide layer is formed from a semiconductor,

an oxygen atom density in the sixth oxide layer is different from an oxygen atom density in the fifth oxide layer; and

an oxygen atom density in the seventh oxide layer is different from the oxygen atom density of the sixth oxide layer.

In a light-emitting element, in a case where ΔEv<ΔEc or ΔE_{F1}<ΔE_{F2}, for example, the amount of hole injection to the light-emitting layer tends to be excessive with respect to the amount of electron injection. For example, in a case of excessive hole injection, regarding the layering order of the oxide layers for the light-emitting element 5RB of the third embodiment illustrated in FIG. 14, for example, the size relationship between the oxygen atom density in the fifth oxide layer (oxide layer 34b) and the oxygen atom density in the sixth oxide layer (oxide layer 34as) or the size relationship between the oxygen atom density in the sixth oxide layer (oxide layer 34as) and the seventh oxide layer (oxide layer 124b) may be reversed.

In a case where the oxygen atom density in the fifth oxide layer is less than the oxygen atom density in the sixth oxide layer, the orientation of the dipole moment of the electric dipole 1a is the opposite from that in the first embodiment and ΔE_{F1}′>ΔE_{F1} holds true. Thus, hole injection from the first electrode to the second oxide layer is suppressed, and as a result, excessive hole injection to the light-emitting layer is suppressed, and imbalance between hole injection and electron injection to the light-emitting layer is suppressed.

Note that in this manner, regarding the layering order of the oxide layers in the light-emitting element 5RB of the third embodiment illustrated in FIG. 14 for example, in a case where the oxygen atom density in the fifth oxide layer is less than the oxygen atom density in the sixth oxide layer, the same material as used for the oxide layer 124b listed in FIG. 18 can be used for the fifth oxide layer, for example. In addition, as the sixth oxide layer, the same material as used for the oxide layer (HTL) 34as listed in FIG. 18 can be used.

Also, in a case where the oxygen atom density in the sixth oxide layer is less than the oxygen atom density in the seventh oxide layer, the orientation of the dipole moment of the electric dipole 1c is the opposite from that in the third embodiment and ΔEv′>ΔEv holds true. As a result, excessive hole injection to the light-emitting layer is suppressed, and imbalance between hole injection and electron injection to the light-emitting layer is suppressed.

Also, regarding the layering order of the oxide layers in the light-emitting element 5RB of the third embodiment illustrated in FIG. 14 for example, in a case where the oxygen atom density in the sixth oxide layer is less than the oxygen atom density in the seventh oxide layer, the same material as used for the oxide layer (HTL) 34a listed in FIG. 6 can be used for the sixth oxide layer as described above, for example. In addition, as the seventh oxide layer, the same material as used for the oxide layer 34b listed in FIG. 6 can be used.

In this manner, the orientation (and size) of the electric dipole moment of the electric dipole 1a and the orientation (and size) of the electric dipole moments of the electric dipole 1c can be independently controlled, allowing the amount of hole injection to the light-emitting layer to be freely controlled. As a result, unbalance between hole injection and electron injection to the light-emitting layer is suppressed, and long-term reliability is improved. That is, the luminous efficiency after aging is enhanced.

Note that regarding the layering order of the oxide layers in the light-emitting element 5RB of the third embodiment illustrated in FIG. 14 for example, in a case where the oxygen atom density in the fifth oxide layer is less than the oxygen atom density in the sixth oxide layer and the oxygen atom density in the sixth oxide layer is less than the oxygen atom density in the seventh oxide layer, the same material as used for the oxide layer 124b listed in FIG. 18 can be used for the fifth oxide layer, for example. In addition, as the sixth oxide layer, the same material as used for the oxide layer (HTL) 34as listed in FIG. 18 can be used. Also, as the seventh oxide layer, from among the materials of the oxide layer 34b listed in FIG. 6, an inorganic oxide including at least one of aluminum oxide (for example, Al₂O₃), gallium oxide (for example, Ga₂O₃), tantalum oxide (for example, Ta₂O₅), zirconium oxide (for example, ZrO₂), hafnium oxide (for example, HfO₂), magnesium oxide (for example, MgO), or a composite oxide including two or more types of cations of these oxides can be used.

Also, a light-emitting element according to the present disclosure may include:

a first electrode which is an anode;

a second electrode which is a cathode;

a light-emitting layer provided between the first electrode and the second electrode; and

a fifth oxide layer, a sixth oxide layer in contact with the fifth oxide layer, and a seventh oxide layer in contact with the sixth oxide layer provided in this order from a side closer to the first electrode between the light-emitting layer and the second electrode, wherein

the sixth oxide layer is formed from a semiconductor,

an oxygen atom density in the sixth oxide layer is different from an oxygen atom density in the fifth oxide layer; and

an oxygen atom density in the seventh oxide layer is different from the oxygen atom density of the sixth oxide layer.

In a light-emitting element, in a case where ΔEv>ΔEc or ΔE_{F1}>ΔE_{F2}, for example, the amount of electron injection to the light-emitting layer tends to be excessive with respect to the amount of hole injection. For example, in a case of excessive electron injection, regarding the layering order of the oxide layers for the light-emitting element 5RC of the fourth embodiment illustrated in FIG. 19, for example, the size relationship between the oxygen atom density in the fifth oxide layer (oxide layer 74b) and the oxygen atom density in the sixth oxide layer (oxide layer 34cs) or the size relationship between the oxygen atom density in the sixth oxide layer (oxide layer 34cs) and the seventh oxide layer (oxide layer 34d) may be reversed.

In a case where the oxygen atom density in the fifth oxide layer is less than the oxygen atom density in the sixth oxide layer, the orientation of the dipole moment of the electric dipole 1b is the opposite from that in the second embodiment and ΔE_{F2}′>ΔE_{F2} holds true. Thus, electron injection from the second electrode to the first oxide layer is suppressed, and as a result, excessive electron injection to the light-emitting layer is suppressed, and imbalance between hole injection and electron injection to the light-emitting layer is suppressed.

Note that, regarding the layering order of the oxide layers in the light-emitting element 5RC of the fourth embodiment illustrated in FIG. 19 for example, in a case where the oxygen atom density in the fifth oxide layer is less than the oxygen atom density in the sixth oxide layer, a combination of the material for the oxide layer 74b and the materials for the oxide layer (ETL) 34c listed in FIG. 12 can be used as the combination of the material for the fifth oxide layer and the material for the sixth oxide layer.

Also, in a case where the oxygen atom density in the sixth oxide layer is less than the oxygen atom density in the seventh oxide layer, the orientation of the dipole moment of the electric dipole 1d is the opposite from that in the fourth embodiment and ΔEc′>ΔEc holds true. As a result, excessive electron injection to the light-emitting layer is suppressed, and imbalance between hole injection and electron injection to the light-emitting layer is suppressed.

Note that, regarding the layering order of the oxide layers in the light-emitting element 5RC of the fourth embodiment illustrated in FIG. 19 for example, in a case where the oxygen atom density in the sixth oxide layer is less than the oxygen atom density in the seventh oxide layer, a combination of the material for the oxide layer (ETL) 34cs and the material for the oxide layer 74b illustrated in FIG. 23 can be used as the combination of the material for the sixth oxide layer and the material for the seventh oxide layer.

In this manner, the orientation (and size) of the electric dipole moment of the electric dipole 1b and the orientation (and size) of the electric dipole moments of the electric dipole 1d can be independently controlled and formed, allowing the amount of electron injection to the light-emitting layer to be freely controlled. As a result, unbalance between hole injection and electron injection to the light-emitting layer is suppressed, and long-term reliability is improved. That is, the luminous efficiency after aging is enhanced.

Regarding the layering order of the oxide layers in the fourth embodiment illustrated in FIG. 19 for example, in a case where the oxygen atom density in the fifth oxide layer is less than the oxygen atom density in the sixth oxide layer and the oxygen atom density in the sixth oxide layer is less than the oxygen atom density in the seventh oxide layer, as the combination of the material for the fifth oxide layer and the material for the sixth oxide layer, for example, the combinations for the oxide layer 74b and the oxide layer (ETL) 34c listed in FIG. 12 can be used, and as the combination of the material for the sixth oxide layer and the material for the seventh oxide layer, for example, the combination for the oxide layer (ETL) 34cs and the oxide layer 74b illustrated in FIG. 23 can be used.

In a case where an inorganic oxide layer including zinc oxide is used as the material for the sixth oxide layer, as the fifth oxide layer, for example, as listed in FIG. 12, an inorganic oxide including at least one of yttrium oxide (for example, Y₂O₃), lanthanum oxide (for example, La₂O₃), strontium oxide (for example, SrO), or a composite oxide including two or more types of cations of these oxides can be used, and as the seventh oxide layer, for example, as illustrated in FIG. 23, an inorganic oxide including at least one of aluminum oxide (for example, Al₂O₃), gallium oxide (for example, Ga₂O₃(α), Ga₂O₃(β)), tantalum oxide (for example, Ta₂O₅), zirconium oxide (for example, ZrO₂), hafnium oxide (for example, HfO₂), magnesium oxide (for example, MgO), germanium oxide (for example, GeO₂), silicon oxide (for example, SiO₂), or a composite oxide including two or more types of cations of these oxides can be used.

In a similar manner, in a case where titanium oxide (for example, TiO₂) with a rutile structure is used as the material for the sixth oxide layer, as the fifth oxide layer, for example, as listed in FIG. 12, an inorganic oxide including at least one of aluminum oxide (for example, Al₂O₃), gallium oxide (for example, Ga₂O₃(α), Ga₂O₃(β)), tantalum oxide (for example, Ta₂O₅), zirconium oxide (for example, ZrO₂), hafnium oxide (for example, HfO₂), magnesium oxide (for example, MgO), germanium oxide (for example, GeO₂), silicon oxide (for example, SiO₂), yttrium oxide (for example, Y₂O₃), lanthanum oxide (for example, La₂O₃), strontium oxide (for example, SrO), or a composite oxide including two or more types of cations of these oxides may be used, and as the seventh oxide layer, for example, as illustrated in FIG. 23, an inorganic oxide including at least one of aluminum oxide (for example, Al₂O₃), gallium oxide (for example, Ga₂O₃(α), Ga₂O₃(β)), or a composite oxide including two or more types of cations of these oxides may be used.

In a similar manner, in a case where titanium oxide (for example, TiO₂) with an anatase structure is used as the material for the sixth oxide layer, as the fifth oxide layer, for example, as listed in FIG. 12, an inorganic oxide including at least one of gallium oxide(s) (for example, Ga₂O₃(β)), tantalum oxide (for example, Ta₂O₅), zirconium oxide (for example, ZrO₂), hafnium oxide (for example, HfO₂), magnesium oxide (for example, MgO), germanium oxide (for example, GeO₂), silicon oxide (for example, SiO₂), yttrium oxide (for example, Y₂O₃), lanthanum oxide (for example, La₂O₃), strontium oxide (for example, SrO), or a composite oxide including two or more types of cations of these oxides may be used, and as the seventh oxide layer, for example, as illustrated in FIG. 23, an inorganic oxide including at least one of aluminum oxide (for example, Al₂O₃), gallium oxide (for example, Ga₂O₃(α), Ga₂O₃(β)), or a composite oxide including two or more types of cations of these oxides may be used.

In a similar manner, in a case where an inorganic oxide layer including indium oxide is used as the material for the sixth oxide layer, for example, as listed in FIG. 12, an inorganic oxide including at least one of silicon oxide (for example, SiO₂) yttrium oxide (for example, Y₂O₃), lanthanum oxide (for example, La₂O₃), strontium oxide (for example, SrO), or a composite oxide including two or more types of cations of these oxides can be used, and as the seventh oxide layer, for example, as illustrated in FIG. 23, an inorganic oxide including at least one of tantalum oxide (for example, Ta₂O₅), zirconium oxide (for example, ZrO₂), hafnium oxide (for example, HfO₂), magnesium oxide (for example, MgO), germanium oxide (for example, GeO₂), or a composite oxide including two or more types of cations of these oxides can be used.

In a similar manner, in a case where tin oxide is used as the material for the sixth oxide layer, for example, as listed in FIG. 12, an inorganic oxide including at least one of hafnium oxide (for example, HfO₂), magnesium oxide (for example, MgO), germanium oxide (for example, GeO₂), silicon oxide (for example, SiO₂), yttrium oxide (for example, Y₂O₃), lanthanum oxide (for example, La₂O₃), strontium oxide (for example, SrO), or a composite oxide including two or more types of cations of these oxides may be used, and as the seventh oxide layer, for example, as illustrated in FIG. 23, an inorganic oxide including at least one of aluminum oxide (for example, Al₂O₃), gallium oxide (for example, Ga₂O₃(α), Ga₂O₃(β)), tantalum oxide, (for example, Ta₂O₅), or a composite oxide including two or more types of cations of these oxides may be used.

In a similar manner, in a case where strontium titanate is used as the material for the sixth oxide layer, for example, as listed in FIG. 12, an inorganic oxide including at least one of germanium oxide (for example, GeO₂), silicon oxide (for example, SiO₂), yttrium oxide (for example, Y₂O₃), lanthanum oxide (for example, La₂O₃), strontium oxide (for example, SrO), or a composite oxide including two or more types of cations of these oxides may be used, and as the seventh oxide layer, for example, as illustrated in FIG. 23, an inorganic oxide including at least one of aluminum oxide (for example, Al₂O₃), gallium oxide (for example, Ga₂O₃(α), Ga₂O₃(β)), tantalum oxide, (for example, Ta₂O₅), zirconium oxide (for example, ZrO₂), hafnium oxide (for example, HfO₂), or a composite oxide including two or more types of cations of these oxides may be used.

Furthermore, in the light-emitting element 5RD of fifth embodiment illustrated in FIG. 24 and the light-emitting element 5RW of the sixth embodiment illustrated in FIG. 25, by the oxygen atom density in each oxide layer being determined in a similar manner to that described above, the amount of hole injection and the amount of electron injection to the light-emitting layer can be freely controlled. As a result, unbalance between hole injection and electron injection to the light-emitting layer is suppressed, and long-term reliability is improved. That is, the luminous efficiency after aging is enhanced.

Note that the oxygen atom density of the oxide layers in the present disclosure is a unique value for the oxide layers and applies to the oxygen atom bulk density of the material forming the oxide layers. For example, for the materials listed in FIGS. 5, 11, 17, and 22, the oxygen atom densities listed in FIGS. 5, 11, 17, and 22 are applied. Note that the oxygen atom density of a composite oxide can be determined by, for the total cations contained in the composite oxide, finding the weighted average by finding the sum of: multiplying the oxygen atom density of the oxide of each cation alone by the composition ratio of each cation to the total cation contained in the composite oxide.

That is, in a composite oxide including N types of cations Ai (i=1, 2, 3, . . . , N), the ratio of the number density of cations Ai to the sum of the number density of all cations (the composition ratio of each cation relative to the total cations including in the composite oxide) is Xi, and when the oxygen atom density of the oxide including only the cation Ai as the cation (oxide of the cation Ai alone) is Di, the oxygen atom density MDi of the composite oxide is expressed as follows (Formula A). However, the sum of Xi (i=1, 2, 3, . . . , N) is 1 as shown in Formula B below.

$$\begin{matrix}[ Expression 1 ] & \\ MDi = {\sum }_{i = 1}^{N} Xi \cdot Di & ( Formula A )\end{matrix}$$

$$\begin{matrix}[ Expression 2 ] & \\ {\sum }_{i = 1}^{N} Xi = 1 & ( Formula B )\end{matrix}$$

### Supplement

### First Aspect

A light-emitting element, including.

a first electrode which is an anode;

a second electrode which is a cathode;

a light-emitting layer provided between the first electrode and the second electrode;

a first oxide layer provided between the first electrode or the second electrode and the light-emitting layer; and

a second oxide layer provided in contact with the first oxide layer and between the first oxide layer and the second electrode, wherein

of the first oxide layer and the second oxide layer, the layer closer to the light-emitting layer is formed from a semiconductor; and

an oxygen atom density in the second oxide layer is different from an oxygen atom density in the first oxide layer.

### Second Aspect

The light-emitting element according to the first aspect, wherein the oxygen atom density in the second oxide layer is less than the oxygen atom density in the first oxide layer.

### Third Aspect

The light-emitting element according to the second aspect, wherein the first oxide layer is formed of an inorganic oxide.

### Fourth Aspect

The light-emitting element according to the second or third aspect, wherein the second oxide layer is formed of an inorganic oxide.

### Fifth Embodiment

The light-emitting element according to any one of the second to fourth aspects, wherein of the first oxide layer and the second oxide layer, the layer farther from the light-emitting layer is formed of an insulator.

### Sixth Aspect

The light-emitting element according to any one of the second to fifth aspects, wherein an electric dipole is formed at an interface between the first oxide layer and the second oxide layer.

### Seventh Aspect

The light-emitting element according to the sixth aspect, wherein the electric dipole has a dipole moment including a component orientated from the second oxide layer toward the first oxide layer.

### Eighth Aspect

The light-emitting element according to any one of the second to seventh aspects, wherein of the first oxide layer and the second oxide layer, at least the layer on an upper layer side is formed of a continuous film.

### Ninth Aspect

The light-emitting element according to any one of the second to eighth aspects, wherein of the first oxide layer and the second oxide layer, at least an upper surface of the layer on a lower layer side includes grains.

### Tenth Aspect

The light-emitting element according to any one of the second to eighth aspects, wherein of the first oxide layer and the second oxide layer, at least a portion of the upper surface of the layer on a lower layer side is polycrystallized.

### Eleventh Aspect

The light-emitting element according to any one of the second to seventh aspects, wherein of the first oxide layer and the second oxide layer, the layer of a lower layer side is formed into island shapes.

### Twelfth Aspect

The light-emitting element according to any one of the second to eleventh aspects, wherein of the first oxide layer and the second oxide layer, the layer on an upper layer side is formed of an amorphous oxide.

### Thirteenth Aspect

The light-emitting element according to any one of the second to twelfth aspects, wherein the first oxide layer and the second oxide layer are provided between the first electrode and the light-emitting layer; and the second oxide layer is formed from a p-type semiconductor.

### Fourteenth Aspect

The light-emitting element according to the thirteenth aspect, wherein the second oxide layer is formed of at least one of nickel oxide, copper aluminate, or copper(I) oxide.

### Fifteenth Aspect

The light-emitting element according to the thirteenth aspect, wherein the second oxide layer is formed of an oxide including one or more elements from among Ni, Al, and Cu as a main component.

### Sixteenth Aspect

The light-emitting element according to the thirteenth aspect, wherein the second oxide layer is formed of an oxide in which a most abundant element other than oxygen is any one of Ni, Ai, or Cu.

### Seventeenth Aspect

The light-emitting element according to any one of the thirteenth to sixteenth aspects, wherein the first oxide layer is formed of at least one of aluminum oxide, gallium oxide, tantalum oxide, zirconium oxide, hafnium oxide, magnesium oxide, germanium oxide, silicon oxide, yttrium oxide, lanthanum oxide, strontium oxide, or a composite oxide including two or more types of cations of these oxides.

### Eighteenth Aspect

The light-emitting element according to any one of the thirteenth to sixteenth aspects, wherein the first oxide layer is formed of any one of aluminum oxide, gallium oxide, tantalum oxide, zirconium oxide, hafnium oxide, magnesium oxide, germanium oxide, silicon oxide, yttrium oxide, lanthanum oxide, strontium oxide, or a composite oxide including two or more types of cations of these oxides.

### Nineteenth Aspect

The light-emitting element according to any one of the thirteenth to sixteenth aspects, wherein the first oxide layer is formed of an oxide including one or more elements from among Al, Ga, Ta, Zr, Hf, Mg, Ge, Si, Y, La, and Sr as a main component.

### Twentieth Aspect

The light-emitting element according to any one of the thirteenth to sixteenth aspects, wherein the first oxide layer is formed of an oxide in which a most abundant element other than oxygen is any one of Al, Ga, Ta, Zr, Hf, Mg, Ge, Si, Y, La, or Sr.

### Twenty-First Aspect

A light-emitting element, including.

a first electrode which is an anode;

a second electrode which is a cathode;

a light-emitting layer provided between the first electrode and the second electrode:

a first oxide layer provided between the first electrode and the light-emitting layer; and

a second oxide layer provided in contact with the first oxide layer and between the first oxide layer and the light-emitting layer, wherein

the second oxide layer includes at least one of nickel oxide or copper aluminate; and

the first oxide layer includes at least one of aluminum oxide, gallium oxide, tantalum oxide, zirconium oxide, hafnium oxide, magnesium oxide, or a composite oxide including two or more types of cations of these oxides.

### Twenty-Second Aspect

A light-emitting element, including:

a first electrode which is an anode;

a second electrode which is a cathode;

a light-emitting layer provided between the first electrode and the second electrode;

a first oxide layer provided between the first electrode and the light-emitting layer; and

a second oxide layer provided in contact with the first oxide layer and between the first oxide layer and the light-emitting layer, wherein

the second oxide layer includes copper(I) oxide; and

the first oxide layer includes at least one of aluminum oxide, gallium oxide, tantalum oxide, zirconium oxide, hafnium oxide, magnesium oxide, germanium oxide, silicon oxide, yttrium oxide, lanthanum oxide, strontium oxide, or a composite oxide including two or more types of cations of these oxides.

### Twenty-Third Aspect

The light-emitting element according to any one of the thirteenth to twenty-second aspects, wherein a hole density in the second oxide layer is greater than a hole density in the first oxide layer.

### Twenty-Fourth Aspect

The light-emitting element according to any one of the thirteenth to twenty-third aspects, wherein an energy difference between a conduction band lower end and a valence band upper end in the first oxide layer is greater than an energy difference between a conduction band lower end and a valence band upper end in the second oxide layer.

### Twenty-Fifth Aspect

The light-emitting element according to any one of the thirteenth to twenty-fourth aspects, wherein an energy difference between a vacuum level and a Fermi level of the first electrode is less than an ionization potential of the light-emitting layer; and the ionization potential of the light-emitting layer is less than an ionization potential of the first oxide layer.

### Twenty-Sixth Aspect

The light-emitting element according to any one of the thirteenth to twenty-fifth aspects, wherein a film thickness of the first oxide layer is from 0.2 nm to 5 nm.

### Twenty-Seventh Aspect

The light-emitting element according to the twenty-sixth aspect, wherein the film thickness of the first oxide layer is from 0.8 nm to less than 3 nm.

### Twenty-Eighth Aspect

The light-emitting element according to any one of the thirteenth to twenty-seventh aspects, wherein the oxygen atom density in the second oxide layer is from 50% to 90% of the oxygen atom density in the first oxide layer.

### Twenty-Ninth Aspect

The light-emitting element according to the twenty-eighth aspect, wherein the oxygen atom density in the second oxide layer is from 50% to 80% of the oxygen atom density in the first oxide layer.

### Thirtieth Aspect

The light-emitting element according to any one of the thirteenth to twenty-ninth aspects, wherein the oxygen atom density in the second oxide layer is 50% or greater of the oxygen atom density in the first oxide layer.

### Thirty-First Aspect

The light-emitting element according to any one of the second to twelfth aspects, wherein the first oxide layer and the second oxide layer are provided between the light-emitting layer and the second electrode; and the first oxide layer is formed from an n-type semiconductor.

### Thirty-Second Aspect

The light-emitting element according to the thirty-first aspect, wherein the first oxide layer includes any one of titanium oxide, tin oxide, strontium titanate, indium oxide, or zinc oxide.

### Thirty-Third Aspect

The light-emitting element according to the thirty-first aspect, wherein the first oxide layer is formed of an oxide including one or more elements from among Ti, Sn, Sr, In, and Zn as a main component.

### Thirty-Fourth Aspect

The light-emitting element according to the thirty-first aspect, wherein the first oxide layer is formed of an oxide in which a most abundant element other than oxygen is any one of Ti, Sn, Sr, In, or Zn.

### Thirty-Fifth Aspect

The light-emitting element according to any one of the thirty-first to thirty-fourth aspects, wherein the second oxide layer is formed of at least one of aluminum oxide, gallium oxide, tantalum oxide, zirconium oxide, hafnium oxide, magnesium oxide, germanium oxide, silicon oxide, yttrium oxide, lanthanum oxide, strontium oxide, or a composite oxide including two or more types of cations of these oxides.

### Thirty-Sixth Aspect

The light-emitting element according to any one of the thirty-first to thirty-fourth aspects, wherein the second oxide layer is formed of any one of aluminum oxide, gallium oxide, tantalum oxide, zirconium oxide, hafnium oxide, magnesium oxide, germanium oxide, silicon oxide, yttrium oxide, lanthanum oxide, strontium oxide, or a composite oxide including two or more types of cations of these oxides.

### Thirty-Seventh Aspect

The light-emitting element according to any one of the thirty-first to thirty-fourth aspects, wherein the second oxide layer is formed of an oxide including one or more elements from among Al, Ga, Ta, Zr, Hf, Mg, Ge, Si, Y, La, and Sr as a main component.

### Thirty-Eighth Aspect

The light-emitting element according to any one of the thirty-first to thirty-fourth aspects, wherein the second oxide layer is formed of an oxide in which a most abundant element other than oxygen is any one of Al, Ga, Ta, Zr, Hf, Mg, Ge, Si, Y, La, or Sr.

### Thirty-Ninth Aspect

A light-emitting element, including.

a first electrode which is an anode;

a second electrode which is a cathode;

a light-emitting layer provided between the first electrode and the second electrode;

a first oxide layer provided between the second electrode and the light-emitting layer; and

a second oxide layer provided in contact with the first oxide layer and between the first oxide layer and the second electrode, wherein

an oxide including at least one of aluminum oxide, gallium oxide, tantalum oxide, zirconium oxide, hafnium oxide, magnesium oxide, germanium oxide, silicon oxide, yttrium oxide, lanthanum oxide, strontium oxide, or a composite oxide including two or more types of cations of these oxides is an oxide of a first group;

an oxide including at least one of gallium oxide (β), tantalum oxide, zirconium oxide, hafnium oxide, magnesium oxide, germanium oxide, silicon oxide, yttrium oxide, lanthanum oxide, strontium oxide, or a composite oxide including two or more types of cations of these oxides is an oxide of a second group;

an oxide including at least one of hafnium oxide, magnesium oxide, germanium oxide, silicon oxide, yttrium oxide, lanthanum oxide, strontium oxide, or a composite oxide including two or more types of cations of these oxides is an oxide of a third group;

an oxide including at least one of germanium oxide, silicon oxide, yttrium oxide, lanthanum oxide, strontium oxide, or a composite oxide including two or more types of cations of these oxides is an oxide of a fourth group;

an oxide including at least one of silicon oxide, yttrium oxide, lanthanum oxide, strontium oxide, or a composite oxide including two or more types of cations of these oxides is an oxide of a fifth group;

an oxide including at least one of yttrium oxide, lanthanum oxide, strontium oxide, or a composite oxide including two or more types of cations of these oxides is an oxide of a sixth group;

in a case where the first oxide layer includes a rutile-type titanium oxide, the second oxide layer is an oxide of the first group;

in a case where the first oxide layer includes an anatase-type of titanium oxide, the second oxide layer is an oxide of the second group;

in a case where the first oxide layer includes tin oxide, the second oxide layer is an oxide of the third group;

in a case where the first oxide layer includes strontium titanium, the second oxide layer is an oxide of the fourth group;

in a case where the first oxide layer includes indium oxide, the second oxide layer is an oxide of the fifth group; and

in a case where the first oxide layer includes zinc oxide, the second oxide layer is an oxide of the sixth group.

### Fortieth Aspect

The light-emitting element according to the thirty-ninth aspect, wherein the first oxide layer is formed of a rutile-type titanium oxide; and the second oxide layer is formed of at least one of aluminum oxide, gallium oxide, tantalum oxide, zirconium oxide, hafnium oxide, magnesium oxide, germanium oxide, silicon oxide, yttrium oxide, lanthanum oxide, strontium oxide, or a composite oxide including two or more types of cations of these oxides.

### Forty-First Aspect

The light-emitting element according to the thirty-ninth aspect, wherein the first oxide layer is formed of an anatase-type titanium oxide; and the second oxide layer is formed of at least one of gallium(s) oxide, tantalum oxide, zirconium oxide, hafnium oxide, magnesium oxide, germanium oxide, silicon oxide, yttrium oxide, lanthanum oxide, strontium oxide, or a composite oxide including two or more types of cations of these oxides.

### Forty-Second Aspect

The light-emitting element according to the thirty-ninth aspect, wherein the first oxide layer is formed of tin oxide; and the second oxide layer is formed of at least one of hafnium oxide, magnesium oxide, germanium oxide, silicon oxide, yttrium oxide, lanthanum oxide, strontium oxide, or a composite oxide including two or more types of cations of these oxides.

### Forty-Third Aspect

The light-emitting element according to the thirty-ninth aspect, wherein the first oxide layer is formed of strontium titanate; and the second oxide layer is formed of at least one of germanium oxide, silicon oxide, yttrium oxide, lanthanum oxide, strontium oxide, or a composite oxide including two or more types of cations of these oxides.

### Forty-Fourth Aspect

The light-emitting element according to the thirty-ninth aspect, wherein the first oxide layer is formed of indium oxide; and the second oxide layer is formed of at least one of silicon oxide, yttrium oxide, lanthanum oxide, strontium oxide, or a composite oxide including two or more types of cations of these oxides.

### Forty-Fifth Aspect

The light-emitting element according to the thirty-ninth aspect, wherein the first oxide layer is formed of zinc oxide; and the second oxide layer is formed of at least one of yttrium oxide, lanthanum oxide, strontium oxide, or a composite oxide including two or more types of cations of these oxides.

### Forty-Sixth Aspect

The light-emitting element according to any one of the thirty-first to forty-fifth aspects, wherein an electron density in the first oxide layer is greater than an electron density in the second oxide layer.

### Forty-Seventh Aspect

The light-emitting element according to any one of the thirty-first to forty-sixth aspects, wherein an energy difference between a conduction band lower end and a valence band upper end in the second oxide layer is greater than an energy difference between a conduction band lower end and a valence band upper end in the first oxide layer.

### Forty-Eighth Aspect

The light-emitting element according to any one of the thirty-first to forty-seventh aspects, wherein an energy difference between a vacuum level and a Fermi level of the second electrode is greater than an electron affinity of the first oxide layer; and an electron affinity of the second oxide layer is less than the electron affinity of the first oxide layer.

### Forty-Ninth Aspect

The light-emitting element according to any one of the thirty-first to forty-eighth aspects, wherein a film thickness of the second oxide layer is from 0.2 nm to 5 nm.

### Fiftieth Aspect

The light-emitting element according to the forty-ninth aspect, wherein the film thickness of the second oxide layer is from 0.8 nm to less than 3 nm.

### Fifty-First Aspect

The light-emitting element according to any one of the thirty-first to fiftieth aspects, wherein the oxygen atom density in the second oxide layer is from 50% to 90% of the oxygen atom density in the first oxide layer.

### Fifty-Second Aspect

The light-emitting element according to the fifty-first aspect, wherein the oxygen atom density in the second oxide layer is from 50% to 80% of the oxygen atom density in the first oxide layer.

### Fifty-Third Aspect

The light-emitting element according to any one of the thirty-first to fifty-second aspects, wherein the oxygen atom density in the second oxide layer is 50% or greater of the oxygen atom density in the first oxide layer.

### Fifty-Fourth Aspect

The light-emitting element according to any one of the thirteenth to thirtieth aspects, further comprising: a third oxide layer provided between the light-emitting layer and the second electrode; and a fourth oxide layer provided in contact with the third oxide layer and between the third oxide layer and the second electrode, wherein the third oxide layer is formed from an n-type semiconductor; and an oxygen atom density in the fourth oxide layer is less than an oxygen atom density in the third oxide layer.

### Fifty-Fifth Aspect

A light-emitting element, including:

a first electrode which is an anode;

a second electrode which is a cathode;

a light-emitting layer provided between the first electrode and the second electrode; and

a fifth oxide layer, a sixth oxide layer in contact with the fifth oxide layer, and a seventh oxide layer in contact with the sixth oxide layer provided in this order from a side closer to the first electrode between the first electrode and the light-emitting layer or between the light-emitting layer and the second electrode, wherein

the sixth oxide layer is formed from a semiconductor,

an oxygen atom density in the sixth oxide layer is different from an oxygen atom density in the fifth oxide layer; and

an oxygen atom density in the seventh oxide layer is different from the oxygen atom density of the sixth oxide layer.

### Fifty-Sixth Aspect

The light-emitting element according to the fifty-fifth aspect, wherein the oxygen atom density in the sixth oxide layer is less than the oxygen atom density in the fifth oxide layer; and the oxygen atom density in the seventh oxide layer is less than the oxygen atom density in the sixth oxide layer.

### Fifty-Seventh Aspect

The light-emitting element according to the fifty-sixth aspect, wherein the fifth oxide layer, the sixth oxide layer, and the seventh oxide layer are provided between the first electrode and the light-emitting layer; and the sixth oxide layer is formed from a p-type semiconductor.

### Fifty-Eighth Aspect

The light-emitting element according to the fifty-sixth aspect, wherein the fifth oxide layer, the sixth oxide layer, and the seventh oxide layer are provided between the light-emitting layer and the second electrode; and the sixth oxide layer is formed from an n-type semiconductor.

### Fifty-Ninth Aspect

The light-emitting element according to the fifty-seventh aspect, wherein an electric dipole is formed at an interface between the fifth oxide layer and the sixth oxide layer; and the electric dipole has a dipole moment including a component orientated from the sixth oxide layer toward the fifth oxide layer.

### Sixtieth Aspect

The light-emitting element according to the fifty-eighth aspect, wherein an electric dipole is formed at an interface between the sixth oxide layer and the seventh oxide layer; and the electric dipole has a dipole moment including a component orientated from the seventh oxide layer toward the sixth oxide layer.

### Sixty-First Aspect

The light-emitting element according to the fifty-seventh aspect, wherein the sixth oxide layer is formed of at least one of nickel oxide or copper aluminate.

### Sixty-Second Aspect

The light-emitting element according to the fifty-seventh aspect, wherein the sixth oxide layer is formed of an oxide including one or more elements from among Ni, Al, and Cu as a main component.

### Sixty-Third Aspect

The light-emitting element according to the fifty-seventh aspect, wherein the sixth oxide layer is formed of an oxide in which a most abundant element other than oxygen is any one of Ni, Ai, or Cu.

### Sixty-Fourth Aspect

The light-emitting element according to any one of the fifty-seventh and sixty-first to sixty-third aspects, wherein the fifth oxide layer is formed of at least one of aluminum oxide, gallium oxide, tantalum oxide, zirconium oxide, hafnium oxide, magnesium oxide, or a composite oxide including two or more types of cations of these oxides.

### Sixty-Fifth Aspect

The light-emitting element according to any one of the fifty-seventh and sixty-first to sixty-third aspects, wherein the fifth oxide layer is formed of any one of aluminum oxide, gallium oxide, tantalum oxide, zirconium oxide, hafnium oxide, magnesium oxide, or a composite oxide including two or more types of cations of these oxides.

### Sixty-Sixth Aspect

The light-emitting element according to any one of the fifty-seventh and sixty-first to sixty-third aspects, wherein the fifth oxide layer is formed of an oxide including one or more elements from among Al, Ga, Ta, Zr, Hf, and Mg as a main component.

### Sixty-Seventh Aspect

The light-emitting element according to any one of the fifty-seventh and sixty-first to sixty-third aspects, wherein the fifth oxide layer is formed of an oxide in which a most abundant element other than oxygen is any one of Al, Ga, Ta, Zr, Hf, or Mg.

### Sixty-Eighth Aspect

The light-emitting element according to any one of the fifty-seventh and sixty-first to sixty-seventh aspects, wherein the seventh oxide layer is formed of at least one of strontium oxide, lanthanum oxide, yttrium oxide, silicon oxide, germanium oxide, or a composite oxide including two or more types of cations of these oxides.

### Sixty-Ninth Aspect

The light-emitting element according to any one of the fifty-seventh and sixty-first to sixty-seventh aspects, wherein the seventh oxide layer is formed of any one of strontium oxide, lanthanum oxide, yttrium oxide, silicon oxide, germanium oxide, or a composite oxide including two or more types of cations of these oxides.

### Seventieth Aspect

The light-emitting element according to any one of the fifty-seventh and sixty-first to sixty-seventh aspects, wherein the seventh oxide layer is formed of an oxide including one or more elements from among Sr, La, Y, Si, and Ge as a main component.

### Seventy-First Aspect

The light-emitting element according to any one of the fifty-seventh and sixty-first to sixty-seventh aspects, wherein the seventh oxide layer is formed of an oxide in which a most abundant element other than oxygen is any one of Sr, La, Y, Si, or Ge.

### Seventy-Second Aspect

A light-emitting element, including:

a first electrode which is an anode;

a second electrode which is a cathode;

a light-emitting layer provided between the first electrode and the second electrode;

a fifth oxide layer provided between the first electrode and the light-emitting layer; and

a sixth oxide layer provided in contact with the fifth oxide layer and between the fifth oxide layer and the light-emitting layer; and

a seventh oxide layer provided in contact with the sixth oxide layer and between the sixth oxide layer and the light-emitting layer, wherein

the sixth oxide layer is formed from a semiconductor;

the fifth oxide layer includes at least one of aluminum oxide, gallium oxide, tantalum oxide, zirconium oxide, hafnium oxide, magnesium oxide, or a composite oxide including two or more types of cations of these oxides;

the sixth oxide layer includes at least one of nickel oxide or copper aluminate; and

the seventh oxide layer includes at least one of strontium oxide, lanthanum oxide, yttrium oxide, silicon oxide, germanium oxide, or a composite oxide including two or more types of cations of these oxides.

### Seventy-Third Aspect

The light-emitting element according to any one of the fifty-seventh and sixty-first to seventy-second aspects, wherein a hole density in the sixth oxide layer is greater than a hole density in the seventh oxide layer.

### Seventy-Fourth Aspect

The light-emitting element according to any one of the fifty-seventh and sixty-first to seventy-third aspects, wherein an energy difference between a conduction band lower end and a valence band upper end in the seventh oxide layer is greater than an energy difference between a conduction band lower end and a valence band upper end in the sixth oxide layer.

### Seventy-Fifth Aspect

The light-emitting element according to any one of the fifty-seventh and sixty-first to seventy-fourth aspects, wherein an energy difference between a vacuum level and a Fermi level of the first electrode is less than an ionization potential of the sixth oxide layer; and the ionization potential of the sixth oxide layer is less than an ionization potential of the seventh oxide layer.

### Seventy-Sixth Aspect

The light-emitting element according to any one of the fifty-seventh and sixty-first to seventy-fifth aspects, wherein a film thickness of the seventh oxide layer is from 0.2 nm to 5 nm.

### Seventy-Seventh Aspect

The light-emitting element according to the seventy-sixth aspect, wherein the film thickness of the seventh oxide layer is from 0.8 nm to less than 3 nm.

### Seventy-Eighth Aspect

The light-emitting element according to any one of the fifty-seventh and sixty-first to seventy-seventh aspects, wherein the oxygen atom density in the seventh oxide layer is from 50% to 90% of the oxygen atom density in the sixth oxide layer.

### Seventy-Ninth Aspect

The light-emitting element according to the seventy-eighth aspect, wherein the oxygen atom density in the seventh oxide layer is from 50% to 80% of the oxygen atom density in the sixth oxide layer.

### Eightieth Aspect

The light-emitting element according to any one of the fifty-seventh and sixty-first to seventy-seventh aspects, wherein the oxygen atom density in the seventh oxide layer is 50% or greater of the oxygen atom density in the sixth oxide layer.

### Eighty-First Aspect

The light-emitting element according to the fifty-eighth aspect, wherein the sixth oxide layer includes at least one of zinc oxide, titanium oxide, indium oxide, tin oxide, or strontium titanate.

### Eighty-Second Aspect

The light-emitting element according to the fifty-sixth aspect, wherein the sixth oxide layer is formed of an oxide including one or more elements from among Zn, Ti, In, Sn, and Sr as a main component.

### Eighty-Third Aspect

The light-emitting element according to any one of the fifty-eighth, eighty-first, or eighty-second aspects, wherein the seventh oxide layer is formed of at least one of aluminum oxide, gallium oxide, tantalum oxide, zirconium oxide, hafnium oxide, magnesium oxide, germanium oxide, silicon oxide, yttrium oxide, lanthanum oxide, strontium oxide, or a composite oxide including two or more types of cations of these oxides.

### Eighty-Fourth Aspect

The light-emitting element according to any one of the fifty-eighth, eighty-first, or eighty-second aspects, wherein the seventh oxide layer is formed of any one of aluminum oxide, gallium oxide, tantalum oxide, zirconium oxide, hafnium oxide, magnesium oxide, germanium oxide, silicon oxide, yttrium oxide, lanthanum oxide, strontium oxide, or a composite oxide including two or more types of cations of these oxides.

### Eighty-Fifth Aspect

The light-emitting element according to any one of the fifty-eighth, eighty-first, or eighty-second aspects, wherein the seventh oxide layer is formed of an oxide including one or more elements from among Al, Ga, Ta, Zr, Hf, Mg, Ge, Si, Y, La, and Sr as a main component.

### Eighty-Sixth Aspect

The light-emitting element according to any one of the fifty-eighth, eighty-first, or eighty-second aspects, wherein the seventh oxide layer is formed of an oxide in which a most abundant element other than oxygen is any one of Al, Ga, Ta, Zr, Hf, Mg, Ge, Si, Y, La, or Sr.

### Eighty-Seventh Aspect

The light-emitting element according to any one of the fifty-eighth and eighty-first to eighty-sixth aspects, wherein the fifth oxide layer is formed of at least one of aluminum oxide, gallium oxide, tantalum oxide, zirconium oxide, hafnium oxide, magnesium oxide, germanium oxide, silicon oxide, or a composite oxide including two or more types of cations of these oxides.

### Eighty-Eighth Aspect

The light-emitting element according to any one of the fifty-eighth and eighty-first to eighty-sixth aspects, wherein the fifth oxide layer is formed of any one of aluminum oxide, gallium oxide, tantalum oxide, zirconium oxide, hafnium oxide, magnesium oxide, germanium oxide, silicon oxide, or a composite oxide including two or more types of cations of these oxides.

### Eighty-Ninth Aspect

The light-emitting element according to any one of the fifty-eighth and eighty-first to eighty-sixth aspects, wherein the fifth oxide layer is formed of an oxide including one or more elements from among Al, Ga, Ta, Zr, Hf, Mg, Ge, and Si as a main component.

### Ninetieth Aspect

The light-emitting element according to any one of the fifty-eighth and eighty-first to eighty-sixth aspects, wherein the fifth oxide layer is formed of an oxide in which a Most Abundant Element Other than Oxygen is any One of Al, Ga, Ta, Zr, Hf, Mg, Ge, or Si.

### Ninety-first Aspect

A light-emitting element, including:

a first electrode which is an anode;

a second electrode which is a cathode;

a light-emitting layer provided between the first electrode and the second electrode;

a fifth oxide layer provided between the light-emitting layer and the second electrode;

a sixth oxide layer provided in contact with the fifth oxide layer and between the fifth oxide layer and the second electrode; and

a seventh oxide layer provided in contact with the sixth oxide layer and between the sixth oxide layer and the second electrode, wherein

the sixth oxide layer is formed from a semiconductor;

an oxide including at least one of aluminum oxide, gallium oxide, tantalum oxide, zirconium oxide, hafnium oxide, magnesium oxide, germanium oxide, silicon oxide, or a composite oxide including two or more types of cations of these oxides is an oxide of a group A;

an oxide including at least one of aluminum oxide, gallium oxide, or a composite oxide including two or more types of cations of these oxides is an oxide of a group B;

an oxide including at least one of aluminum oxide, gallium oxide, tantalum oxide, zirconium oxide, hafnium oxide, magnesium oxide, germanium oxide, or a composite oxide including two or more types of cations of these oxides is an oxide of a group C;

an oxide including at least one of aluminum oxide, gallium oxide, tantalum oxide, or a composite oxide including two or more types of cations of these oxides is an oxide of a group D;

an oxide including at least one of aluminum oxide, gallium oxide, tantalum oxide, zirconium oxide, hafnium oxide, or a composite oxide including two or more types of cations of these oxides is an oxide of a group E;

an oxide including at least one of aluminum oxide, gallium oxide, tantalum oxide, zirconium oxide, hafnium oxide, magnesium oxide, germanium oxide, silicon oxide, yttrium oxide, lanthanum oxide, strontium oxide, or a composite oxide including two or more types of cations of these oxides is an oxide of a group F;

an oxide including at least one of gallium oxide, tantalum oxide, zirconium oxide, hafnium oxide, magnesium oxide, germanium oxide, silicon oxide, yttrium oxide, lanthanum oxide, strontium oxide, or a composite oxide including two or more types of cations of these oxides is an oxide of a group G;

an oxide including at least one of hafnium oxide, magnesium oxide, germanium oxide, silicon oxide, yttrium oxide, lanthanum oxide, strontium oxide, or a composite oxide including two or more types of cations of these oxides is an oxide of a group H;

an oxide including at least one of germanium oxide, silicon oxide, yttrium oxide, lanthanum oxide, strontium oxide, or a composite oxide including two or more types of cations of these oxides is an oxide of a group I;

an oxide including at least one of silicon oxide, yttrium oxide, lanthanum oxide, strontium oxide, or a composite oxide including two or more types of cations of these oxides is an oxide of a group J;

an oxide including at least one of yttrium oxide, lanthanum oxide, strontium oxide, or a composite oxide including two or more types of cations of these oxides is an oxide of a group K;

in a case where the sixth oxide layer includes a rutile-type titanium oxide, the seventh oxide layer is an oxide of the group F and the fifth oxide layer is an oxide of the group B;

in a case where the sixth oxide layer includes an anatase-type of titanium oxide, the seventh oxide layer is an oxide of the group G and the fifth oxide layer is an oxide of the group B;

in a case where the sixth oxide layer includes tin oxide, the seventh oxide layer is an oxide of the group H and the fifth oxide layer is an oxide of the group D;

in a case where the sixth oxide layer includes strontium titanium, the seventh oxide layer is an oxide of the group I and the fifth oxide layer is an oxide of the group E;

in a case where the sixth oxide layer includes indium oxide, the seventh oxide layer is an oxide of the group J and the fifth oxide layer is an oxide of the group C; and

in a case where the sixth oxide layer includes zinc oxide, the seventh oxide layer is an oxide of the group K and the fifth oxide layer is an oxide of the group A.

### Ninety-Second Aspect

The light-emitting element according to any one of the fifty-eighth and eighty-first to ninety-first aspects, wherein an electron density in the sixth oxide layer is greater than an electron density in the fifth oxide layer.

### Ninety-Third Aspect

The light-emitting element according to any one of the fifty-eighth and eighty-first to ninety-second aspects, wherein an energy difference between a conduction band lower end and a valence band upper end in the fifth oxide layer is greater than an energy difference between a conduction band lower end and a valence band upper end in the sixth oxide layer.

### Ninety-Fourth Aspect

The light-emitting element according to any one of the fifty-eighth and eighty-first to ninety-third aspects, wherein an energy difference between a vacuum level and a Fermi level of the second electrode is greater than an electron affinity of the sixth oxide layer; and an electron affinity of the fifth oxide layer is less than the electron affinity of the sixth oxide layer.

### Ninety-Fifth Aspect

The light-emitting element according to any one of the fifty-eighth and eighty-first to ninety-fourth aspects, wherein a film thickness of the fifth oxide layer is from 0.2 nm to 5 nm.

### Ninety-Sixth Aspect

The light-emitting element according to the ninety-fifth aspect, wherein the film thickness of the fifth oxide layer is from 0.8 nm to less than 3 nm.

### Ninety-Seventh Aspect

The light-emitting element according to any one of the fifty-eighth and eighty-first to ninety-sixth aspects, wherein the oxygen atom density in the sixth oxide layer is from 50% to 95% of the oxygen atom density in the fifth oxide layer.

### Ninety-Eighth Aspect

The light-emitting element according to the ninety-seventh aspect, wherein the oxygen atom density in the sixth oxide layer is from 50% to 84% of the oxygen atom density in the fifth oxide layer.

### Ninety-Ninth Aspect

The light-emitting element according to any one of the fifty-eighth and eighty-first to ninety-sixth aspects, wherein the oxygen atom density in the sixth oxide layer is 50% or greater of the oxygen atom density in the fifth oxide layer.

### One-Hundredth Aspect

The light-emitting element according to the first aspect, wherein the oxygen atom density in the first oxide layer is less than the oxygen atom density in the second oxide layer.

### One-Hundred and First Aspect

The light-emitting element according to the fifty-fifth aspect, wherein the oxygen atom density in the fifth oxide layer is less than the oxygen atom density in the sixth oxide layer: and the oxygen atom density in the seventh oxide layer is less than the oxygen atom density in the sixth oxide layer.

### One-Hundred and Second Aspect

The light-emitting element according to the fifty-fifth aspect, wherein the oxygen atom density in the sixth oxide layer is less than the oxygen atom density in the fifth oxide layer; and the oxygen atom density in the sixth oxide layer is less than the oxygen atom density in the seventh oxide layer.

### One-Hundred and Third Aspect

The light-emitting element according to the fifty-fifth aspect, wherein the oxygen atom density in the fifth oxide layer is less than the oxygen atom density in the sixth oxide layer; and the oxygen atom density in the sixth oxide layer is less than the oxygen atom density in the seventh oxide layer.

### One-Hundred and Fourth Aspect

A light-emitting element according to any one of the fifty-fifth, fifty-sixth, fifty-seventh, fifty-ninth, and sixty-first to eightieth aspects, wherein

the fifth oxide layer, the sixth oxide layer, and the seventh oxide layer are provided between the first electrode and the light-emitting layer;

an eighth oxide layer, a ninth oxide layer in contact with the eighth oxide layer, and a tenth oxide layer in contact with the ninth oxide layer are provided in this order from the side closer to the first electrode between the light-emitting layer and the second electrode;

the ninth oxide layer is formed from a semiconductor,

an oxygen atom density in the ninth oxide layer is different from an oxygen atom density in the eighth oxide layer; and an oxygen atom density in the tenth oxide layer is different from the oxygen atom density of the ninth oxide layer.

### One-Hundred and Fifth Aspect

The light-emitting element according to any one of the first to one-hundred and fourth aspects, wherein the light-emitting layer includes a quantum dot phosphor.

### One-Hundred and Sixth Aspect

A light-emitting device, including the light-emitting element according to any one of the first to one-hundred and fifth aspects.

### One-Hundred and Seventh Aspect

A display device, including the light-emitting element according to any one of the first to one-hundred and fifth aspects on a substrate.

### One-Hundred and Eighth Aspect

An illumination device, including the light-emitting element according to any one of the first to one-hundred and fifth aspects on a substrate.

### Appendix

The present disclosure is not limited to the embodiments described above, and various modifications may be made within the scope of the claims. Embodiments obtained by appropriately combining technical approaches disclosed in the different embodiments also fall within the technical scope of the present disclosure. Furthermore, novel technical features can be formed by combining the technical approaches disclosed in each of the embodiments.

### INDUSTRIAL APPLICABILITY

The present disclosure may be utilized in light-emitting elements and light-emitting devices.

### REFERENCE SIGNS LIST

1a to 1d Electric dipole
2 Display device
3 Barrier layer
4 TFT layer
5R, 5G, 5B Light-emitting element
5RA to 5RL, 5RW Light-emitting element
6 Sealing layer
10 Substrate
12 Resin layer
16, 18, 20 Inorganic insulating film
21 Flattening film
22 First electrode (anode)
24a Hole transport layer (HTL)
24c Light-emitting layer of first wavelength region (light-emitting layer)
24c′ Light-emitting layer of second wavelength region (light-emitting layer)
24c″ Light-emitting layer of third wavelength region (light-emitting layer)
24d Electron transport layer (ETL)
25 Second electrode (cathode)
34a, 34a′, 34a″, 34a′″ Oxide layer (HTL) (second oxide layer)
34as Oxide layer (HTL) (sixth oxide layer)
34b Oxide layer (first oxide layer, fifth oxide layer)
34b′ Oxide layer (first oxide layer)
34c Oxide layer (ETL) (first oxide layer, third oxide layer)
34c′, 34c″, 34c′″ Oxide layer (ETL) (first oxide layer)
34cs Oxide layer (ETL) (sixth oxide layer, ninth oxide layer)
34d Oxide layer (second oxide layer, fourth oxide layer, seventh oxide layer, tenth oxide
layer)
34d′ Oxide layer (second oxide layer)
74b Oxide layer (fifth oxide layer, eighth oxide layer)
124b Oxide layer (seventh oxide layer)
IP1 to IP4 Ionization potential
EA1 to EA4 Electron affinity
Ed Energy difference between vacuum level and Fermi level of electrode

1. A light-emitting element, comprising:
a first electrode which is an anode;
a second electrode which is a cathode;
a light-emitting layer provided between the first electrode and the second electrode;
a first oxide layer provided between the first electrode or the second electrode and the light-emitting layer; and
a second oxide layer provided in contact with the first oxide layer and between the first oxide layer and the second electrode,
wherein of the first oxide layer and the second oxide layer, the layer closer to the light-emitting layer is formed from a semiconductor, and
an oxygen atom density in the second oxide layer is different from an oxygen atom density in the first oxide layer.

2-14. (canceled)

15. The light-emitting element according to claim 1,
wherein the first oxide layer and the second oxide layer are provided between the first electrode and the light-emitting layer, and
the first oxide layer is formed of an oxide including one or more elements from among Al, Ga, Zr, Hf, Mg, Ge, Si, Y, La, and Sr as a main component.

16. The light-emitting element according to claim 1,
wherein the first oxide layer and the second oxide layer are provided between the first electrode and the light-emitting layer,
if the second oxide layer includes at least one of nickel oxide or copper aluminate, the first oxide layer includes at least one of aluminum oxide, gallium oxide,
zirconium oxide, hafnium oxide, magnesium oxide, or a composite oxide including two or more types of cations of these oxides, and
if the second oxide layer includes a copper(I) oxide, the first oxide layer includes at least one of aluminum oxide, gallium oxide, tantalum oxide, zirconium oxide, hafnium oxide, magnesium oxide, germanium oxide, silicon oxide, yttrium oxide, lanthanum oxide, strontium oxide, or a composite oxide including two or more types of cations of these oxides.

17. The light-emitting element according to claim 16,
wherein the second oxide layer is an oxide including copper(I) oxide,
the first oxide layer includes at least one of aluminum oxide, gallium oxide, tantalum oxide, zirconium oxide, hafnium oxide, magnesium oxide, germanium oxide, silicon oxide, yttrium oxide, lanthanum oxide, strontium oxide, or a composite oxide including two or more types of cations of these oxides.

18-25. (canceled)

26. The light-emitting element according to claim 1,
wherein the first oxide layer and the second oxide layer are provided between the light-emitting layer and the second electrode, and
the first oxide layer is formed of an oxide in which a most abundant element other than oxygen is any one of, Sn, Sr, or In.

27. The light-emitting element according to claim 1,
wherein the first oxide layer and the second oxide layer are provided between the light-emitting layer and the second electrode, and
the second oxide layer is formed of an oxide in which a most abundant element other than oxygen is any one of Al, Ga, Ta, Zr, Hf, Mg, Ge, Y, La, or Sr.

28. A light-emitting element, comprising:
a first electrode which is an anode;
a second electrode which is a cathode;
a light-emitting layer provided between the first electrode and the second electrode;
a first oxide layer provided between the second electrode and the light-emitting layer; and
a second oxide layer provided in contact with the first oxide layer and between the first oxide layer and the second electrode,
wherein an oxide including at least one of aluminum oxide, gallium oxide, tantalum oxide, zirconium oxide, hafnium oxide, magnesium oxide, germanium oxide, yttrium oxide, lanthanum oxide, strontium oxide, or a composite oxide including two or more types of cations of these oxides is an oxide of a first group,
an oxide including at least one of gallium oxide (β), tantalum oxide, zirconium oxide, hafnium oxide, magnesium oxide, germanium oxide, yttrium oxide, lanthanum oxide, strontium oxide, or a composite oxide including two or more types of cations of these oxides is an oxide of a second group,
an oxide including at least one of hafnium oxide, magnesium oxide, germanium oxide, silicon oxide, yttrium oxide, lanthanum oxide, strontium oxide, or a composite oxide including two or more types of cations of these oxides is an oxide of a third group,
an oxide including at least one of germanium oxide, silicon oxide, yttrium oxide, lanthanum oxide, strontium oxide, or a composite oxide including two or more types of cations of these oxides is an oxide of a fourth group,
an oxide including at least one of silicon oxide, yttrium oxide, lanthanum oxide, strontium oxide, or a composite oxide including two or more types of cations of these oxides is an oxide of a fifth group,
an oxide including at least one of yttrium oxide, lanthanum oxide, strontium oxide, or a composite oxide including two or more types of cations of these oxides is an oxide of a sixth group,
in a case where the first oxide layer includes a rutile-type titanium oxide, the second oxide layer is an oxide of the first group,
in a case where the first oxide layer includes an anatase-type of titanium oxide, the second oxide layer is an oxide of the second group,
in a case where the first oxide layer includes tin oxide, the second oxide layer is an oxide of the third group,
in a case where the first oxide layer includes strontium titanium, the second oxide layer is an oxide of the fourth group,
in a case where the first oxide layer includes indium oxide, the second oxide layer is an oxide of the fifth group, and
in a case where the first oxide layer includes zinc oxide, the second oxide layer is an oxide of the sixth group.

29. The light-emitting element according to claim 28,
wherein the first oxide layer is formed of a rutile-type titanium oxide, and
the second oxide layer is formed of at least one of aluminum oxide, gallium oxide, tantalum oxide, zirconium oxide, hafnium oxide, magnesium oxide, germanium oxide, yttrium oxide, lanthanum oxide, strontium oxide, or a composite oxide including two or more types of cations of these oxides.

30. The light-emitting element according to claim 28,
wherein the first oxide layer is formed of an anatase-type titanium oxide, and
the second oxide layer is formed of at least one of gallium(β) oxide, tantalum oxide, zirconium oxide, hafnium oxide, magnesium oxide, germanium oxide, yttrium oxide, lanthanum oxide, strontium oxide, or a composite oxide including two or more types of cations of these oxides.

31. The light-emitting element according to claim 28,
wherein the first oxide layer is formed of tin oxide, and
the second oxide layer is formed of at least one of hafnium oxide, magnesium oxide, germanium oxide, silicon oxide, yttrium oxide, lanthanum oxide, strontium oxide, or a composite oxide including two or more types of cations of these oxides.

32. The light-emitting element according to claim 28,
wherein the first oxide layer is formed of strontium titanate, and
the second oxide layer is formed of at least one of germanium oxide, silicon oxide, yttrium oxide, lanthanum oxide, strontium oxide, or a composite oxide including two or more types of cations of these oxides.

33. The light-emitting element according to claim 28,
wherein the first oxide layer is formed of indium oxide, and
the second oxide layer is formed of at least one of silicon oxide, yttrium oxide, lanthanum oxide, strontium oxide, or a composite oxide including two or more types of cations of these oxides.

34. The light-emitting element according to claim 28,
wherein the first oxide layer is formed of zinc oxide, and
the second oxide layer is formed of at least one of yttrium oxide, lanthanum oxide, strontium oxide, or a composite oxide including two or more types of cations of these oxides.

35-41. (canceled)

42. The light-emitting element according to claim 1, further comprising:
a third oxide layer provided between the light-emitting layer and the second electrode; and
a fourth oxide layer provided in contact with the third oxide layer and between the third oxide layer and the second electrode,
wherein the first oxide layer and the second oxide layer are provided between the light-emitting layer and the first electrode,
the third oxide layer is formed from an n-type semiconductor, and
an oxygen atom density in the fourth oxide layer is different from an oxygen atom density in the third oxide layer.

43. A light-emitting element, comprising:
a first electrode which is an anode;
a second electrode which is a cathode;
a light-emitting layer provided between the first electrode and the second electrode; and
a fifth oxide layer, a sixth oxide layer in contact with the fifth oxide layer, and a seventh oxide layer in contact with the sixth oxide layer provided in this order from a side closer to the first electrode between the first electrode and the light-emitting layer or between the light-emitting layer and the second electrode,
wherein the fifth oxide layer is formed from an insulator,
the sixth oxide layer is formed from a semiconductor,
the seventh oxide layer is formed from an insulator,
an oxygen atom density in the sixth oxide layer is different from an oxygen atom density in the fifth oxide layer, and
an oxygen atom density in the seventh oxide layer is different from the oxygen atom density of the sixth oxide layer.

44. The light-emitting element according to claim 43,
wherein the oxygen atom density in the sixth oxide layer is less than the oxygen atom density in the fifth oxide layer, and
the oxygen atom density in the seventh oxide layer is less than the oxygen atom density in the sixth oxide layer.

45-47. (canceled)

48. The light-emitting element according to claim 1,
wherein the layer of either the first oxide layer or the second oxide layer, which is far from the light emitting layer, is formed from an insulator,
the oxygen atom density in the first oxide layer is less than the oxygen atom density in the second oxide layer.

49. (canceled)

50. A light-emitting device, comprising:
the light-emitting element according to claim 1.

51. The light-emitting element according to claim 16,
wherein the second oxide layer is an oxide including at least one of nickel oxide and copper aluminate,
the first oxide layer includes at least one of aluminum oxide, gallium oxide, zirconium oxide, hafnium oxide, magnesium oxide, or a composite oxide including two or more types of cations of these oxides.

52. The light-emitting element according to claim 42,
wherein the oxygen atom density in the second oxide layer is less than the oxygen atom density in the first oxide layer, and
the oxygen atom density in the forth oxide layer is less than the oxygen atom density in the third oxide layer.
